(19) United States
(12) Patent Application Publication
(10) Pub. No.: US 2019/0013430 A1
(43) Pub. Date: Jan. 10, 2019

(54) OPTOELECTRONIC DEVICES INCLUDING DILUTE NITRIDE

(71) Applicant: Solar Junction Corporation, San Jose, CA (US)

(72) Inventors: Rebecca Elizabeth JONES-ALBERTUS, Washington, DC (US); Pranob MISRA, Sunnyvale, CA (US); Michael J. SHELDON, Marana, AZ (US); Homan B. YUEN, Santa Clara, CA (US); Ting LIU, San Jose, CA (US); Daniel DERKACS, Albuquerque, NM (US); Vijit SABNIS, Cupertino, CA (US); Michael West WIEMER, Campbell, CA (US); Ferran SUAREZ, Chandler, AZ (US)

(73) Assignee: Solar Junction Corporation, San Jose, CA (US)

(21) Appl. No.: 16/132,059

(22) Filed: Sep. 14, 2018

Related U.S. Application Data
(63) Continuation-in-part of application No. 13/894,245, filed on May 14, 2013.
Application No. 13/894,245 is a continuation-in-part of application No. 13/678,389, filed on Nov. 15, 2012, now abandoned.
Application No. 13/678,389 is a continuation-in-part of application No. 14/935,145, filed on Nov. 6, 2015.
Application No. 14/935,145 is a continuation of application No. 12/914,710, filed on Oct. 28, 2010, now Pat. No. 9,214,580.
Application No. 12/914,710 is a continuation-in-part of application No. 14/614,601, filed on Feb. 5, 2015.
(60) Provisional application No. 61/559,982, filed on Nov. 15, 2011.
(60) Provisional application No. 62/564,124, filed on Sep. 27, 2017.
(60) Provisional application No. 61/936,222, filed on Feb. 5, 2014.

(51) Int. Cl. H01L 31/0735; H01L 31/0687; H01L 31/0304; H01L 31/0725; H01L 31/065; H01L 31/18

(52) U.S. Cl. CPC H01L 31/0735; Y02E 10/544; H01L 31/0687; H01L 31/03048; H01L 31/1844; H01L 31/0725; H01L 31/065; H01L 31/03042

(57) ABSTRACT

Compound semiconductor alloys comprising dilute nitride materials, are materials used in absorbing layers for photodetectors, power converters, solar cells, and in particular to high efficiency, electronic and optoelectronic devices, including multijunction solar cells, photodetectors, power converters, and the like, formed primarily of III-V semiconductor alloys. The absorbing (or active) layers achieve improved characteristics including band gap optimization and minimization of defects.

### CROSS REFERENCE TO RELATED APPLICATIONS

This application is a continuation-in-part of U.S. patent application Ser. No. 13/894,245 filed on May 14, 2013, which is a continuation-in-part of U.S. patent application Ser. No. 13/678,389 filed on Nov. 15, 2012, which claims the benefit of U.S. Provisional Patent Application No. 61/559,982 filed on Nov. 15, 2011, which are all incorporated by reference in their entireties.

This application is a continuation-in-part of U.S. patent application Ser. No. 14/935,145 filed on Nov. 6, 2015, which is a continuation of U.S. patent application Ser. No. 12/914,710 filed on Oct. 28, 2010, issued as U.S. Pat. No. 9,214,580, which are both incorporated by reference in their entireties.

This application is a continuation-in-part of U.S. patent application Ser. No. 14/614,601 filed on Feb. 5, 2015, which claims the benefit of U.S. Provisional Patent Application No. 61/936,222 filed on Feb. 5, 2014, which are all incorporated by reference in their entireties.

This application claims the benefit of U.S. Provisional Patent Application No. 62/564,124 filed on Sep. 27, 2017, which is incorporated by reference in its entirety.

### BACKGROUND

The present invention relates to compound semiconductor alloys comprising dilute nitride materials, and the use of the materials as optical absorbing layers for photodetectors, power converters, solar cells, and in particular to high efficiency, electronic and optoelectronic devices, including multijunction solar cells, photodetectors, power converters, and the like, formed primarily of III-V semiconductor alloys

III-V compound semiconductor materials are widely used in the fabrication of semiconductor optoelectronic devices such as emitters, detectors, and modulators, for a variety of applications, as well as in the fabrication of tandem and multijunction solar cells. For devices operating at telecommunications wavelengths at about 1.3 μm and 1.55 μm, indium gallium Arsenide (InGaAs) alloys are used, and are lattice matched to InP substrates to ensure high quality materials with low levels of defects. However, this material system has several limitations, including the high cost of InP substrates, low yields due to fragility of the InP substrates, and limited InP wafer diameter (and associated quality issues at larger diameters). From a manufacturing perspective, and also an economic perspective, gallium arsenide (GaAs) represents a better substrate choice. However, the large lattice mismatch between GaAs and the InGaAs alloys required for infrared devices produces poor quality materials that compromise electrical and optical performance.

For multijunction solar cells, semiconductor materials with appropriate band gaps need to be chosen in order to achieve the highest efficiencies. Devices are typically fabricated on GaAs or Ge substrates. Selecting materials with the appropriate band gaps, and in particular, material with a band gap of nominally leV, results in materials with different lattice constants needing to be integrated together, with metamorphic buffers being used to allow such integration. However, the use of metamorphic buffers requires thicker semiconductor layers, and can introduce defects, such as dislocations into a material, based on lattice-mismatch. It is also very difficult to include more junctions in devices than is presently the case, with different band gaps, since additional band gaps will occur for compositions of matter with yet further different lattice constants.

Dilute nitride materials are a special class of semiconductor alloys of particular interest, since it is known that their band gaps can be tuned over a very wide range, while allowing lattice-matching to be maintained with respect to an underlying semiconductor substrate, such as GaAs or Ge. The band gap for dilute nitride materials that can be grown lattice-matched or pseudomorphically strained to the substrate can be tuned between 0.7 eV and 1.3 eV, spanning the wavelength range of interest for optoelectronic devices, such as those employed in telecommunications applications, providing band gaps corresponding to eye-safe wavelengths for power converter applications, and can also providing band gaps (such as 1 eV and others) suitable for integration of lattice-matched subcells that can be used in multijunction photovoltaic cells.

The highest known solar cell efficiencies have been produced by multijunction solar cells comprised primarily of III-V semiconductor alloys. Such alloys are combinations of elements drawn from columns IIIA and VA of the standard Periodic Table, identified hereinafter by their standard chemical symbols, names and abbreviations, and wherein the total number of elements from column IIIA is substantially equal to the total number of elements from column VA. The high efficiencies of these solar cells make them attractive for terrestrial concentrating photovoltaic systems and systems designed to operate in space.

Historically, the highest efficiency solar cells have consisted of a monolithic stack of three subcells, which are equivalently referred to as junctions, grown on germanium (Ge) or gallium arsenide (GaAs) substrates. The subcells contain the regions of the solar cell where light energy in a range of wavelengths is absorbed and converted into electrical energy that may be collected externally. The subcells may be interconnected with one another by tunnel junctions. Other layers, such as buffer layers, may also exist between the subcells. In the highest efficiency solar cells demonstrated to date, the top subcell has one or more absorbing layers made of (Al)GaInP, the intermediate subcell has one or more absorbing layers made of (In)GaAs, and the bottom subcell includes a Ge substrate or has absorbing layers made of a III-V material. The foregoing nomenclature for a III—V alloy, wherein a constituent element is shown parenthetically, such as Al in (Al)InGaP, denotes a condition of variability in which that particular element can be zero.

Each subcell comprises several associated layers, typically including a window, emitter, base and back surface field (BSF). These terms are well known to those skilled in the art and do not need further definition here. Each of the foregoing layers may itself include one or more sublayers. The window and emitter will be of one doping polarity (e.g., n-type) and the base and back surface field will be of the opposite polarity (e.g., p-type), with a p-n or n-p junction formed between the base and the emitter. If the base contains an intrinsic region in addition to an intentionally doped region, then it may be considered a p-i-n or n-i-p junction, as is well known to those skilled in the art. By convention, the specific alloy and the band gap of a given subcell are considered to be the name and the band gap, respectively, of the material forming the base. This material may or may not also be used for the window, emitter and back surface field of the subcell. For example, a subcell comprising an AlInP window, an InGaP emitter, a GaAs base and an AlGaAs back surface field would be denoted a GaAs subcell and its band gap would be the GaAs band gap of 1.4 eV. A subcell comprising an AlInP window, an InGaP emitter, an InGaP base and an InGaP back surface field would be denoted an InGaP subcell, and its band gap would be that of the InGaP base. The subcell may include layers in addition to those listed above. Those skilled in the art will also recognize that subcells may also be constructed without one or more of the foregoing layers. For example, subcells may be constructed without a window or without a back surface field.

When speaking about the stacking order of the subcells from top to bottom, the top subcell is defined to be the subcell closest to the light source during operation of the solar cell, and the bottom subcell is furthest from the light source. Relative terms like “above,” “below,” “upper,” and “lower” also refer to position in the stack with respect to the light source. The order in which the subcells were grown is not relevant to this definition. The top subcell is also denoted “J1,” with “J2” being the second subcell from the top, “J3” being third from the top, and the highest number going to the bottom subcell.

Three-junction solar cells have reached the highest efficiencies of any solar cells to date. See M. A. Green et al., Progress in Photovoltaics: Research and Applications 19 (2011) 565-572. However, these three-junction solar cells are approaching their practical efficiency limits. To reach significantly higher efficiencies, additional junctions or subcells are needed. With additional subcells, photons can be absorbed more efficiently by materials with band gaps closer to the photon energies, which are able to convert more light energy into electrical energy rather than heat. In addition, the total solar cell current with additional subcells may be lower for a given amount of incident light, which may reduce series resistance losses. Another mechanism for increasing efficiency is to absorb a larger fraction of the solar spectrum with additional subcell(s). For many years, there has been widespread recognition of the need for higher numbers of junctions, but to date, the attempt to build cells of four, five and six junctions has failed to produce solar cells with efficiencies that exceeded the efficiencies of the best three-junction solar cells. The reasons for failure have been unclear, although material and design flaws have been suspected, including poor material quality, which can be a result of dislocations produced by the use of lattice-mismatched layers. There are additional challenges related to the increased number of tunnel junctions required to interconnect the additional subcells, including the loss of light by tunnel junction absorption.

There has long been interest in high efficiency, lattice-matched multijunction solar cells with four or more subcells, but suitable materials for creating high efficiencies while maintaining lattice matching among the subcells and to a substrate have previously been elusive. For example, U.S. Pat. No. 7,807,921 discusses the possibility of a four junction, lattice-matched solar cell with GaInNAs as the material for a 1.0 eV subcell. However, the applicant concluded that this design is impractical because GaInNAs that is lattice matched to the other subcells exhibited poor quality when produced by then known techniques. To overcome the problems with finding feasible, lattice-matched structures, the patent teaches the use of metamorphic materials including a graded metamorphic layer of GaInNAs that is not lattice matched. In another attempt to make a 1 eV subcell that may be lattice-matched to the traditional InGaP/(In)GaAs/Ge solar cell, a material consisting of gallium, indium, nitrogen, arsenic and various concentrations of antimony was studied, but these investigators concluded that antimony, even in small concentrations should be avoided as it was considered detrimental to device performance. See Ptak et al., Journal of Vacuum Science Technology B 25(3) May/June 2007 pp. 955-959.

Prior work in this general field demonstrates that a high level of skill in the art exists for making materials, so that it is not necessary to disclose specific details of the processes of making the materials for use in solar cells. Several representative U.S. patents are exemplary. U.S. Pat. No. 6,281,426 discloses certain structures and compositions without disclosing fabrication techniques and refers to other documents for guidance on growth of materials. U.S. Pat. No. 7,727,795 relates to inverted metamorphic structures for solar cells in which exponential doping is disclosed.

What is needed to continue the progress toward higher efficiency solar cells are designs for multijunction solar cells with four or more subcells that can reach higher efficiencies than can be practically attained with three-junction solar cells. It is conventionally assumed that substantially lattice-matched designs are desirable because they have proven reliability and because they use less semiconductor material than metamorphic solar cells, which require relatively thick buffer layers to accommodate differences in the lattice constants of the various materials. It is to be noted that the general understanding of “substantially lattice matched” is that the in-plane lattice constants of the materials in their fully relaxed states differ by less than 0.6% when the materials are present in thicknesses greater than 100 nm. Further, subcells that are substantially lattice matched to each other as used herein means that all materials in the subcells that are present in thicknesses greater than 100 nm have in-plane lattice constants in their fully relaxed states that differ by less than 0.6%.

For optoelectronic devices, such as photodetectors, while dilute-nitride based devices have been fabricated on GaAs substrates, their performance levels, such as responsivity, have been much lower than for InGaAs/InP devices, which have made materials unsuitable for practical sensing and detection applications.

### SUMMARY

According to the present invention compound semiconductor optoelectronic devices comprise a substrate; a first doped III-V layer overlying the substrate; an active region overlying the first doped III-V region, wherein, the active region comprises a lattice matched or pseudomorphic dilute nitride layer; and the dilute nitride layer has a band gap within a range from 0.7 eV and 1.0 eV; and a second doped III-V layer overlying the active region.

According to the present invention, methods of forming a semiconductor optoelectronic device comprise forming a substrate; forming a first doped III-V layer overlying the substrate; forming an active region overlying the first doped III-V layer, wherein, the active region comprises a pseudomorphic dilute nitride layer; and the dilute nitride layer has a band gap within a range from 0.7 eV and 1.0 eV; and forming a second doped III-V layer overlying the active region.

The invention includes multijunction solar cells comprising four, five or more subcells having efficiencies that can exceed those of known best solar cells. The multijunction solar cells incorporate at least one subcell that has a base comprising a III-V material containing As, N and at least one additional element from the group containing Sb and Bi, referred to as III-AsNV materials, wherein the composition of the material is tailored for band gap and lattice constant. The aforementioned subcells comprise the bottom subcell and/or the subcell immediately adjacent to the bottom subcell in each of the multijunction solar cells of the invention. The subcells of the multijunction solar cells of the invention are substantially lattice-matched to each other. In certain embodiments, the subcells of the multijunction solar cells are substantially lattice-matched to a substrate. The methodology for determining the physical parameters of the subcells is based upon an accurate simulation that specifies subcell thicknesses and runs an optimization procedure to find band gaps, and therefore material ratios in alloys, by imposing lattice-matching and current-matching between subcells. Solar cells of the desired high quality material composition may then be fabricated based on the material compositions specified by the simulation.

In a specific embodiment two III-AsNV subcells of differing band gaps are fabricated in a single multijunction solar cell, where at least one of the subcells has a band gap higher than previously achievable or suggested. In another specific embodiment, three III-AsNV subcells of differing band gaps are fabricated in a single multijunction solar cell, where at least one of the subcells has a band gap higher than previously achievable or suggested.

In further specific embodiments, designs with four to six junctions are disclosed wherein the bottom subcell has a higher bottom band gap than previously disclosed or suggested.

In further embodiments, solar cells with a bottom III-AsNV subcell with a band gap lower than has previously been achievable for a III-AsNV alloy that is substantially lattice-matched to a substrate are disclosed.

While there has been a body of work in multijunction cells, the material parameters and specific structures developed in the present invention and discussed herein have not been disclosed.

The invention will be better understood by reference to the following detailed description in connection with the accompanying tables and figures which constitute the drawings.

### BRIEF DESCRIPTION OF THE DRAWINGS

The accompanying drawings, which are incorporated herein and form part of the specification, illustrate the present disclosure and, together with the description, further serve to explain the principles of the disclosure and to enable a person skilled in the relevant art to make and use the disclosure.

FIG. 1A is a schematic cross-section of a multijunction solar cell with five subcells illustrating an embodiment of the invention.

FIG. 1B is a schematic cross-section of a multijunction solar cell with six subcells illustrating an embodiment of the invention.

FIG. 2A is a schematic cross-section of a multijunction solar cell with five subcells illustrating still another embodiment of the invention.

FIG. 2B depicts a schematic cross-section of a multijunction solar cell with six subcells illustrating still another embodiment of the invention.

FIG. 3A depicts a schematic cross-section of a multijunction solar cell with four subcells illustrating still another embodiment of the invention.

FIG. 3B depicts a schematic cross-section of a multijunction solar cell with four subcells illustrating still another embodiment of the invention.

FIG. 3C depicts a schematic cross-section of a multijunction solar cell with four subcells illustrating still another embodiment of the invention.

FIG. 3D depicts a schematic cross-section of a multijunction solar cell with four subcells illustrating still another embodiment of the invention.

FIG. 4 shows the efficiency as a function of bottom subcell band gap for a specific embodiment of the invention with four subcells under the AM1.5D spectrum at 25° C.

FIG. 5 shows the efficiency as a function of bottom subcell band gap for a specific embodiment of the invention with four subcells under the AM0 spectrum at 25° C.

FIG. 6 depicts a schematic cross-section of a multijunction solar cell with four subcells illustrating still another embodiment of the invention.

FIG. 7 depicts a schematic cross-section of a multijunction solar cell with five subcells illustrating still another embodiment of the invention.

FIG. 8 shows the efficiency as a function of bottom subcell band gap for a specific embodiment of the invention with five subcells.

FIG. 9 depicts a schematic cross-section of a multijunction solar cell with five subcells illustrating still another embodiment of the invention.

FIG. 10 depicts a schematic cross-section of a multijunction solar cell with five subcells illustrating still another embodiment of the invention.

FIG. 11 depicts a schematic cross-section of a multijunction solar cell with six subcells illustrating still another embodiment of the invention.

FIG. 12 depicts a schematic cross-section of a multijunction solar cell with six subcells illustrating still another embodiment of the invention.

FIG. 13A depicts a schematic cross-section of a multijunction solar cell with six subcells illustrating still another embodiment of the invention.

FIG. 13B depicts a schematic cross-section of a multijunction solar cell with six subcells illustrating still another embodiment of the invention.

FIG. 14 shows the efficiency as a function of bottom subcell band gap for a specific embodiment of the invention with six subcells.

FIG. 15 illustrates elements of a multijunction solar cell device as found in certain embodiments of the invention.

FIG. 16 illustrates a schematic cross section of a more specific example of a multijunction solar cell according to the invention.

FIG. 17A shows current-voltage curves for the multijunction solar cell with five subcells according to the invention compared to a state-of-the-art multijunction solar cell with three subcells.

FIG. 17B depicts a schematic cross section of a multijunction solar cell with five subcells illustrating still another example of the embodiment of the invention depicted in FIG. 7.

FIG. 18A shows current-voltage curves for the multijunction solar cell with four subcells according to the invention compared to a state-of-the-art multijunction solar cell with three subcells measured under the AM0 spectrum.

FIG. 18B shows the solar cell with four subcells for which the simulation depicted in FIG. 18A was produced.

FIG. 19A shows current-voltage curves for the multijunction solar cell with six subcells according to the invention compared to a state-of-the-art multijunction solar cell with three subcells measured under the AM0 spectrum.

FIG. 19B shows the solar cell with six subcells for which the simulation depicted in FIG. 19A was produced.

FIG. 20 shows the calculated band gap as a function of composition for Ga_{1.01-3w}In_{3w-0.01}N_{w}As_{0.99-w}Sb_{0.01}.

FIG. 21 shows a side view of an optoelectronic device.

FIG. 22A shows a plot of semiconductor band gap and In/Sb ratio as a function of composition for Ga_{1.01-3w}In_{3w-0.01}N_{w}As_{0.99-w}Sb_{0.01}, as a function of Indium (and Nitrogen) fraction.

FIGS. 22B and 22C show plots of semiconductor band gaps for GaInNAsSb having an In/Sb ratio of 6 as a function of In fraction for several different N fractions within the alloy.

FIG. 23 shows a configuration of various layers of a dilute nitride based solar subcell.

FIG. 24 shows a configuration with labels representing exemplary ranges of thicknesses for various layers of a dilute nitride subcell containing graded doping in a base layer.

FIG. 25 shows a configuration with labels representing how a dilute nitride base layer with both constant doping for one sub-region and graded doping for another sub-region.

FIG. 26 is a graph of an exemplary doping profile in a base layer of a dilute nitride subcell of a structure.

FIG. 27 is a graph of an exemplary doping profile of a dilute nitride subcell that contains constant doping in the front portion of the base layer and exponential doping in the back portion of the base layer.

FIG. 28 is a graph of exemplary doping profiles of a dilute nitride subcell including graded doping in an emitter layer.

FIG. 29 is a graph comparing quantum efficiency of a dilute nitride subcell with graded doping in a base layer with that of a subcell without graded doping.

FIG. 30 is a graph illustrating a measured current versus voltage characteristic for a short circuit current and an open circuit voltage for a dilute nitride subcell having graded doping in a base layer with that of one not having graded doping in the base layer.

FIG. 31 shows a substrate comprising a lattice-engineered layer over a silicon substrate, the lattice-engineered layer having lattice parameter matching/nearly matching GaAs.

FIG. 32 shows a lattice engineered layer that includes a (graded) SixGe1-x, layer.

FIG. 33 shows a lattice engineered layer that includes rare earth containing layer.

FIG. 34 shows a side view of a semiconductor optoelectronic device.

FIG. 35 shows a side view of a semiconductor optoelectronic device.

FIG. 36 shows a side view of a photodetector.

FIG. 37 is a schematic diagram showing hybrid integration of a detector array chip with an array of readout circuits on an ROIC chip.

FIG. 38 is an x-ray diffraction scan of a dilute nitride layer GaInNAsSb layer formed on a GaAs substrate.

FIG. 39 is an x-ray diffraction scan of a dilute nitride layer GaInNAsSb layer formed on a GaAs substrate.

FIG. 40 is a photoluminescence spectrum for a GaInNAsSb layer grown on a GaAs substrate.

FIG. 41 is a photoluminescence spectrum for a GaInNAsSb layer grown on a GaAs substrate.

FIG. 42 is a photoluminescence spectrum for a GaInNAsSb layer grown on a GaAs substrate.

FIG. 43A is a scanning electron microscopy image of an etched mesa for a dilute nitride photodetector.

FIG. 43B is a scanning electron microscopy image of an array of photodetectors.

FIG. 44 depicts measured responsivity curves for photodetectors.

FIG. 45 shows an embodiment of a monolithic multijunction power converter in which E₁, E₂, and E₃ represent semiconductor materials having the same band gap.

FIG. 46A shows a single junction resonant power converter with dual distributed Bragg reflectors (DBRs).

FIG. 46B shows a triple junction resonant power converter with dual distributed Bragg reflectors (DBRs).

FIG. 47A shows a single junction resonant power converter with single distributed Bragg reflectors (DBRs).

FIG. 47B shows a triple junction resonant power converter with single distributed Bragg reflectors (DBRs).

FIG. 48A shows a single junction resonant power converter with a top distributed Bragg reflector (DBR) and a back mirror.

FIG. 48B shows a triple junction resonant power converter with a top DBR and a back mirror.

FIG. 49A shows a single junction resonant power converter with a back mirror.

FIG. 49B shows a triple junction resonant power converter with a back mirror.

FIG. 50A shows a single junction resonant power converter with two distributed Bragg reflectors (DBRs) and a top substrate.

FIG. 50B shows a triple junction resonant power converter with two distributed Bragg reflectors (DBRs) and a top substrate.

FIG. 51A shows a single junction resonant power converter with a substrate overlying a top distributed Bragg reflector (DBR) and a back mirror.

FIG. 51B shows a triple junction resonant power converter with a substrate overlying a top distributed Bragg reflector (DBR) and a back mirror.

FIG. 52A shows a single junction resonant power converter with two distributed Bragg reflectors DBRs and etched back contacts to lateral conducting layers (LCL).

FIG. 52B shows a triple junction resonant power converter with two distributed Bragg reflectors (DBRs) and etched back contacts to lateral conducting layers (LCL).

FIG. 53 shows a top view of a Pi structure having multiple power converters interconnected in series.

FIG. 54A shows triple junction power converters having a double pass configuration and characterized by a single area or four quadrant area.

FIG. 54B shows triple junction power converters having a double pass configuration and characterized by a single area or four quadrant area.

FIG. 55A is a photograph of a top view of a triple junction power converter.

FIG. 55B is a photograph of a top view of triple junction power converters.

FIG. 56 shows efficiency, power output, and voltage at a maximum power point (Mpp) as a function of laser input power for single, double, and triple lattice-matched GaInNAsSb junction power converters.

FIG. 57 shows normalized density of current (J) as a function of voltage for several laser input power levels for single, double, and triple lattice-matched GaInNAsSb junction power converters.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

The term “lattice matched” as used herein means that the two referenced materials have the same lattice constant or a lattice constant differing by up to +/−0.2%. For example, GaAs and AlAs are lattice matched, having lattice constants differing by 0.12%.

The term “pseudomorphically strained” as used herein means that layers made of different materials with a lattice constant difference up to +/−2% can be grown on top of a lattice matched or strained layer without generating misfit dislocations. The lattice parameters can differ, for example, by up to +/−1%, by up to +/−0.5%, or by up to +/−0.2%.

The term “layer” as used herein, means a continuous region of a material (e.g., an alloy) that can be uniformly or non-uniformly doped and that can have a uniform or a non-uniform composition across the region.

The term “band gap” as used herein is the energy difference between the conduction and valence bands of a material.

The term “responsivity” as used herein is the ratio of the generated photocurrent to the incident light power at a given wavelength.

A. Dilute Nitride Materials in an Absorber/Active Layer

“III-AsNV” materials are herein defined to be alloys of elements from group IIIA (i.e., B, Al, Ga, In, Tl) and group VA (i.e., N, P, As, Sb, Bi) of the periodic table, which alloys include As, N and at least one additional element from Sb and Bi. In certain embodiments, the at least one additional element is Sb. In certain embodiments, the at least one additional element is Bi. The alloys may comprise approximately one-half group IIIA elements and one-half group-VA elements. An element may only be considered to be part of the alloy if it is present in an atomic composition of at least 0.05%. Thus, dopants used to create n-type or p-type conductivity (e.g., Mg, Be, Si or Te) are not considered to be part of the alloy. Examples of III-AsNV materials include GaNAsSb, GaInNAsSbBi, and AlInGaNAsSb. In certain embodiments, a III-AsNV material is an alloy of one or more elements from group III on the periodic table, nitrogen, arsenic, and at least one element selected from Sb and Bi. The expression “elements from group III on the periodic table” as used herein refers to one or more elements from group III on the periodic table. For example, in certain embodiments, an alloy comprises one element from group III on the periodic table, and in certain embodiments, more than one element from group III on the periodic table, such as two elements from group III on the periodic table.

III-AsNV materials are advantageous as solar cell materials for optoelectronic and other devices. Such devices may include, for example, solar cells, optical detectors and eye-safe power converters and the like. These materials are advantageous because the lattice constants can be varied to be substantially matched to a broad range of substrates, subcells, and/or other structural device elements, that may be formed from other than III-AsNV materials. Their lattice constants can be controlled by the relative fractions of the different group IIIA and group VA elements. Thus, by tailoring the compositions (i.e., the elements and quantities) of III-AsNV materials, a wide range of lattice constants and band gaps may be obtained. Further, high quality material may be obtained by optimizing the composition around a specific lattice constant and band gap, while limiting the total Sb and/or Bi composition to no more than 20 percent of the Group V lattice sites, in certain embodiments to no more than 3 percent of the Group V lattice sites, and in certain embodiments, to no more than 1 percent of the Group V lattice sites. The Sb and/or Bi are believed to act as surfactants to promote smooth growth morphology of the III-AsNV alloys. In addition, they facilitate uniform incorporation of nitrogen and minimize the formation of nitrogen-related defects. The incorporation of Sb and/or Bi enhances the overall nitrogen incorporation and reduces the alloy band gap, aiding the realization of lower band gap alloys. However, there are additional defects created by Sb and/or Bi; for this reason, their total concentration should be limited to no more than 20 percent of the Group V lattice sites. Further, the limit to the Sb and/or Bi composition decreases with decreasing nitrogen composition. Alloys that include In have even lower limits to the total composition of Sb and/or Bi because the In reduces the amount of Sb and/or Bi needed to tailor the lattice constant. For alloys that include In, the total composition of Sb and/or Bi may be limited to no more than 3 percent of the Group V lattice sites, and in certain embodiments, to no more than 1 percent of the Group V lattice sites. For example, Ga₁₋ₓInₓN_{y}As_{1-y-z}Sb_{z}, disclosed in U.S. Application Publication No. 2011-0232730, which is incorporated by reference, is known to have produced high quality material when substantially lattice-matched to a GaAs or Ge substrate and in the composition range of 0.08≤x≤0.18, 0.025≤y≤0.04 and 0.001≤z≤0.03, with a band gap of at least 0.9 eV. This material is used as the bottom subcell of the solar cell holding the world record for conversion efficiency as of the filing date of the priority provisional application.

In certain embodiments of the invention, the N composition is not more than 7 percent of the Group V lattice sites. In certain embodiments the N composition is not more than 4 percent and in certain embodiments, not more than 3 percent.

Embodiments present invention include optoelectronic devices, such as solar cells, photodetectors, and power converters that each include a dilute nitride layer. According to embodiments of the present invention, compound semiconductor optoelectronic devices may include a substrate; a first doped III-V layer overlying the substrate; an active region (also referred to as an “active layer”, an “absorber layer” or a “dilute nitride absorber layer”) overlying the first doped III-V region, where, the active region includes a lattice matched or pseudomorphic dilute nitride layer; and a second doped III-V layer overlying the active region.

The dilute nitride layer may have a composition of Ga₁₋ₓInₓN_{y}As_{1-y-z}Sb_{z}, where 0≤x≤1, 0<y≤1 and 0<z≤1. In certain embodiments of the present invention, this dilute nitride layer composition may be tuned in to target particular band gap ranges. In certain embodiments of the present invention, the dilute nitride layer can have a composition of Ga₁₋ₓInₓN_{y}As_{1-y-z}Sb_{z}, where 0≤x≤0.55, 0≤y≤0.1 and 0<z≤0.1. More preferably, 0≤x≤0.4, 0<y≤0.07 and 0<z≤0.04, or 0.01≤x≤0.4, 0.02≤y≤0.07 and 0.001≤z≤0.04. A low antimony content relative to indium is preferred to achieve desirable characteristics of the dilute nitride layer, according to some embodiments. For example, the dilute nitride layer can have a composition—where 0.13≤x≤0.19, 0.03≤y≤0.048, and 0.007≤z≤0.02—to achieve an In/Sb ratio of approximately 6.5 or greater.

In some embodiments described herein, the dilute nitride layer may have a band gap within a range, for example, from 0.7 eV to 1.0 eV, or from 0.7. eV to 0.85 eV, or from 0.7 eV to 0.9 eV, or from 0.7 eV to 0.949 eV. Additionally, the dilute nitride layer, including the nitrogen content thereof, is formulated to reduce the level of defects and unintentional background doping. Thereby, a sufficient minority carrier lifetime within the dilute nitride material of an active layer can be achieved.

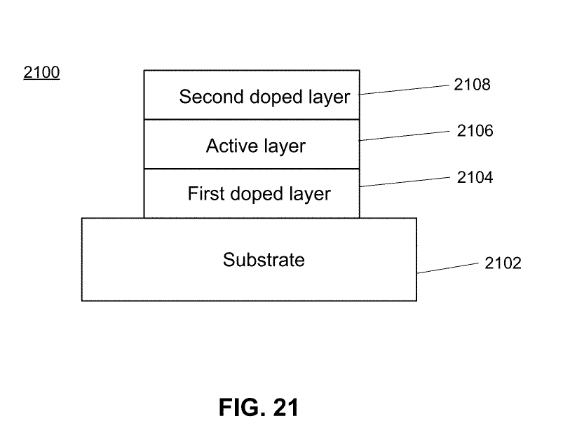

FIG. 21 shows a side view of an example of a semiconductor optoelectronic device 2100 according to embodiments of the present invention. Device 2100 (which may be, for example, a photodetector or other optoelectronic device) includes a substrate 2102, a first doped layer 2104, an active layer 2106, and a second doped layer 2108. For simplicity, each layer is shown as a single layer. However, it will be understood that each layer can include one or more layers with differing compositions, thicknesses, and doping levels to provide an appropriate optical and/or electrical functionality, and to improve interface quality, electron transport, hole transport and/or other optoelectronic properties.

Substrate 2102 can have a lattice constant that matches or nearly matches the lattice constant of GaAs or Ge. The substrate can be GaAs, in some embodiments. Substrate 2102 may be doped p-type, or n-type, or may be a semi-insulating (SI substrate). The thickness of substrate 2102 can be chosen to be any suitable thickness. Substrate 2102 can include one or more layers, for example, the substrate can include a Si layer having an overlying SiGeSn buffer layer that is engineered to have a lattice constant that matches or nearly matches the lattice constant of GaAs or Ge. This can mean the substrate has a lattice constant different than that of GaAs or Ge by less than or equal to 3%, less than 1%, or less than 0.5% of the lattice constant of GaAs or Ge.

First doped layer 2104 can have a doping of one type and the second doped layer 2108 can have a doping of the opposite type. If first doped layer 2104 is doped n-type, second doped layer 2108 is doped p-type. Conversely, if first doped layer 2104 is doped p-type, second doped layer 2108 is doped n-type. Examples of p-type dopants include C and Be. Examples of n-type dopants include Si and Te. Doped layers 2104 and 2108 are chosen to have a composition that is lattice matched or pseudomorphically strained to the substrate. The doped layers can include any suitable III-V material, such as GaAs, AlGaAs, GaInAs, GaInP, GaInPAs, GaInNAs, or GaInNAsSb. The band gap of the doped layers can be selected to be larger than the band gap of active layer 2106. Doping levels can be within a range from 1×10¹⁵ cm⁻³ to 2×10¹⁹ cm⁻³. Doping levels may be constant within a layer, and/or the doping profile may be graded, for example, increasing the doping level from a minimum value to a maximum value as a function of the distance from the interface between the doped layer and the active layer. Doped layers 2104 and 2108 can have a thickness within a range from 50 nm to 3 μm.

Active layer 2106 can be lattice matched or pseudomorphically strained with respect to the substrate and/or the doped layers. The band gap of active layer 2106 can be lower than that of the doped layers 2104 and 2108. Active layer 2106 includes a layer capable of processing light over a desired wavelength range. Processing is defined to be a light emission, a light receiving, a light sensing, and light modulation.

Active layer 2106 can include a dilute nitride material. A dilute nitride material can be Ga₁₋ₓInₓN_{y}As_{1-y-z}Sb_{z}, where x, y, and z can be 0≤x≤0.4, 0<y≤0.07 and 0<z≤0.04, respectively. Values for x, y and z can be 0.01≤x≤0.4, 0.02≤y≤0.07 and 0.001≤z≤0.04, respectively. Active layer 2106 can have a band gap within a range from 0.7 eV and 1.1 eV such that the active layer can absorb or emit light at wavelengths up to 1.8 μm. Bismuth (Bi) may be added as a surfactant during growth of the dilute nitride material, improving material quality (such as defect density), and the device performance. The thickness of active layer 2106 can be within a range from 0.2 μm to 10 μm. In some embodiments, the thickness of active layer 2106 can be within a range from 0.5 μm to 10 μm, 1 μm to 10 μm, 2 μm to 10 μm, 3 μm to 10 μm, 3 μm to 5 μm. In other embodiments, the thickness of active layer 2106 can be within a range from 0.5 μm to 5 μm and/or within a range from 1 μm to 4 μm. Active layer 2106 can be compressively strained with respect to the substrate 2102. Strain can improve device performance. For a photodetector, the parameters most relevant to device performance include the dark current, operating speed, noise, and responsivity.

Active layer 2106 and doped layers 2104 and 2108 form a p-i-n or an n-i-p junction. This junction provides the basic structure for operation of a device, such as a photodetector or a light-emitting diode. For photodetectors, p-i-n epitaxial structures can have low background doping in the intrinsic region (active layer) of the devices which are typically operated at 0 or very low bias (e.g., less than 2 V). Therefore, the active layer may not be deliberately doped. The active layer can be an intrinsic layer or an unintentionally doped layer. Unintentionally doped semiconductors do not have dopants intentionally added but can include a nonzero concentration of impurities that act as dopants. The carrier concentration of the active layer can be, for example, less than 1×10¹⁶ cm⁻³ (measured at room temperature), less than 5×10¹⁵ cm⁻³, or less than 1×10¹⁵ cm⁻³. The minority carrier lifetime within the material can be greater than 1 ns. The minority carrier lifetime can be affected by defects within the semiconductor that contribute to the background carrier concentration, as well as other defect types that can act as recombination centers but do not contribute carriers.

In solar cell embodiments, for example, the present invention includes multijunction solar cells with four or more subcells incorporating at least one III-AsNV subcell. The band gaps of the III-AsNV materials can be tailored by varying the compositions while limiting the overall composition of Sb and Bi. Thus, III-AsNV subcells with optimal band gaps for integrating with the other subcells may be fabricated while maintaining substantial lattice-matching to the other subcells. The band gaps and compositions of the III-AsNV subcells are tailored so that the short-circuit currents produced by the III-AsNV subcells will be the same as or slightly greater than the other subcells in the solar cell. Because the III-AsNV materials provide high quality, lattice-matched and band gap tunable subcells, the disclosed solar cells comprising III-AsNV subcells will reach conversion efficiencies exceeding those of triple junction solar cells. The boost in efficiency is largely due to less light energy being lost as heat, as the extra subcells allow more of the incident photons to be absorbed by materials with band gaps closer to the energy level of the incident photons. In addition, there will be lower series resistance losses in these multijunction solar cells compared with triple junction solar cells due to the lower operating currents. At higher concentrations of sunlight, the reduced series resistance losses become more pronounced. Depending on the band gap of the bottom subcell, the collection of a wider range of photons in the solar spectrum may also contribute to the efficiency boost.

Designs of multijunction solar cells with more than three subcells in the prior art predominantly rely on metamorphic growth structures, new materials, or dramatic improvements in the quality of existing subcell materials in order to predict structures that can achieve high efficiencies. Solar cells containing metamorphic buffer layers may have reliability concerns due to the potential for dislocations from the buffer layers to propagate over time into the subcells, causing degradation in performance. In contrast, III-AsNV materials can be used today in solar cells with more than three subcells to attain high efficiencies while maintaining substantial lattice-matching between subcells, which is advantageous for reliability. For example, Reliability testing on III-AsNV subcells provided by the present disclosure has shown that such devices survived the equivalent of 390 years of on-sun operation at 100° C. with no failures. The maximum degradation seen in these subcells was a decrease in open-circuit voltage of 1.2%.

For application in space, radiation hardness, which refers to minimal degradation in device performance when exposed to ionizing radiation including electrons and protons, is of great importance. Multijunction solar cells incorporating III-AsNV subcells of the present invention have been subjected to proton radiation testing to examine the effects of degradation in space environments. Compared to Ge-based triple junction solar cells, the results demonstrate that these III-AsNV containing devices have similar power degradation rates and superior voltage retention rates. Compared to non-lattice matched (metamorphic) triple junction solar cells, all metrics are superior for III-AsNV containing devices. In certain embodiments of the invention, the solar cells contain (Al)GaInPAs subcells to improve radiation hardness compared to (Al,In)GaAs subcells.

An enhanced simulation model was used to determine the designs and efficiencies of multijunction solar cells with 4, 5, or 6 subcells. The simulation relied upon the use of standard solar cell equations (see, for example, Nelson, The Physics of Solar Cells. London: Imperial College Press, 2003, pp. 145-176; or Kurtz et al., Journal of Applied Physics 68 (1990) 1890) to calculate quantum efficiency, dark current, current, and voltage for an individual subcell, independent of the surrounding subcells, and standard circuit equations for calculating the overall multijunction current-voltage curve from the current-voltage curves of the component subcells, including a single lumped series resistance element. When high illumination intensities (>10 W/cm²) were used in these simulations, the dark current was assumed to be dominated by the diffusion current; the contribution from Shockley-Read-Hall recombination in the depletion region was neglected. The simulation varied the band gaps, and thus compositions of the subcells, until the subcells were current-matched. (By current-matched, it is understood to mean that the current generating capacity is substantially the same for each subcell, which is defined as differing by no more than 2 percent and preferably not more than 1 percent. Note that in any multijunction solar cell with subcells connected in series, the current flowing through each subcell must necessarily be the same. It can be convenient, however, to talk about the short-circuit currents that would be produced by each individual subcell if the subcells were not connected in series, and as though the light to lower subcells was still filtered by the upper subcells. This is what is meant by reference to the current generating capacity of a subcell.) The subcell materials were specified in the simulation, and the band gaps, or the compositions, were varied within specified ranges for each given material alloy system. When the band gap of a given subcell hit the upper end of its allowed range but current-matching had not been achieved, the base thickness was reduced to achieve current-matching. When the band gap of a given subcell hit the lower end of its allowed range, the current-matching requirement was limited to the given subcell and those above it; lower subcells had higher current generating capacities. This is a distinct departure from earlier simulations of this type, which typically vary only the base thickness to match the currents between subcells. The simulation used for this invention is further distinct from other types of simulations in the prior art that vary the band gap of individual subcells to match currents but assume ideal or arbitrary material properties for some or all of the subcells. Such simulations in the prior art will give different results than the simulations employed here, which use experimentally determined material parameters for all subcells except for Ge. The simulation can be used to optimize band gap relationships and current-match for any incident spectrum of light energy, and at any reasonable operating temperature. The simulations used for the invention were carried out using the AM1.5D spectrum at temperatures between 25° C. and 90° C. as inputs. The simulations were run on Matlab software on a Windows operating system.

The simulation model was also used with the AM0 spectrum at 25° C. to predict the designs and efficiencies of multijunction solar cells with 4, 5, and 6 subcells for application in space. Because these simulations were run at 1 sun of illumination, the contribution to the dark current from Shockley-Read-Hall recombination in the depletion region was included. Depending on the application of interest, solar cells for space may be optimized for other operating temperatures and the resulting structures may change slightly from those here.

For the predictive simulations, a perfect anti-reflection coating (ARC) was assumed in order to reduce the computational expense of optimizing the ARC. This can cause the predictive efficiencies to be inflated by approximately two to four percent (e.g., 40.8% instead of 40.0%). For the simulation of existing single and triple junction solar cells, a realistic ARC was included in the simulation of solar cells having an ARC, in order to more accurately model the experimental results.

Unique to the simulation used for this invention is the use of accurate material parameters for the alloy systems of interest that are substantially lattice-matched to GaAs and Ge substrates, including (Al)InGaP, (Al,In)GaAs, and GaInNAsSb, an example of III-AsNV material. These material parameters can be used to predict, among other values, the quantum efficiency and the dark current. For these material systems, a range of compositions were found in which the primary effect on quantum efficiency and dark current was the change in band gap. As a result, the other material parameters could be treated as constant with accurate results. For example, for (Al)InGaP, the range of compositions in which the material parameters other than band gap could be treated as constant for subcells substantially lattice-matched to GaAs or Ge was x≤0.2 for AlₓIn_{0.5}Ga₁₋ₓP.

Material parameters for (Al)GaInPAs and SiGe(Sn) were not included in the simulation, but high efficiency solar cell structures using (Al)GaInPAs and SiGe(Sn) may be designed with the same methodology

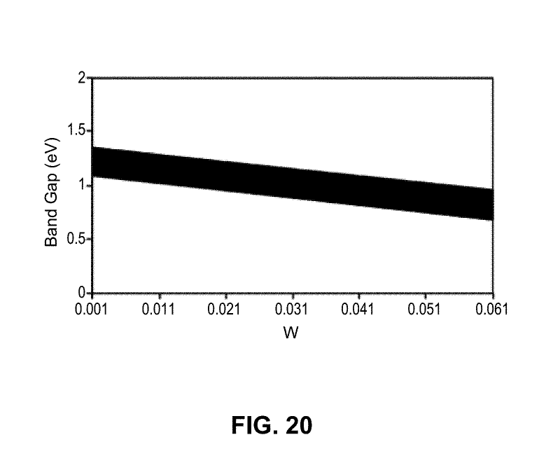

The material parameters for each material system in the simulation included the band gap, the n and k values (i.e., the refractive index), the hole and electron effective masses, the static dielectric constant, the minority carrier mobilities, the minority carrier lifetimes and the surface recombination velocities for interfaces with relevant materials. The n and k values were determined from ellipsometry measurements for some materials and taken from the literature for other materials, and were shifted as a function of band gap energy as necessary within a given alloy system. The effective masses and static dielectric constants were taken from the literature for (Al)InGaP and (Al,In)GaAs. For GaInNAsSb the values used were 0.6 m₀, 0.15 m₀ and 13.3 for the hole and electron effective masses and the static dielectric constant respectively, where m₀ is the electron effective mass. Material parameters were assumed to be constant with temperature in the range simulated, except for the band gap and the n and k values, which shifted with the band gap energy. The minority carrier mobilities were initially estimated from the majority carrier mobilities measured on uniformly doped layers using Hall effect measurements, and were refined by fitting experimental quantum efficiency data. The minority carrier lifetimes and surface recombination velocities were determined by time resolved photoluminescence measurements. For Ge, all material parameters were estimates based on available numbers in the literature. Average doping values and material parameters were used in the simulations to treat cases where doping values were graded throughout a layer. The doping values were between 1×10¹⁷ cm⁻³ and 1×10¹⁹ cm⁻³ for n-type layers and between 5×10¹⁵ cm⁻³ and 2×10¹⁸ cm⁻³ for the p-type layers, and were optimized for performance in experimental devices. The relationship between composition and band gap is well known for the (Al)InGaP and (Al,In)GaAs material systems lattice matched to GaAs and Ge, specifying the composition for a given band gap. The band gap of Ga₁₋ₓInₓN_{y}As_{1-y-z}Sb_{z} is not a simple function of composition due to interactions between the different elements, as well as factors such as the strain in the layer. The composition that yields a desired band gap with a specific lattice constant will be found by varying the composition in an optimization procedure. As an example, the relationship between band gap and composition w for Ga_{1.01-3w}In_{3w-0.01}N_{w}As_{0.99-w}Sb_{0.01} is shown in FIG. 20. Here, the Sb composition is fixed. Similar plots may be constructed for different Sb compositions or with other elements held constant.

The thermal dose, which is controlled by the intensity of heat applied for a given duration of time (e.g., application of a temperature of 600° C. to 900° C. for a duration of between 10 seconds to 10 hours), that a III-AsNV material receives during growth and after growth, also affects the relationship between band gap and composition. In general, the band gap increases as thermal dose increases.

As development continues on the above-described materials, it is expected that material quality will continue to improve, enabling even higher efficiencies from the same structures described in this invention. The simulation was also run with improved minority carrier properties to predict structures and performance of future devices.

The use of the simulation over the temperature ranges from 25° C. to 90° C. is supported by data for triple junction solar cells with a bottom GaInNAsSb subcell operating from 25° C. to 125° C.

As composition is varied within a given alloy system, the growth conditions need to be modified, as is well known to those skilled in the art. For example, for (Al,In)GaAs, the growth temperature will increase as the fraction of Al increases and decrease as the fraction of In increases, in order to maintain the same material quality. Thus, as a composition is changed, the growth temperature as well as other growth conditions can be adjusted accordingly

Tables 1A and 1B show the short-circuit current, open circuit voltage and fill factor from both simulated I-V curves and experimental data for Al_{0.1}In_{0.5}Ga_{0.4}P and In_{0.5}Ga_{0.5}P subcells, respectively, exposed to incident solar radiation of the stated intensity using an AM1.5D spectrum at 25° C. The close conformance between simulation and experimental results is a verification of the accuracy of the simulation. The number of suns listed for each table gives information about the illumination intensity incident on the cell during testing. It is the number of multiples of “one sun” intensity (0.1 W/cm²) incident on the cell. For example, the term “800 suns” indicates 80 W/cm². The numbers of suns differs for each case because the existing experimental data was taken at different intensities. The incident spectrum approximated the AM1.5D spectrum in the experimental measurements and was the AM1.5D spectrum in the simulations.

TABLE 1A
Simulated and experimental solar cell data for an Al_{0.1}In_{0.5}Ga_{0.4}P
subcell illuminated at 525 suns under the AM1.5D spectrum.

| | Al_{0.1}In_{0.5}Ga_{0.4}P Subcell at 525 Suns | | | |
|---|---|---|---|---|
| | Simulated Data | | Experimental Data | |
| Short-circuit current | 6.3 | A/cm² | 6.2 | A/cm² |
| Open-circuit voltage | 1.68 | V | 1.70 | V |

| | | |
|---|---|---|
| Fill Factor | 84% | 82% |

TABLE 1B
Simulated and experimental solar cell data for an In_{0.5}Ga_{0.5}P
subcell illuminated at 925 suns under the AM1.5D spectrum.

| | In_{0.5}Ga_{0.5}P Subcell at 925 Suns | | | |
|---|---|---|---|---|
| | Simulated Data | | Experimental Data | |
| Short-circuit current | 13.0 | A/cm² | 12.7 | A/cm² |
| Open-circuit voltage | 1.61 | V | 1.63 | V |

| | | |
|---|---|---|
| Fill Factor | 79% | 80% |

Tables 1C and 1D show the short-circuit current, open circuit voltage and fill factor from both simulated I-V curves and experimental data for Al_{0.1}In_{0.5}Ga_{0.4}P and In_{0.5}Ga_{0.5}P subcells under the air mass zero (AM0) spectrum. The incident spectrum approximated the AM0 spectrum at an intensity of 1,353 W/cm² at 25° C. in the experimental measurements and was the AM0 spectrum at 25° C. in the simulations. The close conformance between simulation and experimental results is a verification of the accuracy of the simulation.

TABLE 1C
Simulated and experimental solar cell data for an Al_{0.1}In_{0.5}Ga_{0.4}P
subcell illuminated under the AM0 spectrum.

| | Al_{0.1}In_{0.5}Ga_{0.4}P Subcell | | | |
|---|---|---|---|---|
| | Simulated Data | | Experimental Data | |
| Short-circuit current | 16.0 | mA/cm² | 16.2 | mA/cm² |
| Open-circuit voltage | 1.50 | V | 1.48 | V |

| | | |
|---|---|---|
| Fill Factor | 87% | 87% |

TABLE 1D
Simulated and experimental solar cell data for an In_{0.5}Ga_{0.5}P
subcell under the AM0 spectrum.

| | In_{0.5}Ga_{0.5}P Subcell | | | |
|---|---|---|---|---|
| | Simulated Data | | Experimental Data | |
| Short-circuit current | 18.1 | A/cm² | 17.7 | mA/cm² |
| Open-circuit voltage | 1.41 | V | 1.41 | V |

| | | |
|---|---|---|
| Fill Factor | 87% | 89% |

Tables 2A and 2B show analogous data for Al_{0.2}Ga_{0.8}As and GaAs subcells, respectively, and Tables 3A and 3B for Ga_{0.96}In_{0.04}N_{0.01}As_{0.98}Sb_{0.01} and Ga_{0.96}In_{0.1}N_{0.03}As_{0.96}Sb_{0.01} subcells, respectively, exposed to incident solar radiation of the stated intensity using an AM1.5D spectrum at 25° C.

TABLE 2A
Simulated and experimental solar cell data for an Al_{0.2}Ga_{0.8}As
subcell illuminated at 1130 suns under the AM1.5D spectrum.

| | Al_{0.2}Ga_{0.8}As Subcell at 1130 Suns | | | |
|---|---|---|---|---|
| | Simulated Data | | Experimental Data | |
| Short-circuit current | 10.3 | A/cm² | 10.4 | A/cm² |
| Open-circuit voltage | 1.46 | V | 1.43 | V |

| | | |
|---|---|---|
| Fill Factor | 85% | 83% |

TABLE 2B
Simulated and experimental solar cell data for a
GaAs subcell illuminated at 980 suns
under the AM 1.5D spectrum.

| | GaAs Subcell at 980 Suns | | | |
|---|---|---|---|---|
| | Simulated Data | | Experimental Data | |
| Short-circuit current | 17.2 | A/cm² | 17.1 | A/cm² |
| Open-circuit voltage | 1.22 | V | 1.22 | V |

| | | |
|---|---|---|
| Fill Factor | 78% | 80% |

TABLE 3A
Simulated and experimental solar cell data for a
Ga_{0.96}In_{0.04}N_{0.01}As_{0.98}Sb_{0.01} subcell
illuminated at 1230 suns under the AM1.5D spectrum.

| | Ga_{0.96}In_{0.04}N_{0.01}As_{0.98}Sb_{0.01} | | | |
|---|---|---|---|---|
| | Subcell at 1230 Suns | | | |
| | Simulated Data | | Experimental Data | |
| Short-circuit current | 6.5 | A/cm² | 6.6 | A/cm² |
| Open-circuit voltage | 0.84 | V | 0.82 | V |

| | | |
|---|---|---|
| Fill Factor | 81% | 77% |

TABLE 3B
Simulated and experimental solar cell data for a
Ga_{0.9}In_{0.1}N_{0.03}As_{0.96}Sb_{0.01} subcell
illuminated at 610 suns under the AM1.5D spectrum.

| | Ga_{0.9}In_{0.1}N_{0.03}As_{0.96}Sb_{0.01} | | | |
|---|---|---|---|---|
| | Subcell at 610 Suns | | | |
| | Simulated Data | | Experimental Data | |
| Short-circuit current | 9.5 | A/cm² | 9.3 | A/cm² |
| Open-circuit voltage | 0.59 | V | 0.60 | V |

| | | |
|---|---|---|
| Fill Factor | 71% | 70% |

Tables 2C and 2D show analogous data for Al_{0.2}Ga_{0.8}As and GaAs subcells, respectively; and Tables 3C and 3D show data for Ga_{0.96}In_{0.04}N_{0.01}As_{0.98}Sb_{0.01} and Ga_{0.96}In_{0.1}N_{0.03}As_{0.96}Sb_{0.01} subcells, respectively, under the AM0 spectrum at an intensity of 1,353 W/cm² at 25° C.

TABLE 2C
Simulated and experimental solar cell data for an
Al_{0.2}Ga_{0.8}As subcell under the AM0 spectrum.

| | Al_{0.2}Ga_{0.8}As Subcell | | | |
|---|---|---|---|---|
| | Simulated Data | | Experimental Data | |
| Short-circuit current | 10.3 | mA/cm² | 10.4 | mA/cm² |
| Open-circuit voltage | 1.23 | V | 1.18 | V |

| | | |
|---|---|---|
| Fill Factor | 85% | 83% |

TABLE 2D
Simulated and experimental solar cell data for a GaAs
subcell under the AM0 spectrum.

| | GaAs Sub cell | | | |
|---|---|---|---|---|
| | Simulated Data | | Experimental Data | |
| Short-circuit current | 18.9 | mA/cm² | 19.0 | mA/cm² |
| Open-circuit voltage | 1.01 | V | 1.00 | V |

| | | |
|---|---|---|
| Fill Factor | 83% | 85% |

TABLE 3C
Simulated and experimental solar cell data for a
Ga_{0.96}In_{0.04}N_{0.01}As_{0.98}Sb_{0.01} subcell
under the AM0 spectrum.

| | Ga_{0.96}In_{0.04}N_{0.01}As_{0.98}Sb_{0.01} Subcell | | | |
|---|---|---|---|---|
| | Simulated Data | | Experimental Data | |
| Short-circuit current | 7.5 | mA/cm² | 7.7 | mA/cm² |
| Open-circuit voltage | 0.61 | V | 0.57 | V |

| | | |
|---|---|---|
| Fill Factor | 76% | 77% |

TABLE 3D
Simulated and experimental solar cell data for a
Ga_{0.96}In_{0.1}N_{0.03}As_{0.96}Sb_{0.01} subcell
under the AM0 spectrum.

| | Ga_{0.96}In_{0.1}N_{0.03}As_{0.96}Sb_{0.01} Subcell | | | |
|---|---|---|---|---|
| | Simulated Data | | Experimental Data | |
| Short-circuit current | 18.2 | mA/cm² | 17.9 | mA/cm² |
| Open-circuit voltage | 0.40 | V | 0.41 | V |

| | | |
|---|---|---|
| Fill Factor | 70% | 71% |

Validation of the model was also performed by simulating the performance of a state-of-the-art multijunction solar cell comprising three subcells: In_{0.5}Ga_{0.5}P (1.9 eV), GaAs (1.4 eV), and Ga_{0.9}In_{0.1}N_{0.03}As_{0.96}Sb_{0.01} (1.0 eV), with the total subcell thicknesses being 1-2 μm, 4-4.5 μm and 2-3 μm, respectively. Table 4A shows the short-circuit current, open circuit voltage and fill factor of the simulated solar cell under the AM1.5D spectrum concentrated to 525 suns (or 52.5 W/cm²) at 25° C. Also shown is the measured performance of a solar cell with these characteristics and operating conditions. It can be seen that the model accurately predicts the measured performance.

TABLE 4A
Simulated and experimental solar cell data for a solar cell with
three subcells illuminated at 525 suns under the AM1.5D spectrum.

| | Solar Cell with 3 Subcells at 525 Suns | | | |
|---|---|---|---|---|
| | Simulated Data | | Experimental Data | |
| Short-circuit current | 7.3 | A/cm² | 7.3 | A/cm² |
| Open-circuit voltage | 3.37 | V | 3.40 | V |

| | | |
|---|---|---|
| Fill Factor | 87% | 86% |

Validation of the model was also performed by simulating the performance of a state-of-the-art multijunction solar cell comprising three subcells: Al_{0.1}In_{0.5}Ga_{0.4}P (2.0 eV), GaAs (1.4 eV), and Ga_{0.9}In_{0.1}N_{0.03}As_{0.96}Sb_{0.01} (1.0 eV), with the total subcell thicknesses being 0.75-1.25 μm, 3-4 μm and 2-3 μm, respectively, under the AM0 spectrum. Table 4B shows the short-circuit current, open circuit voltage, and fill factor of the simulated solar cell under the AM0 spectrum at 25° C. Also shown is the measured performance of a solar cell with these characteristics and operating conditions. The model accurately predicts the measured performance under the AM0 spectrum at 25° C.

TABLE 4B
Simulated and experimental solar cell data for a solar
cell with three subcells under the AM0 spectrum.

| | Solar Cell with 3 Subcells | | | |
|---|---|---|---|---|
| | Simulated Data | | Experimental Data | |
| Short-circuit current | 17.1 | mA/cm² | 16.7 | mA/cm² |
| Open-circuit voltage | 2.90 | V | 2.92 | V |

| | | |
|---|---|---|
| Fill Factor | 85% | 86% |

The model was then used to predict the structures of multijunction solar cells with 4, 5 and 6 subcells that exceed the efficiencies of known best three-junction solar cells. The subsequent paragraphs describe more general and more specific embodiments of the invention. In many cases, the structures were constrained to be substantially lattice-matched to GaAs and Ge substrates. All band gap ranges are given to one significant digit to the right of the decimal point. While the simulation predicts optimized structures where the subcells are typically current-matched, other design criteria (e.g., desired solar cell thickness) may lead to the modification of said structures, within the band gap ranges specified below.

Of note is that the embodiments of the invention disclosed below include multijunction solar cells with bottom subcells having band gaps greater than 0.8 eV, up to 1.1 eV. The prior art predominantly teaches that multijunction solar cells with more than 3 subcells should have a bottom subcell with a band gap less than or equal to 0.8 eV, in order to collect light over a broader fraction of the solar spectrum. Most commonly, the material composing the base of the bottom subcell in the prior art is Ge or InGaAs. Surprisingly, however, high efficiencies can be achieved from solar cells of the invention using a bottom III-AsNV subcell that has a band gap as high as 1.1 eV, due at least in part to the higher voltages and efficient current extraction of such subcells.

Another novel aspect of many of the embodiments disclosed below is the inclusion of two or three III-AsNV subcells of differing band gaps in a single multijunction solar cell. In these embodiments, at least one of the III-AsNV subcells has a band gap higher than has been previously achievable or suggested such as, for example, a band gap of 1.3 eV.

Also of note is that certain embodiments have a bottom III-AsNV subcell with a band gap lower than has been previously achievable for a III-AsNV alloy that is substantially lattice-matched to a substrate, such as, for example, a band gap of 0.8 eV.

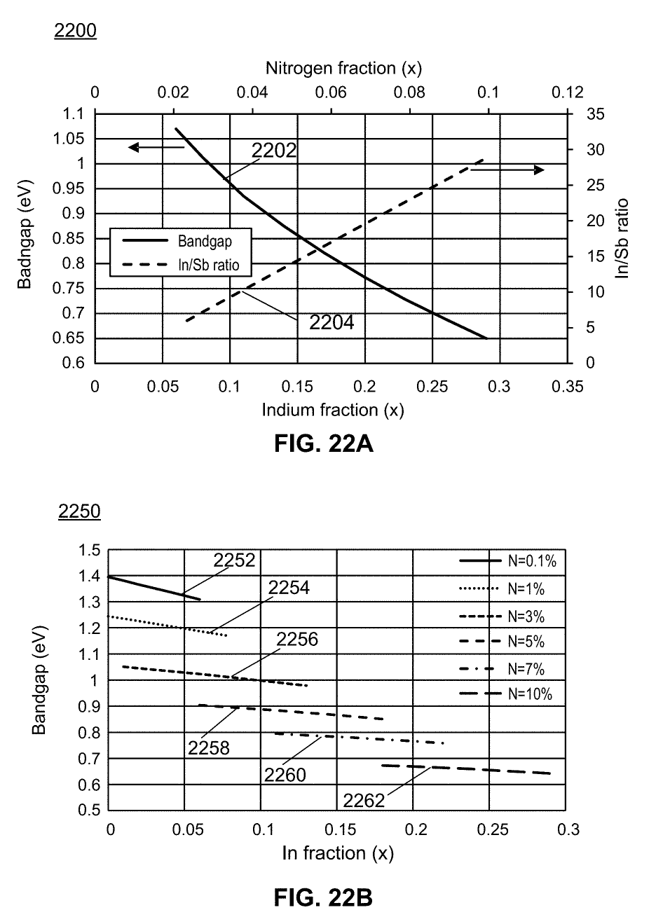

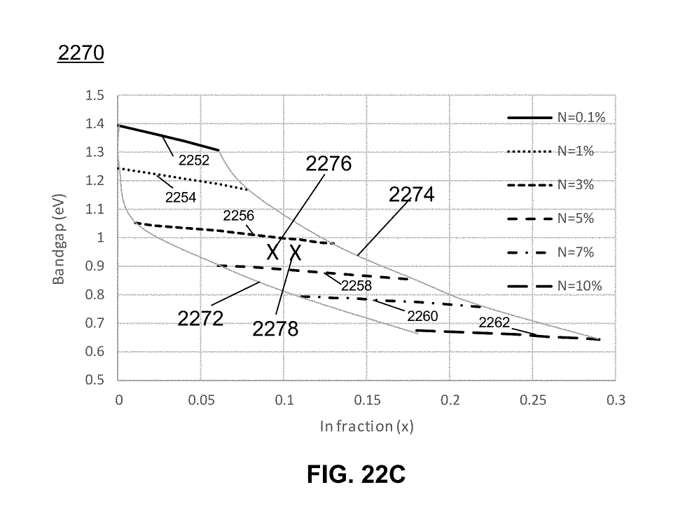

From the example in FIG. 20, in FIG. 22A, the band gap and In/Sb ratio are plotted as a function of indium mole fraction (and nitrogen mole fraction) within a GaInNAsSb alloy at a fixed Sb mole fraction of 1% based on a composition as described in FIG. 20 (i.e., Ga_{1.01-3w}In_{3w-0.01}N_{w}As_{0.99-w}Sb_{0.01}). The lower x-axis shows the indium mole fraction, while the upper x-axis shows the N mole fraction. The band gap of the material is shown in curve 2202 and varies between about 1.05 eV and 0.65 eV for In mole fractions between 0.06 (or 6%) and 0.29 (29%), corresponding to N mole fractions of about 0.023 (2.3%) and 0.1 (10%). The In/Sb ratio (curve 2204) varies between 6 and 29, as shown.

FIG. 22B shows a plot of semiconductor band gap for GaInNAsSb having an In/Sb ratio of 6 as a function of In mole fraction for several different N mole fractions within the alloy. In this illustrative example, the alloy compositions have a lattice constant that is within about 0.5% of the lattice constant of GaAs. Curve 2252 shows the band gap for material containing 0.1% N having band gaps between about 1.4 eV and 1.3 eV, curve 2254 shows the band gap for material containing 1% N having band gaps between about 1.25 eV and 1.16 eV, curve 2256 shows the band gap for material containing 3% N having band gaps between about 1.05 eV and 0.98 eV, curve 2258 shows the band gap for material containing 5% N having band gaps between about 0.9 eV and 0.85 eV, curve 2260 shows the band gap for material containing 7% N having band gaps between about 0.8 eV and 0.75 eV, and curve 2262 shows the band gap for material containing 10% N, having band gaps between about 0.67 eV and 0.64 eV. As can be seen from all curves, as the In mole fraction increases, while maintaining a constant In/Sb ratio, the band gap of the material decreases. It can also be seen from the sequence of curves from 2252 through to 2262 that increasing the N mole fraction also decreases the band gap. GaInNAsSb materials can cover a band gap range between about 0.65 eV and 1.4 eV.

The band gaps for these curves are shown for materials with a lattice constant within 0.5% of the lattice constant for GaAs, such that high-quality materials with low defect densities can be achieved, for layers with thicknesses greater than about 0.1 μm. Curve 2252 (0.1% N) shows the minimum In composition is about 0%, while the maximum In composition is about 6%, while curve 2262 (10% N) shows the minimum In composition is about 17.5% while the maximum In composition is about 29%. Increasing the N content in the alloy allows a higher In content to be achieved, while maintaining a close lattice match to the lattice constant of GaAs.

One of ordinary skill in the art will understand that a lattice matched material could be grown to be very thick, with the actual thickness being determined by the intended application. For example, lattice-matched distributed Bragg reflectors grown on GaAs, such as those grown for vertical cavity surface emitting lasers (VCSELs) and power converters are known to be grown with thicknesses in excess of 10 μm with high quality and low defect levels.

Turning now to FIG. 22C, the compositional boundary for dilute nitride materials with an In/Sb ratio of 6 and a lattice constant parameter within 0.5% of the lattice constant for GaAs is bound by curve 2252, curve 2262, curve 2272 and curve 2274. Within this range, multiple compositions are possible to allow a bandgap of approximately 0.95 eV. For example, point 2276 having an Indium fraction of 0.09, and a nitrogen fraction of about 0.039, or point 2278 having an indium fraction of 11% and a nitrogen fraction of about 0.037 both provide compositions with a bandgap of approximately 0.95 eV.

### B. Multijunction Solar Cells Including Dilute Nitride Materials in an Active Layer of a III-AsNV Subcell

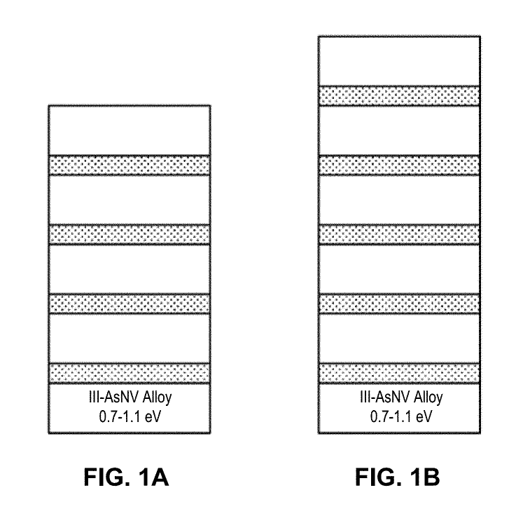

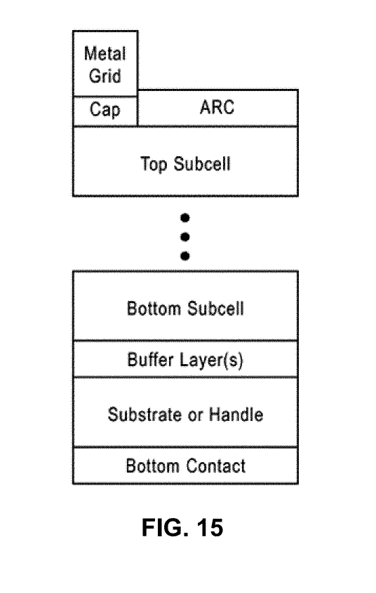

FIGS. 1A-1B, 2A-2B, 3A-3D, 6-7, 9-12, 13A-B, and 15-16, 17B, 18B, and 19B exemplify, in additional detail, certain embodiments of a 4, 5, and 6 multijunction solar cells according to the invention. For simplicity, FIGS. 1A-1B, 2A-2B, 3A-3D, 6-7, 9-12, 13A-B, 17B, 18B, and 19B show only the subcells and interconnecting tunnel junctions of the multijunction solar cells. As is well known to those skilled in the art, additional elements may be necessary to create a complete solar cell, including an anti-reflection coating, contact layers, electrical contacts and a substrate or wafer handle. As will be discussed below, FIG. 15 shows one example structure with these additional elements. Further, additional elements may be present in a complete solar cell, such as buffer layers and additional tunnel junctions. In some of the embodiments disclosed herein, the bottom subcell includes the substrate (e.g., a Ge subcell) and thus the substrate is shown in the figures. In other embodiments, the substrate is not part of a subcell, and is therefore typically not shown in the figures.

FIG. 1A depicts a multijunction solar cell according to the invention that has five subcells, with the bottom subcell being a III-AsNV subcell. All five subcells are substantially lattice-matched to each other and may be interconnected by four tunnel junctions, which are shown as dotted regions. The III-AsNV subcell at the bottom of the stack has the lowest band gap of the five subcells and absorbs the lowest-energy light that is converted into electricity by the solar cell. The band gap of the III-AsNV material in the bottom subcell is between 0.7-1.1 eV. The upper subcells may comprise any suitable III-V, II-VI, or group IV materials, including III-AsNV materials.

FIG. 1B depicts a multijunction solar cell according to the invention that has six subcells, with the bottom subcell being a III-AsNV subcell. All six subcells are substantially lattice-matched to each other and may be interconnected by five tunnel junctions, which are shown as dotted regions. The III-AsNV subcell has the lowest band gap of the six subcells. The band gap of the III-AsNV material in the bottom subcell is between 0.7-1.1 eV. The upper subcells may comprise any suitable III-V, II-VI, or group IV materials, including III-AsNV materials.

In certain embodiments, the band gap of the III-AsNV alloy in a bottom subcell is between 0.8-0.9 eV, and in other embodiments, between 0.9-1.0 eV. In certain embodiments, the composition of the base layer of a bottom III-AsNV subcell comprises Ga₁₋ₓInₓN_{y}As_{1-y-z}Sb_{z}, in which values for x, y and z are 0≤x≤0.24, 0.01≤y≤0.07 and 0.001≤z≤0.20, in certain embodiments, 0.02≤x≤0.24, 0.01≤y≤0.07 and 0.001≤z≤0.03, in certain embodiments, 0.02≤x≤0.18, 0.01≤y≤0.04 and 0.001≤z≤0.03, and in certain embodiments, 0.06≤x≤0.20, 0.02≤y≤0.05 and 0.005≤z≤0.02.

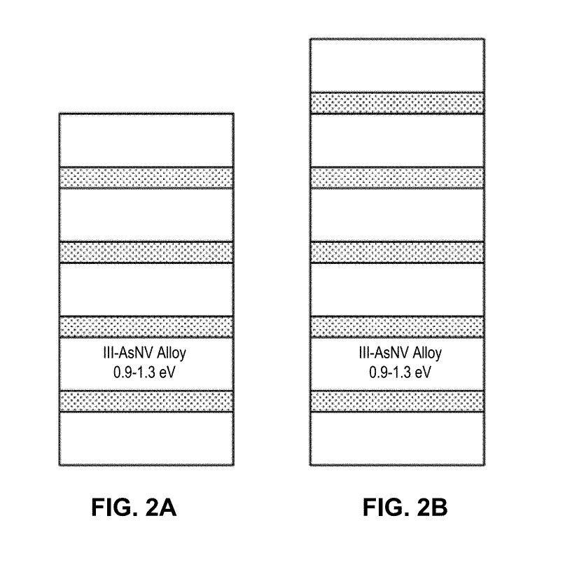

In the embodiment of the invention illustrated in FIG. 2A, a multijunction solar cell has five subcells, with J4, the subcell directly above the bottom subcell and the fourth subcell from the top, being a III-AsNV subcell. The band gap of the III-AsNV material in J4 is between 0.9-1.3 eV. All five subcells are substantially lattice-matched to each other and may be interconnected by four tunnel junctions, which are shown as dotted regions. The other four subcells may comprise any suitable III-V, II-VI, or group IV materials, including III-AsNV materials.

FIG. 2B shows a multijunction solar cell according to the invention that has six subcells, with J5, the subcell directly above the bottom subcell, being a III-AsNV subcell. The band gap of the III-AsNV material in the base of J5 is between 0.9-1.3 eV. All six subcells are substantially lattice-matched to each other and may be interconnected by five tunnel junctions, which are shown as dotted regions. The other five subcells may comprise any suitable III-V, II-VI or group IV materials, including III-AsNV materials.

In certain embodiments, the band gap of the III-AsNV alloy in the subcell directly above the bottom subcell is between 0.9-1.0 eV, and in certain embodiments, between 1.0-1.1 eV. In certain embodiments, the composition of the base layer of the subcell directly above the bottom subcell comprises Ga₁₋ₓInₓN_{y}As_{1-y-z}Sb_{z}, in which values for x, y and z are 0≤x≤0.18, 0.001≤y≤0.05 and 0.001≤z≤0.15, in certain embodiments 0≤x≤0.18, 0.001≤y≤0.05, and 0.001≤z≤0.03, and in certain embodiments 0.02≤x≤0.18, 0.005≤y≤0.04 and 0.001≤z≤0.03.

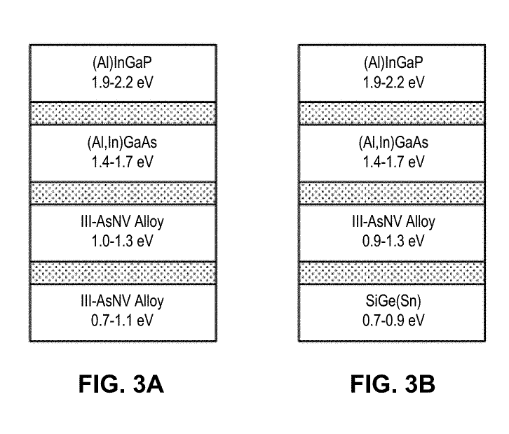

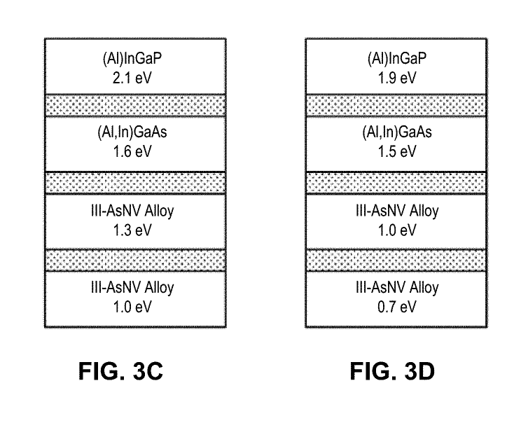

Another embodiment of the invention is shown in FIG. 3A. In this embodiment, there are four subcells, the two bottom subcells being III-AsNV subcells. The band gap of the bottom subcell, J4, is between 0.7-1.1 eV. The band gap of J3 is between 0.9-1.3 eV, or between 1.0-1.3 eV, and is greater than the band gap of J4. The subcell J2, directly above the two III-AsNV subcells, is an (Al,In)GaAs subcell with a band gap in the range of 1.4-1.7 eV. The top subcell J1 is an (Al)InGaP subcell with a band gap in the range of 1.9-2.2 eV. Examples of band gaps for the subcells, from bottom to top, are respectively 0.8-0.9 eV or 0.9-1.0 eV, 1.1-1.2 eV, 1.5-1.6 eV, and 1.9-2.0 or 2.0-2.1 eV. The band gaps and thicknesses of the subcells are most optimal when the currents produced by the four subcells are substantially the same. All of the subcells are substantially lattice-matched to each other and may be connected in series by tunnel junctions. In a similar embodiment of the invention, the structure is the same except that the subcell directly above the bottom subcell, J3, is a GaInNAs subcell. In another related embodiment, the structure is the same except that J2 is a (Al)GaInPAs subcell. In another, related embodiment that is depicted in FIG. 3B, J4 is a SiGe(Sn) subcell.

The specific band gaps of the subcells, within the ranges given in the preceding as well as subsequent embodiments, are dictated by the band gap of the bottom subcell, the thicknesses of the subcell layers, and the incident spectrum of light. Although there are numerous structures in the present disclosure that will produce efficiencies exceeding those of three junction solar cells, it is not the case that any set of subcell band gaps that falls within the disclosed ranges will produce such an efficiency. For a certain choice of bottom subcell band gap, or alternately the band gap of another subcell, incident spectrum of light, subcell materials and subcell layer thicknesses, there is a narrower range of band gaps for the remaining subcells that will produce efficiencies exceeding those of three junction solar cells. The band gaps may be found from the simulation and/or from experimentation. In general, the higher the band gap of the bottom subcell, the higher the band gaps of the upper subcells, within the specified ranges. FIGS. 3C and 3D illustrate this for the embodiment of the invention depicted in FIG. 3A using the AM1.5D spectrum. The band gap of the bottom subcell in FIG. 3C is higher than the band gap of the bottom subcell in FIG. 3D. Accordingly, the band gaps of the upper subcells in FIG. 3C are higher than the band gaps of the upper subcells, respectively, in FIG. 3D.

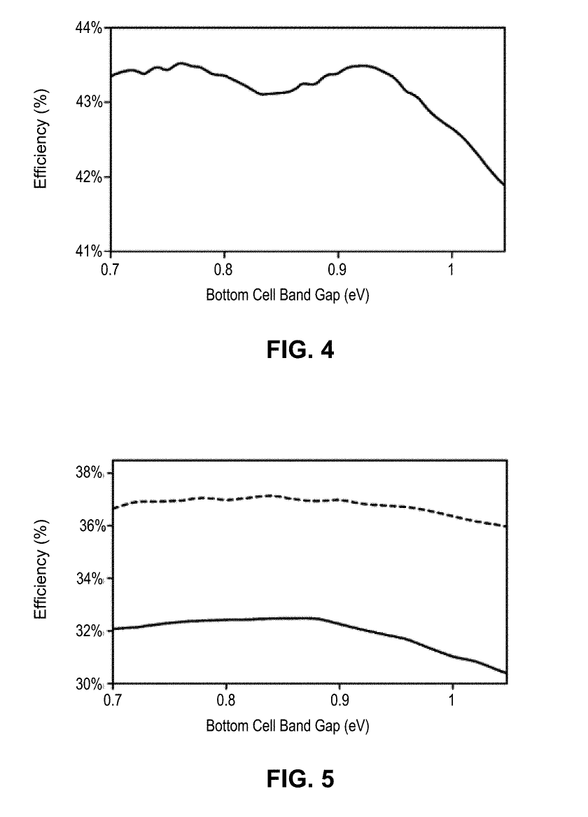

FIG. 4 shows the efficiencies predicted by the simulation as a function of the band gap of the bottom subcell for a specific embodiment of the invention depicted in FIG. 3A, under an illumination intensity of 100 W/cm² or 1000 suns at 25° C. In this embodiment, J4 and J3 are GaInNAsSb subcells with total subcell thicknesses of 2-3 microns, J2 is an (Al)GaAs subcell with a thickness of 4-5 microns and J1 is an (Al)InGaP subcell with a thickness of 1-2 microns. The trend in efficiency with bottom band gap has two peaks, near band gaps of 0.75 eV and 0.92 eV, which is largely a result of the variation in solar spectrum irradiance in the energy range between 0.7 eV and 1 eV. In all cases shown, the efficiency is higher than the simulated efficiency for the state-of-the-art triple junction solar cell structure under the same conditions (40.8%).

FIG. 5 shows the efficiencies predicted by the simulation as a function of the band gap of the bottom subcell for a specific embodiment of the invention depicted in FIG. 3A, under the AM0 spectrum at 25° C. In this embodiment, the bottom two subcells are GaInNAsSb subcells with total subcell thicknesses of 2-3 microns, J2 is an (Al)GaAs subcell with a thickness of 3-4 microns and J1 is an (Al)InGaP subcell with a thickness of 0.5-1.5 microns. The solid line shows the efficiencies predicted for solar cells made with today's material parameters, and the dashed line shows predicted future efficiencies with improvements in material quality that increase minority carrier lifetime and improve interface recombination velocities. The trend in today's efficiencies with bottom subcell band gap peaks near 0.90 eV. The efficiency increases as the bottom band gap decreases because more of the solar spectrum is absorbed until the upper band gap limit for the top subcell is reached. At this point, the simulation fixes the top subcell band gap and decreases the top subcell thickness to reach current matching between subcells. This causes the overall efficiency to decrease. In all cases shown, the efficiency is higher than the simulated efficiency for the triple junction solar cell structure under the same conditions.

Another embodiment of the invention has four subcells, with the bottom subcell being a III-AsNV subcell. The band gap of the bottom subcell, J4, is between 0.9-1.1 eV. The subcell J3 is an (Al,In)GaAs or an (Al)GaInPAs subcell with a band gap between 1.4-1.5 eV. The subcell J2 is an Al(In)GaAs or an (Al)GaInPAs subcell with a band gap in the range of 1.6-1.8 eV. The top subcell J1 is an (Al)InGaP subcell with a band gap in the range of 1.9-2.3 eV. Examples of band gaps for the subcells, from bottom to top, are respectively 1.0 eV, 1.4 eV, 1.7 eV, and 2.1 eV.

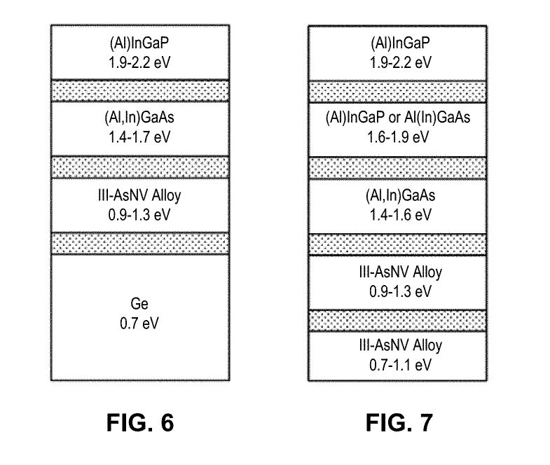

FIG. 6 illustrates another embodiment of the invention with four subcells. J3, directly above the bottom subcell, is a III-AsNV subcell with a band gap in the range of 0.9 eV-1.3 eV. The bottom subcell is a Ge subcell, incorporating the Ge substrate, which has a band gap of 0.7 eV. J2 is an (Al)InGaAs or (Al)GaInPAs subcell with a band gap in the range of 1.4 eV-1.7 eV. J1 is an (Al)InGaP subcell with a band gap in the range of 1.9 eV-2.2 eV. Examples of band gaps for the subcells above the Ge subcell, from bottom to top, are respectively, 1.0 eV-1.1 eV, 1.4 eV-1.5 eV, and 1.9 eV-2.0 eV. All of the subcells are substantially lattice-matched to the Ge substrate and may be connected in series by tunnel junctions.

FIG. 7 depicts an embodiment of the invention with five subcells. The bottom two subcells are III-AsNV subcells. The band gap of the bottom subcell is between 0.7 eV-1.1 eV. The band gap of J4, the subcell second from the bottom, is between 0.9 eV-1.3 eV, or between 1.0-1.3 eV, and is greater than or equal to the band gap of the bottom subcell. J3, the subcell above the III-AsNV subcells, is an (Al,In)GaAs subcell with a band gap in the range of 1.4 eV-1.6 eV. J2 is an Al(In)GaAs or an (Al)InGaP subcell with a band gap in the range of 1.6 eV-1.9 eV. The top subcell is an (Al)InGaP subcell with a band gap in the range of 1.9-2.2 eV. Examples of band gaps for subcells from bottom to top are, respectively, 0.9 eV-1.0 eV, 1.1 eV-1.2 eV, 1.4 eV-1.5 eV, 1.7 eV-1.8, and 1.9 eV-2.1 eV. All of the subcells are substantially lattice-matched to each other and may be connected in series by tunnel junctions. In a related embodiment of the invention, the structure is the same except that J4 is a GaInNAs subcell. In another related embodiment, the structure is the same except that one or both of J2 and J3 is an (Al)GaInPAs subcell. In an additional related embodiment, the bottom subcell is a SiGe(Sn) subcell.

In another embodiment of the invention, the bottom three subcells are III-AsNV subcells. The band gap of the bottom subcell, J5, is between 0.7 eV-1.0 eV. The band gap of J4 is between 0.9 eV-1.2 eV and is greater than the band gap of J5. J3 is a III-AsNV subcell with a band gap in the range of 1.2 eV-1.4 eV. J2 is an Al(In)GaAs, (Al)InGaPAs or InGaP subcell with a band gap in the range of 1.6 eV-1.8 eV. The top subcell, J1, is an (Al)InGaP subcell with a band gap in the range of 1.9 eV-2.2 eV. In certain embodiments, band gaps for the subcells, from bottom to top, respectively, are 0.7 eV-0.8 eV, 0.9 eV-1.1 eV, 1.2 eV-1.3 eV. 1.6 eV-1.7 eV, and 2.0 eV-2.1 eV. The subcells may be substantially lattice-matched to each other and connected in series by tunnel junctions. In a related embodiment of the invention, the structure is the same except J3 and/or J4 is a GaInNAs subcell.

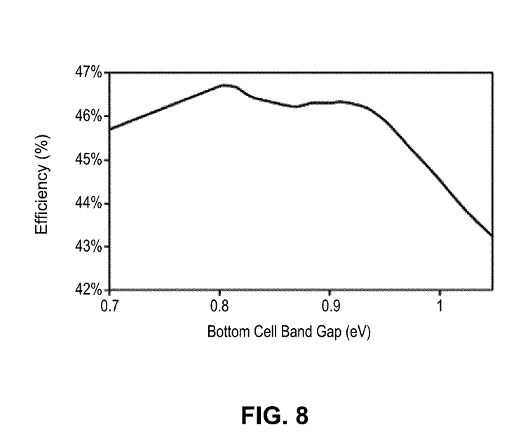

FIG. 8 shows the efficiencies predicted by the simulation as a function of the band gap of the bottom subcell for a specific embodiment of the invention depicted in FIG. 7 under an illumination intensity of 100 W/cm² or 1000 suns of the AM1.5D spectrum at 25° C. In this embodiment, the bottom two subcells are GaInNAsSb subcells with total subcell thicknesses of 2-3 microns, J3 and J2 are (Al)GaAs subcells with thicknesses of 4-5 microns and the top subcell is an (Al)InGaP subcell with a thickness up to 1.5 microns. The trend in efficiency with bottom band gap has two peaks, near 0.80 eV and 0.92 eV, which is a result of at least two factors. One is the variation in solar spectrum irradiance in the energy range between 0.7 eV and 1 eV. Another factor is the limitation on composition (x≤0.2 for AlₓIn_{0.5}Ga₁₋ₓP) and thus band gap for the AlInGaP subcell. When the band gap reaches the upper limit, the efficiency begins to decrease because the limitation on band gap places a limitation on the solar cell voltage. In all cases shown, the measured efficiency is higher than the simulated efficiency for the state-of-the-art triple junction solar cell structure under the same conditions.

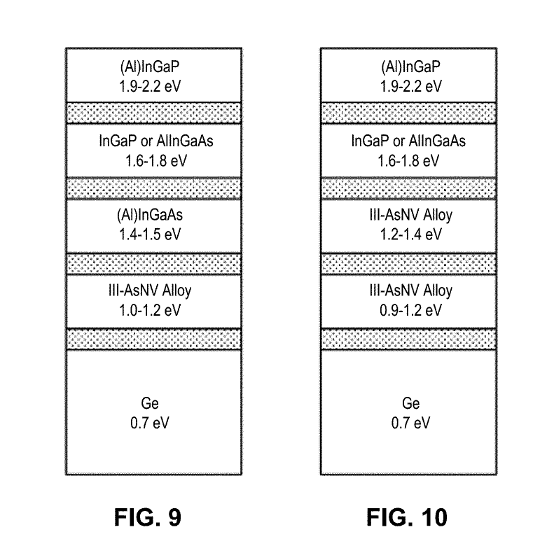

In FIG. 9 is shown another embodiment of the invention with five subcells. The bottom subcell is a Ge subcell, incorporating the Ge substrate. J4, the subcell directly above the Ge subcell, is a III-AsNV subcell with a band gap between 1.0 eV-1.2 eV. J3, above the III-AsNV subcell, is an (Al)InGaAs subcell with a band gap in the range of 1.4 eV-1.5 eV. J2 is an AlInGaAs or an InGaP subcell with a band gap in the range of 1.6 eV-1.8 eV. J1 is an (Al)InGaP subcell with a band gap in the range of 1.9 eV-2.2 eV. Examples of band gaps for the subcells above the Ge subcell, from the bottom to the top are, respectively, 1.0 eV-1.1 eV, 1.4 eV, 1.6 eV-1.7 eV, and 2.0-2.1 eV. All of the subcells are substantially lattice-matched to each other and may be connected in series by tunnel junctions. In a related embodiment, the structure is the same except that one or both of J2 and J3 is an (Al)GaInPAs subcell.

Yet another embodiment of the invention with five subcells is depicted in FIG. 10. The bottom subcell is a Ge subcell, incorporating the Ge substrate. J4 is a III-AsNV subcell with a band gap between 0.9 eV-1.0 eV or between 1.0 eV-1.2 eV. J3 is a III-AsNV subcell with a band gap in the range of 1.2 eV-1.4 eV. J2 is an AlInGaAs or an InGaP subcell with a band gap in the range of 1.6 eV-1.8 eV. The top subcell is an (Al)InGaP subcell with a band gap in the range of 1.9 eV-2.2 eV. Examples of band gaps for the subcells above the Ge subcell, from bottom to top, are, respectively 1.0 eV-1.1 eV, 1.3 eV, 1.6 eV-1.7 eV and 2.0-2.1 eV. All of the subcells are substantially lattice-matched to each other and may be connected in series by tunnel junctions. In a related embodiment of the invention, the structure is the same except that J3 is a GaInNAs subcell. In another related embodiment, the structure is the same except that J2 is a (Al)GaInPAs subcell.

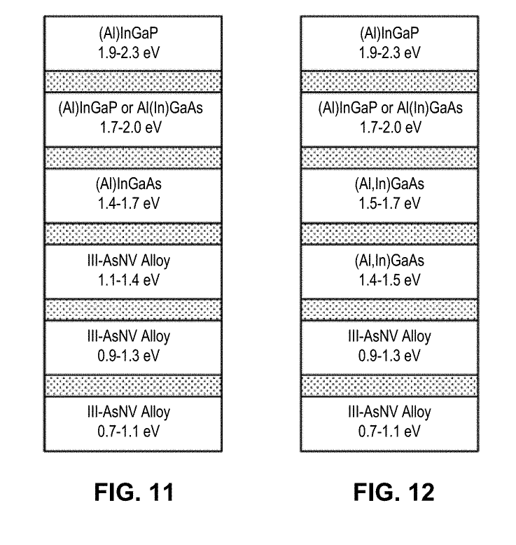

Embodiments of the invention with six subcells are illustrated in FIGS. 11, 12, 13A, and 13B.

In FIG. 11, the bottom three subcells are III-AsNV subcells. The band gap of the bottom subcell, J6, is between 0.7 eV-1.1 eV. The band gap of J5 is between 0.9-1.3 eV and is greater than or equal to the band gap of the bottom subcell. The band gap of J4 is between 1.1-1.4 eV and is greater than or equal to the band gap of J5. Above the III-AsNV subcells is J3, which is an (Al,In)GaAs subcell with a band gap in the range of 1.4-1.7 eV. J2 is an Al(In)GaAs or an (Al)InGaP subcell with a band gap in the range of 1.7-2.0 eV. The top subcell is an (Al)InGaP subcell with a band gap in the range of 1.9-2.2 eV or 2.2-2.3 eV. Examples of band gaps for the subcells from bottom to top are, respectively, 0.9-1.0 eV, 1.1-1.2 eV, 1.3-1.4 eV, 1.5-1.6 eV, 1.8-1.9 eV, and 2.0-2.1 eV. As another example, the band gaps of the subcells from bottom to top are, respectively, 0.7-0.8 eV, 0.9-1.0 eV, 1.1-1.2 eV, 1.4-1.5 eV, 1.7-1.8 eV, and 2.1-2.2 eV. All of the subcells are substantially lattice-matched to each other and may be connected in series by tunnel junctions. In a related embodiment of the invention, the structure is the same except that one or both of J4 and J5 are GaInNAs subcell(s). In a related embodiment, the structure is the same except that one or both J2 and J3 is a (Al)GaInPAs subcell. In an additional related embodiment, the structure is the same except the bottom subcell is a SiGe(Sn) subcell.

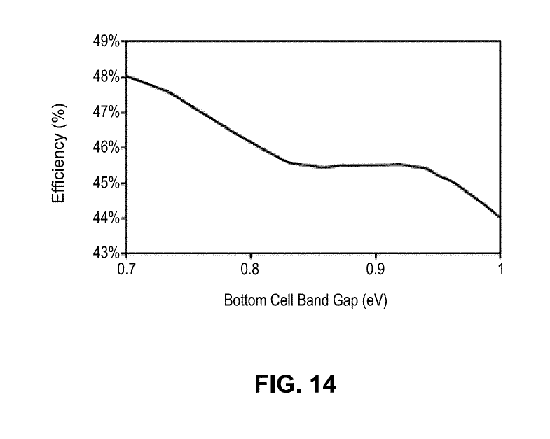

FIG. 14 shows the efficiencies predicted by the simulation as a function of the band gap of the bottom subcell for a specific embodiment of the invention depicted in FIG. 11 under an illumination intensity of 100 W/cm² or 1000 suns under the AM1.5D spectrum at 25° C. In this embodiment, the three bottom subcells are GaInNAsSb subcells each with a total subcell thicknesses of 2-3 microns, the J2 and J3 are (Al)GaAs subcells each with a thickness of 4-5 microns, and J1 is an (Al)InGaP subcell with a thickness up to 1.5 microns. In all cases shown, the efficiency is higher than the simulated efficiency for the state-of-the-art triple junction solar cell structure under the same conditions.

In FIG. 12, the bottom two subcells are III-AsNV subcells. The band gap of the bottom subcell, J6, is between 0.7-1.1 eV. The band gap of J5 is between 0.9-1.3 eV and is greater than or equal to the band gap of J6. The band gap of J4 is between 1.4-1.5 eV and it is an (Al,In)GaAs subcell. J3 is an (Al,In)GaAs subcell with a band gap in the range of 1.5-1.7 eV. J2 is an Al(In)GaAs or an (Al)InGaP subcell with a band gap in the range of 1.7-2.0 eV. J1 is an (Al)InGaP subcell with a band gap in the range of 1.9-2.2 eV or 2.2-2.3 eV. Examples of band gaps for the subcells, from bottom to top, are, respectively, 0.9-1.0 eV, 1.1-1.2 eV, 1.4 eV, 1.6-1.7 eV, 1.8-1.9 eV, and 2.0-2.1 eV. All of the subcells are substantially lattice-matched to each other and may be connected in series by tunnel junctions. In a related embodiment of the invention, the structure is the same except that J5 is a GaInNAs subcell. In a related embodiment, the structure of a photovoltaic cell is the same as in FIG. 12 except that one or more of J2, J3, and J4 is a (Al)GaInPAs subcell. In an additional related embodiment, the bottom subcell is a SiGe(Sn) subcell.

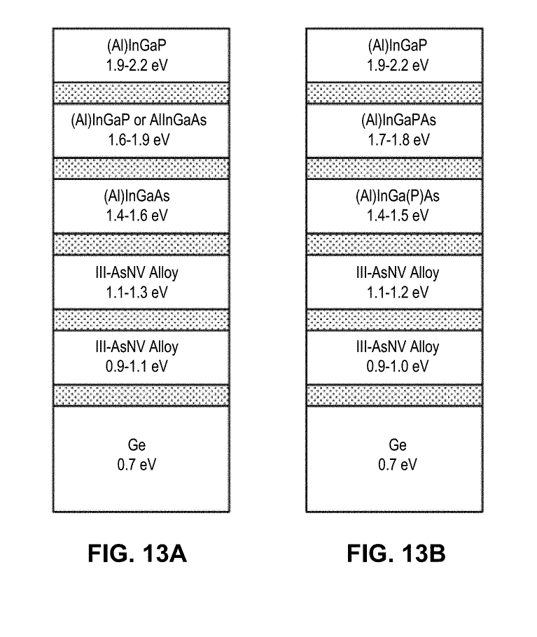

FIG. 13A depicts an embodiment of the invention where the bottom subcell comprises the Ge substrate. J4 and J5 are III-AsNV subcells. The band gap of J5 is between 0.9-1.1 eV. The band gap of J4 is between 1.1-1.3 eV and is greater than or equal to the band gap of the bottom subcell. J3 is an (Al)InGaAs subcell with a band gap in the range of 1.4-1.6 eV. J2 is an AlInGaAs or an (Al)InGaP subcell with a band gap in the range of 1.6-1.9 eV. The top subcell is an (Al)InGaP subcell with a band gap in the range of 1.9-2.2 eV or 2.2-2.3 eV. Examples of band gaps for J5 to J1 are, respectively, 0.9-1.0 eV, 1.1-1.2 eV, 1.4-1.5 eV, 1.7-1.8 eV, and 2.0-2.1 eV. All of the subcells are substantially lattice-matched to each other and may be connected in series by tunnel junctions. In a related embodiment of the invention, the structure of a photovoltaic cell is the same as depicted in FIG. 13A except that J4 is a GaInNAs subcell. In a related embodiment to the above-described certain embodiment, one or both of the J2 and J3 is a (Al)InGaPAs subcell. This embodiment is depicted in FIG. 13B.

In certain of the embodiments described herein, including any of the photovoltaic cells shown in FIG. 1A-B, 2A-B, 3A, 3C-D, 7, 11-12, 15, 16, or 17B, a bottom III-AsNV subcell is a GaInNAsSb subcell with a base layer comprising Ga₁₋ₓInₓN_{y}As_{1-y-z}Sb_{z}, in which values for x, y, and z are 0≤x≤0.24, 0.01≤y≤0.07 and 0.001≤z≤0.20; in certain embodiments, 0.02≤x≤0.24, 0.01≤y≤0.07 and 0.001≤z≤0.03; in certain embodiments, 0.02≤x≤0.18, 0.01≤y≤0.04 and 0.001≤z≤0.03; in certain embodiments, 0.08≤x≤0.18, 0.025≤y≤0.04 and 0.001≤z≤0.03; and in certain embodiments, 0.06≤x≤0.20, 0.02≤y≤0.05 and 0.005≤z≤0.02.

In certain of the embodiments described herein, including any of the photovoltaic cells shown in FIG. 1A-B, 2A-B, 3A-D, 6, 7, 9-13, 15, 16, 17B, 18B, or 19B, a III-AsNV subcell directly above the bottom subcell is a GaInNAsSb subcell with a base layer comprising Ga₁₋ₓInₓN_{y}As_{1-y-z}Sb_{z}, in which values for x, y, and z are 0≤x≤0.18, 0.001≤y≤0.05 and 0.001≤z≤0.15, and in certain embodiments, O≤x≤0.18, 0.001≤y≤0.05 and 0.001≤z≤0.03; in certain embodiments, 0.02≤x≤0.18, 0.005≤y≤0.04 and 0.001≤z≤0.03; in certain embodiments, 0.04≤x≤0.18, 0.01≤y≤0.04 and 0.001≤z≤0.03; in certain embodiments, 0.06≤x≤0.18, 0.015≤y≤0.04 and 0.001≤z≤0.03; and in certain embodiments, 0.08≤x≤0.18, 0.025≤y≤0.04 and 0.001≤z≤0.03.

In certain of the embodiments described herein, including any of the photovoltaic cells shown in FIG. 1A-B, 2A-B, 10-11, 13A-B, 15, or 19B, a III-AsNV subcell that is the third from the bottom (e.g., J4 in a six junction solar cell or J3 in a five junction solar cell) is a GaInNAsSb subcell with a base layer comprising Ga₁₋ₓInₓN_{y}As_{1-y-z}Sb_{z}, in which values for x, y, and z are 0≤x≤0.12, 0.001≤y<0.03 and 0.001≤z≤0.10; in certain embodiments, 0≤x≤0.12, 0.001≤y<0.03 and 0.001≤z≤0.03; in certain embodiments, 0.02≤x≤0.10, 0.005≤y≤0.02 and 0.001≤z≤0.02; in certain embodiments, 0.01≤x≤0.06, 0.005≤y≤0.015 and 0.001≤z≤0.02; and in certain embodiments, 0.01≤x≤0.08, 0.005≤y≤0.025 and 0.001≤z≤0.02.

In each of the embodiments described herein, the tunnel junctions are designed to have minimal light absorption. Light absorbed by tunnel junctions is not converted into electricity by the solar cell, and thus if the tunnel junctions absorb significant amounts of light, it will not be possible for the efficiencies of the multijunction solar cells to exceed those of the best triple junction solar cells. Accordingly, the tunnel junctions must be very thin (preferably less than 40 nm) and/or be made of materials with band gaps equal to or greater than the subcells immediately above them. An example of a tunnel junction fitting these criteria is a GaAs/AlGaAs tunnel junction, where each of the GaAs and AlGaAs layers forming a tunnel junction have a thickness of between 5 and 15 nm. The GaAs layer is doped with Te, Se, S and/or Si, and the AlGaAs layer is doped with C.

In each of the embodiments described and illustrated herein, additional elements are present in order to create a solar cell device. Specifically, cap or contact layer(s), anti-reflection coating (ARC) layers and electrical contacts (also denoted the “metal grid”) are typically formed above the top subcell, and buffer layer(s), the substrate or handle, and bottom contacts are typically formed or exist below the bottom subcell. In certain embodiments, the substrate may be part of the bottom subcell, such as in a Ge subcell. Other elements, such as additional tunnel junctions, may also be present. Devices may also be formed without all of the elements listed above, as known to those skilled in the art. An example illustrating these typical additional elements, and their typical positions relative to the top and bottom subcells, is shown in FIG. 15.

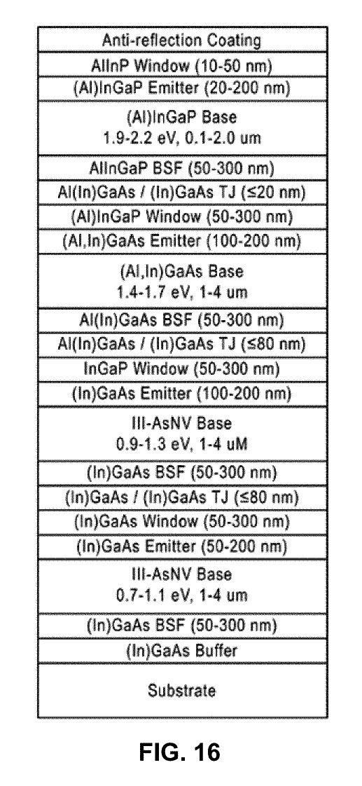

A structural example depicting the individual layers that may compose a multijunction solar cell with four subcells according to the invention is shown in detail in FIG. 16 and described herein. In operation, a multijunction cell is configured such that the subcell having the highest band gap faces the incident solar radiation, with subcells characterized by increasingly lower band gaps situated underneath.

In the embodiments disclosed herein, each subcell may comprise several layers. For example, each subcell may comprise a window layer, an emitter, a base, and a back surface field (BSF) layer. As shown in FIG. 16, the window layer is above the emitter layer, which is above the base, which is above the BSF.

In operation, the window layer is the topmost layer of a subcell and faces the incident solar radiation. In certain embodiments, the thickness of a window layer is from about 10 nm to about 500 nm, from about 10 nm to about 300 nm, from about 10 nm to about 150 nm, and in certain embodiments, from about 10 nm to about 50 nm. In certain embodiments, the thickness of a window layer is from about 50 nm to about 350 nm, from about 100 nm to about 300 nm, and in certain embodiments, from about 50 nm to about 150 nm.

In certain embodiments, the thickness of an emitter layer is from about 10 nm to about 300 nm, from about 20 nm to about 200 nm, from about 50 nm to about 200 nm, and in certain embodiments, from about 75 nm to about 125 nm.

In certain embodiments, the thickness of a base layer is from about 0.1 μm to about 6 μm, from about 0.1 μm to about 4 μm, from about 0.1 μm to about 3 μm, from about 0.1 μm to about 2 μm, and in certain embodiments, from about 0.1 μm to about 1 μm. In certain embodiments, the thickness of a base layer is from about 0.5 μm to about 5 μm, from about 1 μm to about 4 μm, from about 1.5 μm to about 3.5 μm, and in certain embodiments, from about 2 μm to about 3 μm, from about 2 μm to 10 μm, or from about 3 μm to 5 μm.

In certain embodiments the thickness of a BSF layer is from about 10 nm to about 500 nm, from about 50 nm to about 300 nm, and in certain embodiments, from about 50 nm to about 150 nm.

In certain embodiments, an (Al)InGaP subcell comprises a window comprising AlInP, an emitter comprising (Al)InGaP, a base comprising (Al)InGaP, and a back surface field layer comprising AlInGaP.

In certain embodiments, an (Al)InGaP subcell comprises a window comprising AlInP having a thickness from 10 nm to 50 nm, an emitter comprising (Al)InGaP having a thickness from 20 nm to 200 nm, a base comprising (Al)InGaP having a thickness from 0.1 μm to 2 μm, and a BSF layer comprising AlInGaP having a thickness from 50 nm to 300 nm.

In certain of such embodiments, an (Al)InGaP subcell is characterized by a band gap from about 1.9 eV to about 2.2 eV.

In certain embodiments, an (Al,In)GaAs subcell comprises a window comprising (Al)In(Ga)P or Al(In)GaAs, an emitter comprising (Al)InGaP or (Al,In)GaAs, a base comprising (Al,In)GaAs, and a BSF layer comprising Al(In)GaAs or (Al)InGaP. In certain embodiments, an (Al,In)GaAs subcell comprises a window comprising (Al)InGaP having a thickness from 50 nm to 400 nm, an emitter comprising (Al,In)GaAs having a thickness from 100 nm to 200 nm, a base comprising (Al,In)GaAs having a thickness from 1 μm to 4 μm, and a BSF layer comprising Al(In)GaAs having a thickness from 100 nm to 300 nm.

In certain embodiments, an (Al,In)GaAs subcell comprises a window comprising (Al)InGaP having a thickness from 200 nm to 300 nm, an emitter comprising (Al,In)GaAs having a thickness from 100 nm to 150 nm, a base comprising (Al,In)GaAs having a thickness from 2 μm to 3.5 μm, and a BSF layer comprising Al(In)GaAs having a thickness from 150 nm to 250 nm.

In certain of such embodiments, an (Al,In)GaAs subcell is characterized by a band gap from about 1.4 eV to about 1.7 eV.

In certain embodiments, an (Al)GaInPAs subcell comprises a window comprising (Al)In(Ga)P, an emitter comprising (Al)InGaP or (Al)GaInPAs, a base comprising (Al)GaInPAs, and a BSF layer comprising Al(In)GaAs or (Al)InGaP. In certain embodiments, an (Al)GaInPAs subcell comprises a window comprising (Al)In(Ga)P having a thickness from 50 nm to 300 nm, an emitter comprising (Al)InGaP or (Al)GaInPAs having a thickness from 100 nm to 200 nm, a base comprising (Al)GaInPAs having a thickness from 0.5 μm to 4 μm, and a BSF layer comprising Al(In)GaAs or (Al)InGaP having a thickness from 50 nm to 300 nm.

In certain of such embodiments, an (Al)GaInPAs subcell is characterized by a band gap from about 1.4 eV to about 1.8 eV.

In certain embodiments, a III-AsNV alloy subcell comprises a window comprising InGaP or (Al,In)GaAs, an emitter comprising (In)GaAs or a III-AsNV alloy, a base comprising a III-AsNV alloy, and a BSF layer comprising (In)GaAs.

In certain embodiments, a III-AsNV alloy subcell comprises a window comprising InGaP or (In)GaAs, having a thickness from 0 nm to 300 nm, an emitter comprising (In)GaAs or a III-AsNV alloy having a thickness from 100 nm to 200 nm, a base comprising a III-AsNV alloy having a thickness from 1 μm to 4 μm, and a BSF layer comprising (In)GaAs having a thickness from 50 nm to 300 nm. In certain embodiments, a III-AsNV alloy subcell comprises an emitter comprising InGaAs or a III-AsNV alloy having a thickness from 100 nm to 150 nm, a base comprising a III-AsNV alloy having a thickness from 2 μm to 3 μm, and a BSF layer comprising (In)GaAs having a thickness from 50 nm to 200 nm.

In certain of such embodiments, a III-AsNV subcell is characterized by a band gap from about 0.7 to about 1.1 eV, or about 0.9 eV to about 1.3 eV. In certain of such embodiments, the III-AsNV subcell is a GaInNAsSb subcell.

In certain of such embodiments, a III-AsNV subcell has a compressive strain of less than 0.6%, meaning that the in-plane lattice constant of the III-AsNV material in its fully relaxed state is between 0.0% and 0.6% greater than that of the substrate. In certain of such embodiments, the III-AsNV subcell contains Sb and does not contain Bi.

In certain embodiments, a SiGe(Sn) subcell is characterized by a band gap from about 0.7 eV to about 0.9 eV. In certain embodiments, a SiGe(Sn) subcell comprises a window comprising InGaP or (In)GaAs, having a thickness from 0 nm to 300 nm, an emitter comprising (In)GaAs or a III-AsNV alloy having a thickness from 50 nm to 500 nm, and a base comprising SiGe(Sn) having a thickness from 1 μm to 20 μm. In some embodiments, the subcell also comprises a BSF layer comprising (In)GaAs or SiGe(Sn) having a thickness from 50 nm to 300 nm.

In certain embodiments, a Ge subcell comprises a window comprising InGaP or (In)GaAs, having a thickness from 0 nm to 300 nm, an emitter comprising (In)GaAs, (Al,Ga)InP, or a III-AsNV alloy, having a thickness from 10 nm to 500 nm, and a base comprising the Ge substrate. It is to be noted that solar cells disclosed by the invention may also be formed on a Ge substrate wherein the substrate is not part of a subcell.

In certain embodiments, one or more of the subcells has an emitter and/or a base in which there is a graded doping profile. The doping profile may be linear, exponential or with other dependence on position. In certain of such embodiments, one or more of the III-AsNV subcells has an exponential or linear doping profile over part or all of the base, with the doping levels between 1×10¹⁵ and 1×10¹⁹ cm⁻³, or between 1×10¹⁶ and 5×10¹⁸ cm⁻³. Further, the region of the III-AsNV base that is closest to the emitter may have constant or no doping, as described below.

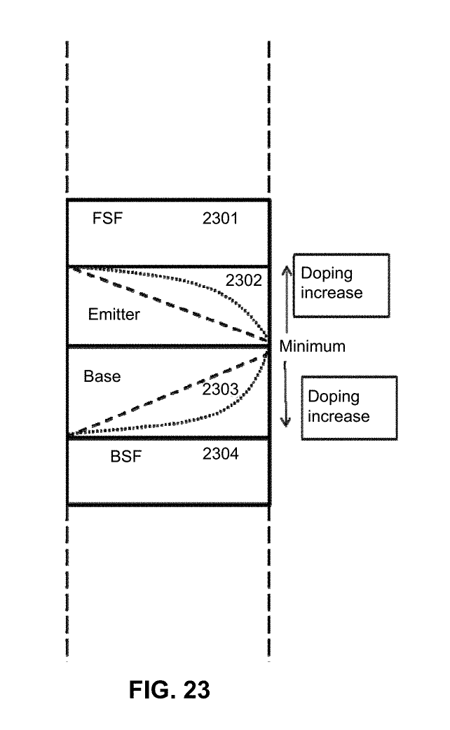

As described above, a multijunction solar cell may have multiple subcells, including a dilute-nitride subcell, for example, as a bottom cell. The subcells may be interconnected with one another by tunnel junctions. The multijunction cell is configured such that the subcell having the highest band gap faces the incident solar radiation, with subcells characterized by increasingly lower band gaps situated underneath. The dilute nitride cell may be integrated as a junction or as the bottom subcell of the multijunction solar cell stack. The solar subcells may be stacked in tandem and have electrical contacts on the upper surface and lower surface. Each subcell is connected to the one above it by a tunnel junction diode at their boundary, which is a thin layer of an extremely highly doped p-n junction. Tunnel junctions are well known in the art and need no further definition. As described more fully below, the base and/or the emitter layer of the dilute nitride subcell 2301 (as depicted in FIG. 23) is doped in such a way as to vary the concentration of dopant within the layer. The middle and top subcells may be constructed from any of a group of materials including but not limited to some combination of Group III and V elements including In, Ga, Al, B, N, As, P, Sb and Bi and also containing dopant elements selected from the group including but not limited to Zn, C, Be, Mg, Si, Ge, O, Se and Te. In certain embodiments of the invention, a dilute nitride subcell with positional dependence of doping and/or impurity incorporation is integrated as one or more subcells of a four-, five- or six-junction solar cell, each sensitive to a different part of the spectrum.

In one embodiment, the dilute nitride subcell is a solar cell with its base and/or emitter comprising a dilute nitride material. The cross section for an exemplary dilute nitride subcell is shown in FIG. 23. Specifically, this subcell comprises multiple layers (numbered 1, 2, 3, 4) including a BSF layer 4 that serves to reduce carrier recombination losses. (By convention in the solar cell art, the term “front” refers to the exterior surface of the cell that faces the radiation source and the term “back” refers to the exterior surface that is away from the source. As used in the figures of this patent application, “back” is thus synonymous with “bottom” and “front” is synonymous with “top.”) Any suitable combination of Group III and Group V element may be used for the fabrication of the BSF, subject to lattice constant and band gap constraints. On top of the BSF, the base comprising dilute nitride material is deposited. On top of the base 3, the emitter 2 comprising dilute nitride material and/or a suitable combination of Group III and Group V elements is grown. Thereafter, an optional front surface field (FSF, layer 1) is deposited on top of the emitter again comprising a suitable combination of Group III and Group V elements. A doping or impurity concentration profile is chosen to yield the desired functional effect of varying the level of doping within the base layer 3 and/or emitter layer 2.

FIG. 23 denotes exemplary cases in which the doping of the base 3 and the emitter has either linearly graded dependence or exponentially graded dependence on the position as measured from the emitter-base junction. Multiple permutations using these exemplary cases can be obtained including an emitter having linear doping and a base having exponential doping and vice versa. Typically, the doping (i.e., impurity concentration) will lie substantially between 1×10¹⁵/cm³ and 1×10¹⁹/cm³, where the lowest doping level is nearest to the emitter-base junction (2-3) and the highest doping level is furthest from the emitter-base junction (1-2) and/or (3-4). For a dopant to function, the minimum deliberate doping level that is introduced into the device should be equal to or greater than any unintentionally incorporated dopants within the semiconductor material itself that naturally arise out of the growth of the dilute nitride alloy (i.e. greater than the background carrier concentration). In accordance with the exemplary doping profiles described in detail below, typical background carrier concentrations in dilute nitrides can be less than 1×10¹⁶/cm³, less than 5×10¹⁵/cm³, or less than 1×10¹⁵/cm³. In this embodiment, such a positional dependence of doping introduces an electric field in addition to the built-in electric field at the emitter-base junction 2-3. The minority carriers generated by the photovoltaic effect in the subcell structure demonstrated in FIG. 23 will be affected by such an electric field. The exact profile of the doping can be varied to introduce an optimized field for substantial improvement in minority carrier collection. This internal field has been determined to improve the current and/or voltage of the solar cell compared to a solar cell with uniform doping. It is determined by this invention that, in dilute nitride-type cells, graded doping is advantageous, as compared to the previously accepted best practice of using a wide intrinsic, i.e., undoped, region to enhance carrier collection, because it yields higher short circuit current, higher open circuit voltage and better fill factors. Some specific examples follow.

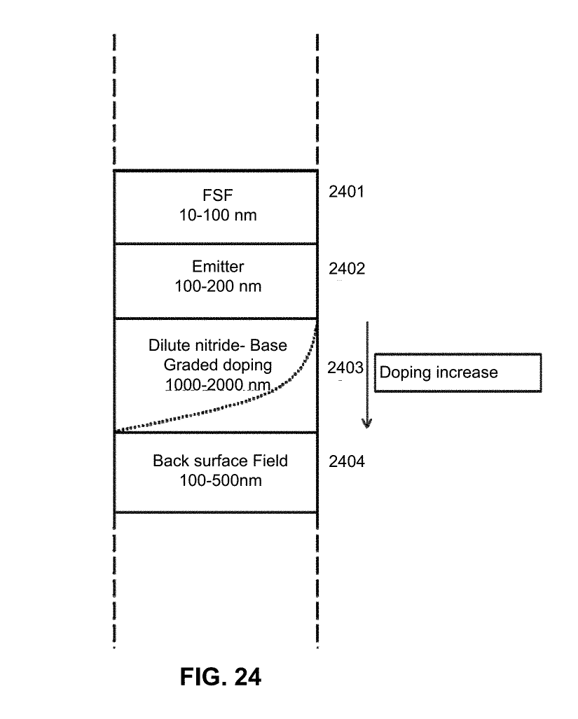

Referring to FIG. 24, consider the population of a dopant that increases in the base 3 from the front of the emitter-base junction (between layers 2 and 3) to the back 4, away from the emitter-base junction (between layers 3-4). The graded doping profile is shown as marked by dotted line in the base 3 of the dilute nitride subcell in FIG. 23. This doping profile assists in minority carrier collection by creating an additional field to push minority carriers to the front of the junction. An exponential doping profile introduces a constant electric field in the base. Linear and other doping profiles may also be used with differing effects. Varying the doping profile changes the electric field as a function of the position in the base 3 and improves current collection correspondingly. In this embodiment, the electric field drives the minority carriers away from the interface at the back of the cell (3-4), which may have a high recombination velocity as mentioned above.

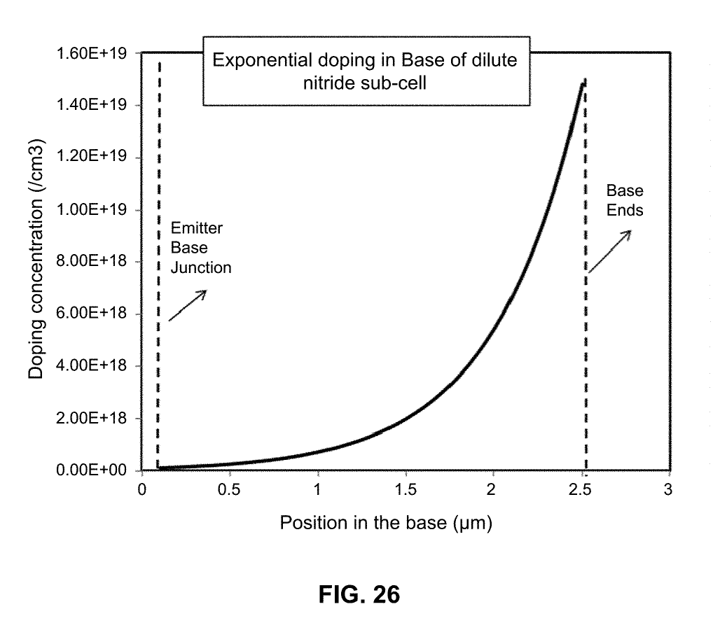

An example of such a doping profile is illustrated by the graph of FIG. 26, wherein an example of the exponential doping with depth is depicted, the least dopant being at the base-emitter junction. As an exemplary case where the dopant concentration varies in a manner as explained in connection with FIG. 26, during manufacturing the dopant flux impinging the epitaxial surface during growth is changed exponentially, keeping other variable parameters as constant. For example, the doping is given by: Doping=A·e^{Bx}; where A=1×10¹⁵/cm³ to 2×10¹⁷/cm³, B=0.1/μm to 10/μm and x is depth. Using this range would yield doping between 1×10¹⁵/cm³ and 1×10¹⁹/cm³ depending on the base thickness. In each case, the dopant flux is minimum at the emitter/base junction. The value of the flux is preset to attain a desired value of the dopant concentration in the epitaxial layer. FIG. 24 also outlines the typical thicknesses of the various layers used for the dilute nitride subcell. In FIG. 24 the back surface field 4, base 3, emitter 2 and the front surface field 1 layers have thicknesses in the range of 100-500 nm, 1000-2000 nm, 100-200 nm and 10-500 nm, respectively.

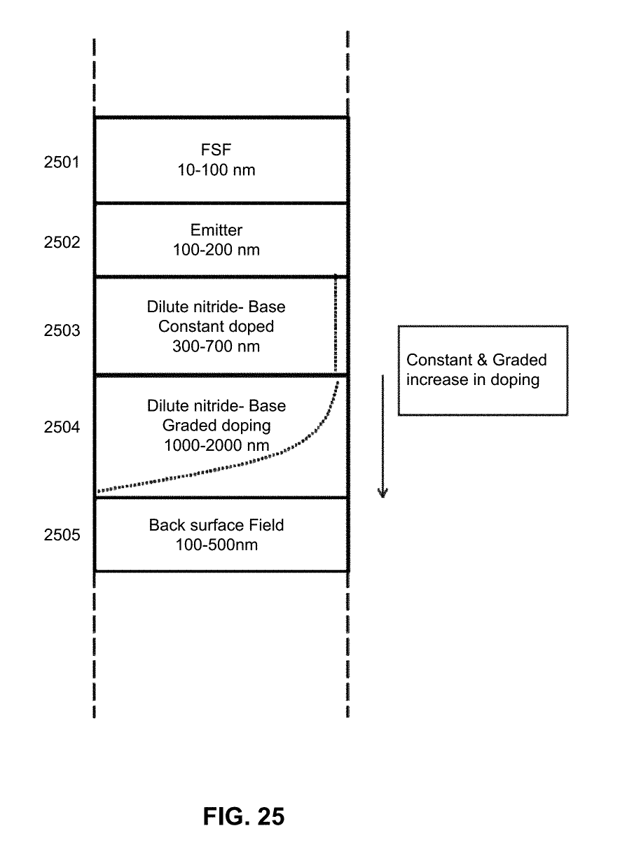

Referring to FIG. 25, the positional dependence of the doping is developed in such a way that the base layer has two sub-regions 3 and 4. The region closer to the front (i.e., the top) of the emitter-base junction (layer 3 in FIG. 25) has constant doping or no doping, as illustrated by the dotted line in sub-region 3. For example, the doping is given by Doping=A; where A is a constant and ranges from 0 to 2×10¹⁷/cm³, The remainder of the base has a doping profile that varies as a function of position in a manner similar to that explained for the previously described embodiment and as illustrated by the dotted line in sub-region 4 of this figure. Using this would yield doping between 1×10¹⁵/cm³ and 1×10¹⁹/cm³ in the base for a thickness of 0 μm to 3 μm of the base.

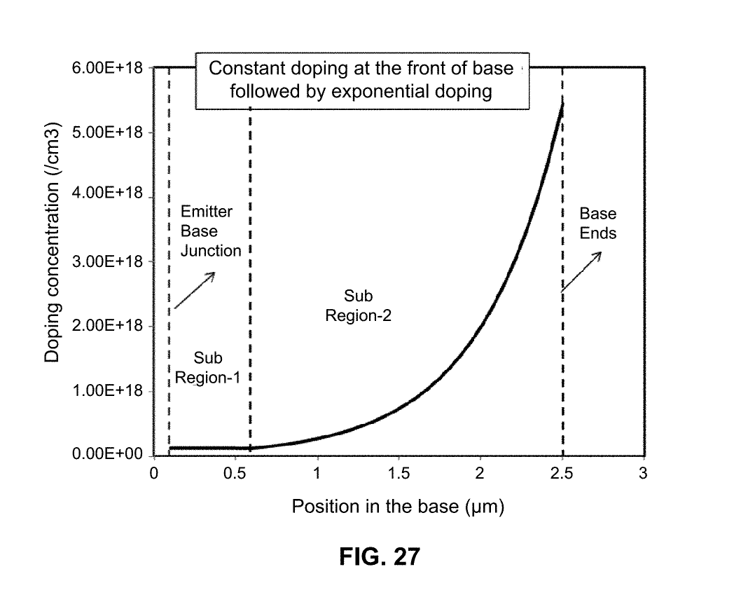

The thickness of each sub-region can be varied in order to optimize the current and voltage output of the subcell. In particular, the optimal thicknesses will be different for different dilute nitride materials, and as the composition of the dilute nitride material changes. An example of such a doping profile is shown in FIG. 27. Sub-region 1 has either constant doping or is undoped. This region is closer to the emitter-base junction. Sub-region 2 has graded doping which varies exponentially as a function of the depth position in the sub-region 2. The position is measured with respect to the emitter-base junction. As an exemplary case where the dopant concentration varies in a manner as explained in connection with FIG. 27, the dopant flux is maximum at the instant when the back of the base is grown. In a typical structure, the back of the base is grown first, and then the dopant flux is changed in a manner so that it exponentially decreases as the remainder of the base is grown. Note that during epitaxy, layer 4 is typically grown first followed by layers 3 and 2 in FIG. 25. The dopant flux is the least at the interface between sub-region 1 and sub-region 2. Thereafter either the dopant flux is turned off or kept constant. The doping profile is varied in this manner in order to gain additional current due to a larger depletion width created by the undoped or uniformly doped region. The remainder of the base has positional (depth) dependent doping so as to introduce a drift field to further improve current collection. Furthermore, the extension of the depletion width by introduction of region of constant doping or no doping as opposed to the case with graded doping in the entire base ensures a higher probability of current collection for carriers generated outside of the depletion region of the solar cell. A substantial improvement in current collection is achieved in these embodiments. In some embodiments, the layer with this doping profile may comprise GaAs, InGaP, AlInGaP, AlGaAs or InGaAs.

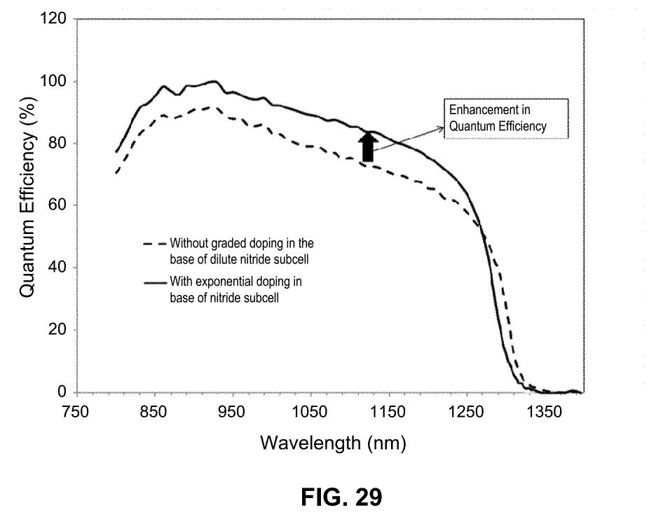

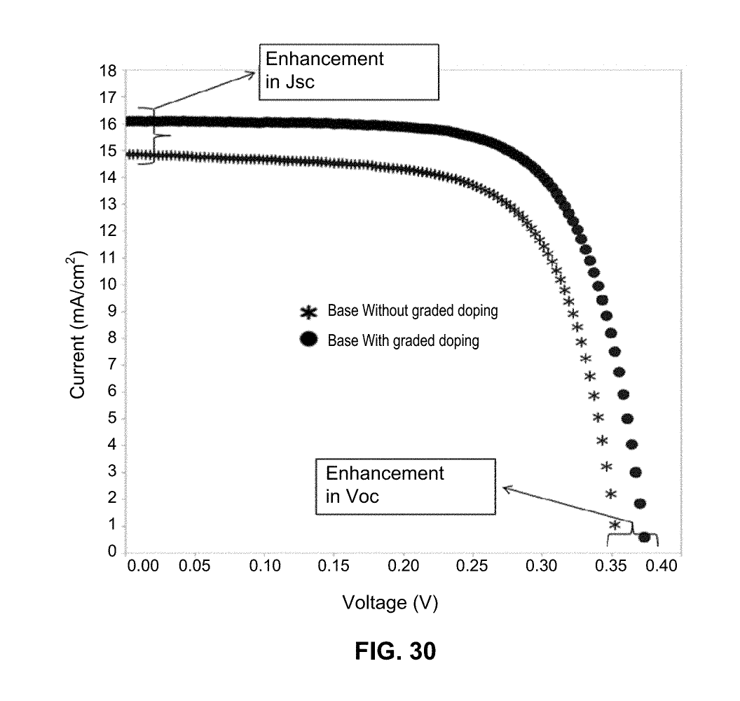

FIG. 29 is a graph that compares the internal quantum efficiency of a dilute nitride subcell with and without use of a position dependent doping profile. Internal quantum efficiency is the ratio of the number of carriers collected by the solar cell to the number of photons of a given wavelength that enter the solar cell (i.e., photons that are reflected from the surface are excluded). If all photons of a certain wavelength are absorbed and the resulting carriers are collected, then the internal quantum efficiency at that particular wavelength is unity. The quantum efficiency measurements showed an approximately 8.5% increase in current under an AM1 5D spectrum as a result of the doping, which would translate to an increase of approximately 8.5% in the overall efficiency of the multijunction solar cell if the dilute nitride subcell were the current limiting cell. With the use of the invention, there is a substantial improvement in the current collection and thus an improvement in the overall efficiency of the solar cell. In this particular demonstration, the short circuit current improves by 8.5% under an AM1 5D spectrum. Similar improvement can also be seen in FIG. 30, which shows the I-V characteristics of dilute nitride subcells. The open circuit voltage, short circuit current and the fill factor show substantial improvement in a subcell with a graded doping profile when compared to subcell without such a doping profile. The substantial improvement in the current and the voltage of the dilute nitride subcell translates directly into an improvement in the efficiency of the multijunction solar cell. This improvement is significantly higher than a dilute nitride subcell without graded doping in the base and/or emitter of the dilute nitride subcell.

In the embodiment of the invention discussed above, the variations in doping profile are achieved during epitaxial growth of the semiconductor layers. In addition to the creation of the preferred doping profile during epitaxial growth, the profile may also be manipulated by post growth steps on the semiconductor epilayer. Such post growth steps include but are not limited to annealing the semiconductor material in an atmosphere comprising one or more of the following: As, P, H₂, N₂, forming gas, and/or O₂. Such a process step has multiple variables that must be optimized to achieve a desired doping profile. This includes but is not limited to changing the anneal time, anneal temperature, anneal cycle in addition to anneal environment mentioned above. For example, the anneal temperature may be between 400° C. and 1000° C., while the duration of the annealing process may lie between 10 sec and 1000 sec, and the ambient condition can be a constant pressure atmosphere of primarily phosphorus, arsenic, hydrogen, oxygen and/or nitrogen. The final objective, irrespective of the process step used to achieve it, is a desirable doping profile for a certain composition of the dilute nitride material.

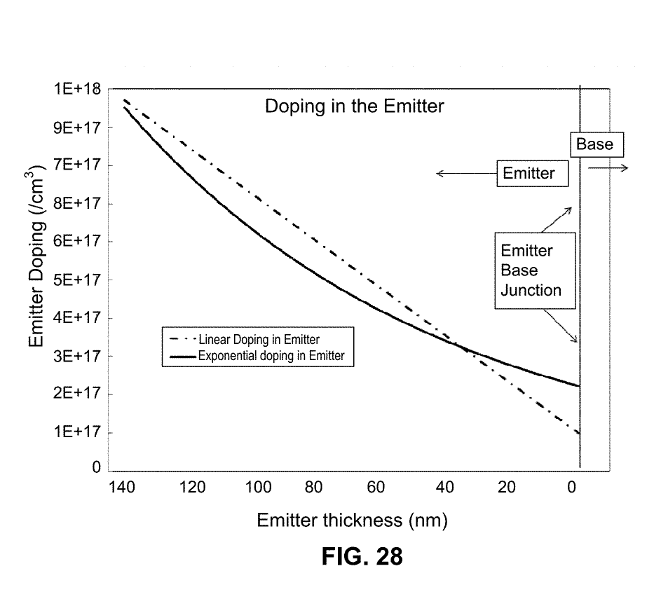

In still another embodiment of this invention, graded doping is introduced in the emitter of the dilute nitride solar cell. In this embodiment, the base may or may not have a graded doping profile according to the embodiments described above. The doping concentration of the emitter (layer 2 in FIG. 23) lies substantially between 1×10¹⁵/cm³ to 1×10¹⁹/cm³. The doping profile increases from the emitter-base junction (interface (2-3) in FIG. 24 and FIG. 25) towards the front surface field of the solar cell (interface (1-2) in FIG. 24 and FIG. 25). FIG. 28 outlines the doping in the emitter of the dilute nitride subcell. Two exemplary cases are given. In the first case, the doping changes linearly as a function of the position in the emitter. In the second case, such a variation in doping follows an exponential increase away from the emitter-base junction. For both the cases, the doping is the least at the emitter-base junction. The advantages of position dependent doping in the emitter are similar to those achieved from such doping in the base of the solar cell. In particular, the collection of minority carriers is improved, increasing the photocurrent. An exponential doping profile introduces a constant electric field in the emitter of the solar cell but linear and other doping profiles may also be used to create other fields of differing geometries. Variation in the doping profile is possible so as to change the electric field as a function of the position to improve current collection.

As shown in FIG. 16, a tunnel junction may be disposed between each of the subcells. Each tunnel junction comprises two or more layers that electrically connect adjacent subcells. The tunnel junction includes a highly doped n-type layer adjacent to a highly doped p-type layer to form a p-n junction. Typically, the doping levels in a tunnel junction are between 10¹⁸ cm⁻³ and 10²¹ cm⁻³.

In certain embodiments, a tunnel junction comprises an n-type (In)GaAs or InGaP(As) layer and a p-type (Al,In)GaAs layer. In certain embodiments the dopant of the n-type layer comprises Si and the dopant of the p-type layer comprises C. A tunnel junction may have a thickness less than about 100 nm, less than 80 nm, less than 60 nm, less than 40 nm, and in certain embodiments, less than 20 nm. For example, in certain embodiments, a tunnel junction between (Al)InGaP subcells, between an (Al)InGaP subcell and an (Al,In)GaAs or (Al)GaInPAs subcell, or between (Al,In)GaAs subcells may have a thickness less than about 30 nm, less than about 20 nm, less than about 15 nm, and in certain embodiments, less than about 12 nm. In certain embodiments, a tunnel junction separating an (Al,In)GaAs and III-AsNV alloy subcell, separating adjacent III-AsNV alloy subcells, or separating a III-AsNV alloy and a SiGe(Sn) or Ge subcell may have a thickness less than 100 nm, less than 80 nm, less than 60 nm, and in certain embodiments, less than 40 nm.

A multijunction solar cell may be fabricated on a substrate such as a Ge substrate. In certain embodiments, the substrate comprises GaAs, InP, Ge, or Si. In certain embodiments, all of the subcells are substantially lattice-matched to the substrate. In certain embodiments, one or more of the layers that are included within the completed solar cell but are not part of a subcell such as, for example, anti-reflective coating layers, contact layers, cap layers, tunnel junction layers, and buffer layers, are not substantially lattice-matched to the subcells.

In certain embodiments, a buffer layer is fabricated overlying the substrate. In certain embodiments, the buffer layer comprises (In)GaAs.

As shown in FIG. 16, the multijunction solar cell comprises subcells characterized by progressively higher band gaps overlying the buffer layer, with each of the subcells typically separated by a tunnel junction.

In certain embodiments, the multijunction solar cell comprises an anti-reflection coating overlying the uppermost subcell. The materials comprising the anti-reflection coating and the thickness of the anti-reflection coating are selected to improve the efficiency of light capture in the multijunction solar cell. In certain embodiments, one or more contact layers overlie the uppermost subcell in the regions underlying or near the metal grid. In certain embodiments, the contact layers comprise (In)GaAs and the dopant may be Si or Be.

In certain embodiments, a photovoltaic cell comprises at least four subcells, wherein: the at least four subcells comprise at least one subcell comprising a base layer, wherein the base layer comprises an alloy of elements from group III on the periodic table, nitrogen, arsenic, and at least one element selected from Sb and Bi; and each of the at least four subcells is substantially lattice matched to each of the other subcells.

In certain embodiments of a photovoltaic cell, each of the at least four subcells is substantially lattice matched to a material selected from Si, Ge, SiGe, GaAs, and InP.

In certain embodiments of a photovoltaic cell, the at least one subcell is characterized by a band gap selected from 0.7 eV to 1.1 eV, from 0.9 eV to 1.0 eV, from 0.9 eV to 1.3 eV, from 1.0 eV to 1.1 eV from 1.0 eV to 1.2 eV, from 1.1 eV to 1.2 eV, from 1.1 eV to 1.4 eV, and from 1.2 eV to 1.4 eV.

In certain embodiments of a photovoltaic cell, the base layer of the at least one subcell comprises Ga₁₋ₓInₓN_{y}As_{1-y-z}Sb_{z}, in which values for x, y and z are 0≤x≤0.24, 0.001≤y≤0.07 and 0.001≤z≤0.20.

In certain embodiments of a photovoltaic cell, the base layer of the at least one subcell comprises Ga₁₋ₓInₓN_{y}As_{1-y-z}Sb_{z}, in which values for x, y and z are 0.01≤x≤0.18, 0.005≤y≤0.05, and 0.001≤z≤0.03.

In certain embodiments of a photovoltaic cell, the at least four subcells comprise at least two subcells, each of the at least two subcells comprising a base layer comprising an alloy of elements from group III on the periodic table, nitrogen, arsenic, and at least one element selected from Sb and Bi.

In certain embodiments of a photovoltaic cell, one of the at least two subcells is characterized by a first band gap of 0.7 to 1.1 eV; and a second of the at least two subcells is characterized by a second band gap of 0.9 to 1.3 eV, wherein the second band gap is greater than the first band gap.

In certain embodiments of a photovoltaic cell, each of the at least two subcells comprise a base layer comprising a material independently selected from GaInNAsSb, GaInNAsBi, GaInNAsSbBi, GaNAsSb, GaNAsBi, and GaNAsSbBi.

In certain embodiments of a photovoltaic cell, one of the at least two subcells comprises a base layer comprising Ga₁₋ₓInₓN_{y}As_{1-y-z}Sb_{z}, in which values for x, y and z are 0.02≤x≤0.24, 0.015≤y≤0.07 and 0.001≤z≤0.03 and a second of the at least two subcells comprises a base layer comprising Ga₁₋ₓInₓN_{y}As_{1-y-z}Sb_{z}, in which values for x, y and z are 0≤x≤0.18, 0.005≤y≤0.05 and 0.001≤z≤0.03.

In certain embodiments of a photovoltaic cell, the photovoltaic cell comprises a first subcell comprising a first base layer comprising a material selected from Ge, SiGe(Sn), and an alloy of elements from group III on the periodic table, nitrogen, arsenic, and at least one element selected from Sb and Bi, and characterized by a band gap of 0.7 eV to 1.1 eV; a second subcell comprising a second base layer overlying the first subcell, wherein the second base layer comprises an alloy of elements from group III on the periodic table, nitrogen, arsenic, and at least one element selected from Sb and Bi, and characterized by a band gap of 0.9 eV to 1.3 eV; a third subcell comprising a third base layer overlying the second subcell, the third base layer comprising a material selected from GaInPAs and (Al,In)GaAs and characterized by a band gap from 1.4 eV to 1.7 eV; and a fourth subcell comprising a fourth base layer overlying the third subcell, the fourth base layer comprising (Al)InGaP and characterized by a band gap from 1.9 eV to 2.2 eV.

In certain embodiments of a photovoltaic cell, the first base layer, the second base layer, or both the first and the second base layer comprises the alloy Ga₁₋ₓInₓN_{y}As_{1-y-z}Sb_{z}, in which values for x, y and z are 0≤x≤0.24, 0.001≤y≤0.07 and 0.001≤z≤0.20.

In certain embodiments of a photovoltaic cell, the band gap of the first base layer is 0.7 to 0.9 eV, the band gap of the second base layer is 1.0 to 1.2 eV, the band gap of the third base layer is 1.5 to 1.6 eV, and the band gap of the fourth base layer is 1.9 eV to 2.1 eV.

In certain embodiments of a photovoltaic cell, the first base layer, the second base layer, or both the first and the second base layer comprises the alloy Ga₁₋ₓInₓN_{y}As_{1-y-z}Sb_{z}, in which values for x, y and z are 0.01≤x≤0.18, 0.005≤y≤0.05, and 0.001≤z≤0.03.

In certain embodiments of a photovoltaic cell, each of the four subcells is substantially lattice matched to a material selected from Ge and GaAs.

In certain embodiments of a photovoltaic cell, the photovoltaic cell comprises a first subcell comprising a first base layer comprising a material selected from the group consisting of Ge, SiGe(Sn), and an alloy of elements from group III on the periodic table, nitrogen, arsenic, and at least one element selected from Sb and Bi, and characterized by a band gap of 0.7 eV to 1.1 eV; a second subcell comprising a second base layer overlying the first subcell, wherein the second base layer comprises an alloy of elements from group III on the periodic table, nitrogen, arsenic, and at least one element selected from Sb and Bi, and characterized by a band gap of 0.9 eV to 1.3 eV; a third subcell comprising a third base layer overlying the second subcell, wherein the second base layer comprises a material selected from GaInPAs, (Al,In)GaAs, and an alloy of elements from group III on the periodic table, nitrogen, arsenic, and at least one element selected from Sb and Bi, and characterized by a band gap of 1.2 eV to 1.6 eV; a fourth subcell comprising a fourth base layer overlying the third subcell, the fourth base layer comprising a material selected from GaInPAs and (Al,In)GaAs and characterized by a band gap from 1.6 eV to 1.9 eV; and a fifth subcell comprising a fifth base layer overlying the fourth subcell, the fifth base layer comprising (Al)InGaP and characterized by a band gap from 1.9 eV to 2.2 eV.

In certain embodiments of a photovoltaic cell comprising five subcells, one or more of the first base layer, the second base layer, and the third base layer comprise the alloy Ga₁₋ₓInₓN_{y}As_{1-y-z}Sb_{z}, in which values for x, y and z are 0≤x≤0.24, 0.001≤y≤0.07 and 0.001≤z≤0.20. In certain of such embodiments, one or more of the first base layer, the second base layer, and the third base layer comprise the alloy Ga₁₋ₓInₓN_{y}As_{1-y-z}Sb_{z}, in which values for x, y and z are 0.01≤x≤0.18, 0.005≤y≤0.05, and 0.001≤z≤0.03.

In certain embodiments of a photovoltaic cell, the photovoltaic cell comprises a first subcell comprising a first base layer comprising a material selected from Ge, SiGe(Sn), and an alloy of elements from group III on the periodic table, nitrogen, arsenic, and at least one element selected from Sb and Bi, and characterized by a band gap of 0.7 eV to 1.1 eV; a second subcell comprising a second base layer overlying the first subcell, wherein the second base layer comprises an alloy of elements from group III on the periodic table, nitrogen, arsenic, and at least one element selected from Sb and Bi, and characterized by a band gap of 0.9 eV to 1.3 eV; a third subcell comprising a third base layer overlying the second subcell, wherein the third base layer comprises a material selected from GaInPAs, (Al,In)GaAs and an alloy of elements from group III on the periodic table, nitrogen, arsenic, and at least one element selected from Sb and Bi, and characterized by a band gap of 1.1 eV to 1.5 eV; a fourth subcell comprising a fourth base layer overlying the third subcell, the fourth base layer comprising a material selected from (Al,In)GaAs and (Al)InGa(P)As, and characterized by a band gap from 1.4 eV to 1.7 eV; a fifth subcell comprising a fifth base layer overlying the fourth subcell, the fifth base layer comprising a material selected from (Al)InGaP and Al(In)Ga(P)As, and characterized by a band gap from 1.6 eV to 2.0 eV; and a sixth subcell comprising a sixth base layer overlying the fifth subcell, the sixth base layer comprising (Al)InGaP, and characterized by a band gap from 1.9 eV to 2.3 eV.

In certain embodiments of a photovoltaic cell comprising six subcells, one or more of the first base layer, the second base layer, and the third base layer comprise the alloy Ga₁₋ₓInₓN_{y}As_{1-y-z}Sb_{z}, in which values for x, y and z are 0≤x≤0.24, 0.001≤y≤0.07 and 0.001≤z≤0.20. In certain of such embodiments, one or more of the first base layer, the second base layer, and the third base layer comprise the alloy Ga₁₋ₓInₓN_{y}As_{1-y-z}Sb_{z}, in which values for x, y and z are 0.01≤x≤0.18, 0.005≤y≤0.05, and 0.001≤z≤0.03.

In one embodiment of the invention with four subcells that is related to FIG. 6, the subcells from bottom to top are Ge, GaInNAsSb, (Al,In)GaAs and (Al)InGaP subcells. The approximate band gaps of the subcells above the Ge subcell, from bottom to top, are, respectively, between 1.00-1.15 eV, between 1.40-1.55 eV and between 1.90-2.01 eV. The term approximate herein signifies that the band gap of the subcell is within 20 meV of the stated value. In one embodiment designed to operate under the AMO spectrum, approximate band gaps of the subcells above the Ge subcell, from bottom to top, are, respectively, 1.05 eV, 1.45 eV and 1.99 eV. In another embodiment, approximate band gaps of the subcells above the Ge subcell, from bottom to top, are, respectively, 1.01 eV, 1.43 eV and 1.95 eV. In one embodiment designed to operate under the AM 1 0.5D spectrum, approximate band gaps of the subcells above the Ge subcell, from bottom to top, are, respectively, 1.10 eV, 1.49 eV and 1.95 eV. In another embodiment designed to operate under the AMI 0.5G spectrum, approximate band gaps of the subcells above the Ge subcell, from bottom to top, are, respectively, 1.14 eV, 1.54 eV and 1.99 eV. Values for x, y and z for the Ga₁₋ₓInₓN_{y}As_{1-y-z}Sb_{z} subcell are 0.04≤x≤0.09, 0.015≤y≤0.025 and 0.001≤z≤0.03. In certain embodiments, values for x, y and z for the Ga₁₋ₓInₓN_{y}As_{1-y-z}Sb_{z} subcell are 0.05≤x≤0.09, 0.020≤y≤0.025 and 0.001≤z≤0.02. In certain embodiments, values for x are 0.08≤x≤0.09, values for y are 0.021≤y≤0.025 and values for z are 0.001≤z≤0.009, 0.005≤z≤0.015 or 0.02≤z≤0.03. All of the four subcells are substantially lattice-matched to the Ge subcell and may be connected in series by tunnel junctions. The compositions for the (Al,In)GaAs and (Al)InGaP subcells are specified within a narrow range by the band gap, given that they are lattice-matched to Ge. In some embodiments, the open-circuit voltage is at least 3.00 V, and in some embodiments, greater than 3.20 V, and in some embodiments, greater than 3.30 V, when measured under the AMI.SD spectrum at 25° C. at an illumination intensity of 0.1 W/cm². In some embodiments, the open-circuit voltage is at least 3.95 V, and in some embodiments, at least 4.10 V, when measured under the AMI.SD spectrum at 25° C. at an illumination intensity of 50 W/cm².

In one embodiment of the invention with five subcells that is related to FIG. 9, the subcells from bottom to top are Ge, GaInNAsSb, (In)GaAs, Al(In)GaAs and (Al)InGaP subcells. The approximate band gaps of the subcells above the Ge subcell, from bottom to top, are, respectively, between 0.94-1.09, 1.41, between 1.64-1.75, and between 1.95-2.10 eV. In one embodiment designed to operate under the AMI 0.5D spectrum, approximate band gaps of the subcells above the Ge subcell, from bottom to top, are, respectively, between 0.98-1.05, 1.41, 1.67 and 2.05 eV. In another embodiment designed to operate under the AM0 spectrum, approximate band gaps of the subcells above the Ge subcell, from bottom to top, are, respectively, between 0.96-1.05, 1.41, 1.68 and 2.08 eV. In another embodiment designed to operate under the AMI 0.5G spectrum, approximate band gaps of the subcells above the Ge subcell, from bottom to top, are, respectively, 1.00, 1.41, 1.68 and between 2.02-2.10 eV. In another embodiment, approximate band gaps of the subcells above the Ge subcell, from bottom to top, are, respectively, 1.02, 1.41, 1.70 and 1.97 eV. In certain embodiments, values for x, y and z for the Ga₁₋ₓInₓN_{y}As_{1-y-z}Sb_{z} subcell are 0.05≤x≤0.09, 0.020<y≤0.025 and 0.001≤z≤0.02. In certain embodiments, values for x are 0.08≤x≤0.09, values for y are 0.021≤y≤0.025 and values for z are 0.001<z≤0.009, 0.005≤z<0.015 or 0.02≤z≤0.03. In certain embodiments, values for x, y and z for the Ga₁₋ₓInₓN_{y}As_{1-y-z}Sb_{z} subcell are 0.10≤x≤0.18, 0.025<y≤0.04 and 0.001≤z<0.02. All of the subcells are substantially lattice-matched to the Ge subcell and may be connected in series by tunnel junctions. The compositions for the (In)GaAs, Al(In)GaAs and (Al)InGaP subcells are specified within a narrow range by the band gap, given that they are lattice-matched to the Ge substrate. In some embodiments, the open-circuit voltage is at least 4.20 V, and in some embodiments, at least 4.35 V, and in some embodiments, at least 4.60 V, when measured under the AMI 0.5D spectrum at 25° C. at an illumination intensity of 0.1 W/cm². In some embodiments, the open-circuit voltage is at least 5.10 V, and in some embodiments, greater than 5.30 V, when measured under the AMI 0.5D spectrum at 25° C. at an illumination intensity of 50 W/cm².

In another embodiment of the invention with six subcells that is related to FIG. 13A, the subcells from bottom to top are Ge, GaInNAsSb, GaInNAsSb, (Al,In)GaAs, Al(In)GaAs or InGaP(As), and (Al)InGaP subcells. The approximate band gaps of the subcells above the Ge subcell, from bottom to top, are, respectively, between 0.93-1.04 eV, between 1.14-1.25 eV, between 1.43-1.54 eV, between 1.72-1.85 eV, and between 1.95-2.15 eV. In one embodiment designed to operate under the AM 1 0.5D spectrum, approximate band gaps of the subcells above the Ge subcell, from bottom to top, are, respectively, 1.02 eV, 1.22 eV, 1.52 eV, 1.78 eV and between 2.00-2.10 e V. In one embodiment designed to operate under the AMO spectrum, approximate band gaps of the subcells above the Ge subcell, from bottom to top, are, respectively, 0.95 eV, 1.18 eV, 1.48 eV, 1.80 eV, and 2.06 eV. In another embodiment, approximate band gaps of the subcells above the Ge subcell, from bottom to top, are, respectively, 0.92, 1.13, 1.44, between 1.70-1.78 and between 2.05-2.15 eV. In another embodiment designed to operate under the AMI 0.5G spectrum, approximate band gaps of the subcells above the Ge subcell, from bottom to top, are, respectively, 1.00, 1.21, 1.50, 1.78 and 2.06 eV. Values for x, y and z for the lower Ga₁₋ₓInₓN_{y}As_{1-y-z}Sb_{z} subcell are 0.07≤x≤0.18, 0.025≤y≤0.04 and 0.001≤z≤0.03. In certain embodiments, values for z for the lower Ga₁₋ₓInₓN_{y}As_{1-y-z}Sb_{z} subcell are 0.001≤z≤0.015. In certain embodiments, values for the lower Ga₁₋ₓInₓN_{y}As_{1-y-z}Sb_{z} subcell are 0.011≤x≤0.018 and values for y are 0.03≤y≤0.04. Values for x, y and z for the upper Ga₁₋ₓInₓN_{y}As_{1-y-z}Sb_{z} subcell are 0.02≤x≤0.04, 0.007≤y≤0.018 and 0.001≤z≤0.03. In certain embodiments, values for x, y and z for the upper Ga₁₋ₓInₓN_{y}As_{1-y-z}Sb_{z} subcell are 0.025≤x≤0.03, 0.008≤y≤0.012 and 0.006≤z≤0.015. In certain embodiments, values for x, y and z for the upper Ga₁₋ₓInₓN_{y}As_{1-y-z}Sb_{z} subcell are 0.02≤x≤0.025, 0.01≤y≤0.012 and 0.02≤z≤0.03. In certain embodiments, values for z for the lower Ga₁₋ₓInₓN_{y}As_{1-y-z}Sb_{z} subcell are 0.001≤z≤0.015 and values for x, y and z for the upper Ga₁₋ₓInₓN_{y}As_{1-y-z}Sb_{z} subcell are 0.025≤x≤0.03, 0.008≤y≤0.012 and 0.006≤z≤0.015. All of the subcells are substantially lattice-matched to the Ge substrate and may be connected in series by tunnel junctions. The compositions for the (Al,In)GaAs, Al(In)GaAs or InGaP(As), and (Al)InGaP subcells are specified within a narrow range by the band gap, given that they are lattice-matched to the Ge substrate. In some embodiments, the open-circuit voltage is at least 4.70 V, and in some embodiments, at least 4.90 V, and in some embodiments, greater than 5.00 V, when measured under the AMI 0.5D spectrum at 25° C. at an illumination intensity of 0.1 W/cm². In some embodiments, the open-circuit voltage is at least 5.90 V, and in some embodiments, greater than 6.10 V, and in some embodiments, greater than 6.30 V, when measured under the AMI 0.5D spectrum at 25° C. at an illumination intensity of 50 W/cm².

One skilled in the art understands that band gap values vary as a function of temperature. The aforementioned band gap values are at a temperature of 25° C.

The solar cells are designed to pass IEC62108 standards when integrated into receivers. Bare solar cells are designed to pass reliability stress testing that includes 2000 hours at 205° C. and 500 hours at 85° C. and 85% humidity.

### C. Photovoltaic Power Systems and Photovoltaic Modules

In one embodiment of the invention, a photovoltaic power system comprises one or more of a photovoltaic cell provided by the present disclosure such as, for example, one or more photovoltaic cells having at least four subcells, including one or more III-AsNV subcells. In one specific embodiment, the one or more photovoltaic cells has a III-AsNV subcell as the bottom subcell or the subcell immediately above the bottom subcell. In certain embodiments, the photovoltaic power system may be a concentrating photovoltaic system, wherein the system may also comprise mirrors and/or lenses used to concentrate sunlight onto one or more photovoltaic cells. In certain embodiments, the photovoltaic power system comprises a single or dual axis tracker. In certain embodiments, the photovoltaic power system is designed for portable applications, and in other embodiments, for grid-connected power generation. In certain embodiments, the photovoltaic power system is designed to convert a specific spectrum of light, such as AM1.5G, AM1.5D or AM0, into electricity. In certain embodiments, the photovoltaic power system may be found on satellites or other extra-terrestrial vehicles and designed for operation in space without the influence of a planetary atmosphere on the impinging light source. In certain embodiments, the photovoltaic power system may be designed for operation on astronomical bodies other than Earth. In certain embodiments, the photovoltaic power system may be designed for satellites orbiting about astronomical bodies other than Earth. In certain embodiments, the photovoltaic power system may be designed for roving on the surface of an astronomical body other than Earth.

In certain embodiments of the invention, photovoltaic modules are provided comprising one or more photovoltaic cells provided by the present disclosure. A photovoltaic module may comprise one or more photovoltaic cells provided by the present disclosure to include an enclosure and interconnects to be used independently or assembled with additional modules to form a photovoltaic power system. A module and/or power system may include power conditioners, power converters, inverters and other electronics to convert the power generated by the photovoltaic cells into usable electricity. A photovoltaic module may further include optics for focusing light onto a photovoltaic cell provided by the present disclosure such as in a concentrated photovoltaic module.

### D. Additional Embodiments of Optoelectronic Devices Including Dilute Nitride Materials in an Active Layer

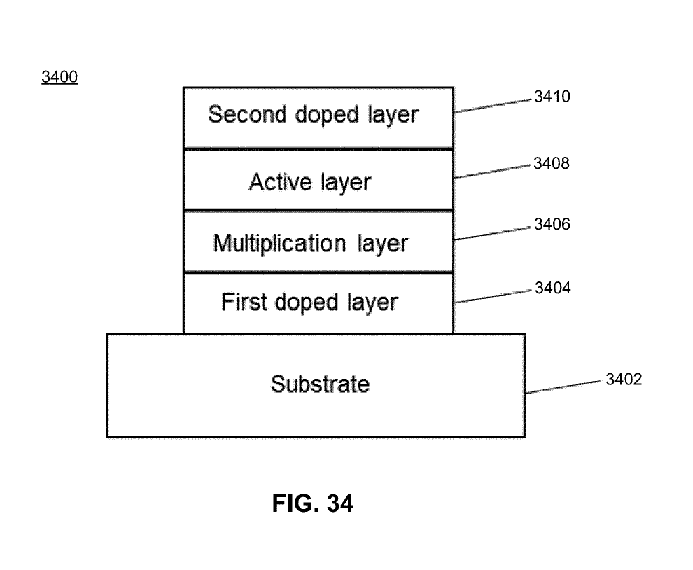

FIG. 34 shows a semiconductor optoelectronic device 3400 with a p-i-n diode and a multiplication layer. Device 3400 is similar to device 2100, but also includes a multiplication layer. The purpose of the multiplication layer is to amplify the photocurrent generated by the active region of a photodetector device. The structure of device 3400 provides an avalanche photodiode (APD). An APD introduces an additional p-n junction into the structure, as well as introduces an additional thickness. This allows a higher reverse bias voltage to be applied to the device, which results in carrier multiplication by the avalanche process.

Substrate 3402 can have a lattice constant that matches or nearly matches the lattice constant of GaAs or Ge. The substrate can be GaAs. Substrate 3402 may be doped p-type, or n-type, or may be a semi-insulating (SI substrate). The thickness of substrate 3402 can be chosen to be any suitable thickness. Substrate 3402 can include one or more layers, for example, a Si layer having an overlying SiGeSn buffer layer that is engineered to have a lattice constant that matches or nearly matches the lattice constant of GaAs or Ge. This can mean the substrate has a lattice parameter different than that of GaAs or Ge by less than or equal to 3%, less than 1%, or less than 0.5% of GaAs or Ge.

First doped layer 3404 can have a doping of one type and the second doped layer 3410 can have a doping of the opposite type. If first doped layer 3404 is doped n-type, second doped layer 3410 is doped p-type. Conversely, if first doped layer 3404 is doped p-type, second doped layer 3410 is doped n-type. Examples of p-type dopants include C and Be. Examples of n-type dopants include Si and Te. Doped layers 3404 and 3410 can be chosen to have a composition that is lattice matched or pseudomorphically strained to the substrate. The doped layers can comprise any suitable III-V material, such as GaAs, AlGaAs, GaInAs, GaInP, GaInPAs, GaInNAs, GaInNAsSb. The band gap of the doped layers can be selected to be larger than the band gap of active layer 3408. Doping levels can be within a range from 1×10¹⁵ cm⁻³ to 2×10¹⁹ cm⁻³. Doping levels may be constant within a layer and/or the doping profile may be graded, for example, increasing the doping level from a minimum value to a maximum value as a function of the distance from the interface between the doped layer and the active layer. Doped layers 3404 and 3410 can have a thickness, for example, within a range from 50 nm and 3 μm.

Active layer 3408 can be lattice matched or pseudomorphically strained to the substrate and/or to the doped layers. The band gap of active layer 3408 can be lower than that of the doped layers 3404 and 3410. Active layer 3408 can comprise a layer capable of processing light over a desired wavelength range. Processing is defined to be a light emission, a light receiving, a light sensing and light modulation.

Active layer 3408 can include a dilute nitride material. The dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. Active layer 3408 can have a band gap within a range from 0.7 eV to 1.1 eV such that the active layer can absorb or emit light at wavelengths up to 1.8 μm. Bismuth (Bi) may be added as a surfactant during growth of the dilute nitride, improving material quality (such as defect density), and the device performance. The thickness of active layer 3408 can be within a range from 0.2 μm to 10 μm, or from 0.5 μm to 10 μm, or from 0.5 μm to 5 μm, or from 1 μm to 10 μm, or from 2 μm to 10 μm, or from 3 μm to 5 μm, or from 1 μm to 4 μm. Active layer 3408 can be compressively strained with respect to the substrate 3402. Strain can also improve device performance. For a photodetector, the device performance of most relevance includes the dark current, operating speed, noise and responsivity.

The multiplication layer 3406 can be a p-type III-V layer that amplifies the current generated by the active layer 3408 through avalanche multiplication. Thus, for each free carrier (electron or hole) generated by the active layer 3408, the multiplication layer 3406 generates one or more carriers via the avalanche effect. Thus, the multiplication layer 3406 increases the total current generated by the semiconductor 3400. Multiplication layer 3406 can comprise a III-V material, such as GaAs, or AlGaAs.

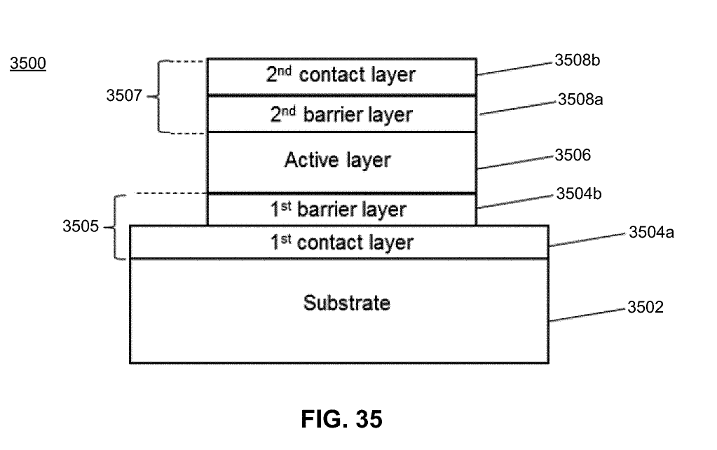

FIG. 35 shows a side view of an example of a semiconductor optoelectronic device 3500 according to the present invention. Device 3500 is similar to device 2100, but each of the doped layers are shown to comprise two layers. Device 3500 includes a substrate 3502, a first contact layer 3504a, a first barrier layer 3504b, an active layer 3506, a second barrier layer 3508a, and a second contact layer 3508b.

Substrate 3502 can have a lattice constant that matches or nearly matches the lattice constant of GaAs or Ge. The substrate can be GaAs. Substrate 3502 may be doped p-type, or n-type, or may be a semi-insulating (SI substrate). The thickness of substrate 3502 can be chosen to be any suitable thickness. Substrate 3502 can include one or more layers, for example, substrate 3502 can include a Si layer having an overlying SiGeSn buffer layer that is engineered to have a lattice constant that matches or nearly matches the lattice constant of GaAs or Ge. This can mean the substrate can have a lattice parameter different than that of GaAs or Ge by less than or equal to 3%, less than 1%, or less than 0.5% of GaAs or Ge.

First contact layer 3504a and first barrier layer 3504b provide a first doped layer 3505, having a doping of one type, and second barrier layer 3508a and second contact layer 3508b provide a second doped layer 3507, having a doping of the opposite type. If first doped layer 3505 is doped n-type, second doped layer 3507 is doped p-type. Conversely, if first doped layer 3505 is doped p-type, second doped layer 3507 is doped n-type. Examples of p-type dopants include C and Be. Examples of n-type dopants include Si and Te. Doped layers 3505 and 3507 can be chosen to have a composition that is lattice matched or pseudomorphically strained to the substrate. The doped layers can comprise any suitable III-V material, such as GaAs, AlGaAs, GaInAs, GaInP, GaInPAs, GaInNAs, GaInNAsSb. The contact and barrier layers can have different compositions and different thicknesses. The band gap of the doped layers can be selected to be larger than the band gap of active region 3506. The doping level of first contact layer 3504a can be chosen to be higher than the doping level of first barrier layer 3504b. A higher doping facilitates electrical connection with a metal contact. Similarly, the doping level of second contact layer 3504b can be chosen to be higher than the doping level of second barrier layer 3504a. Higher doping levels facilitates electrical connection with a metal contact. Doping levels can be within a range from 1×10¹⁵ cm⁻³ to 2×10¹⁹ cm⁻³. Doping levels may be constant within a layer and/or the doping profile may be graded, for example, increasing the doping level from a minimum value to a maximum value as a function of the distance from the interface between the doped layer and the active layer. Each of layers 3504a, 3504b, 3508a and 3508b can have a thickness, for example, within a range from 50 nm to 3 μm.

Active layer 3506 can be lattice matched or pseudomorphically strained to the substrate and/or to the doped layers. The band gap of active layer 3506 can be lower than that of layers 3504a, 3504b, 3508a and 3508b. Active layer 3506 can comprise a layer capable of processing light over a desired wavelength range. Processing is defined to be a light emission, a light receiving, a light sensing and light modulation.

Active layer 3506 can include a dilute nitride material. The dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. Active layer 3506 can have a band gap within a range from 0.7 eV to 1.0 eV such that the active layer can absorb or emit light at wavelengths up to 1.8 μm. Bismuth (Bi) may be added as a surfactant during growth of the dilute nitride, improving material quality (such as defect density), and the device performance. The thickness of active layer 3506 can be, for example, within a range from 0.2 μm to 10 μm, or from 0.5 μm to 10 μm, or from 0.5 μm to 5 μm, or from 1 μm to 10 μm, or from 2 μm to 10 μm, or from 3 μm to 5 μm, or from 1 μm to 4 μm. The carrier concentration of the active layer can be, for example, less than 1×10¹⁶ cm⁻³ (measured at room temperature), less than 5×10¹⁵ cm⁻³, or less than 1×10¹⁵ cm⁻³. Active layer 3506 can be compressively strained with respect to the substrate 3502. Strain can also improve device performance. For a photodetector, the parameters most relevant to device performance include the dark current, operating speed, noise and responsivity

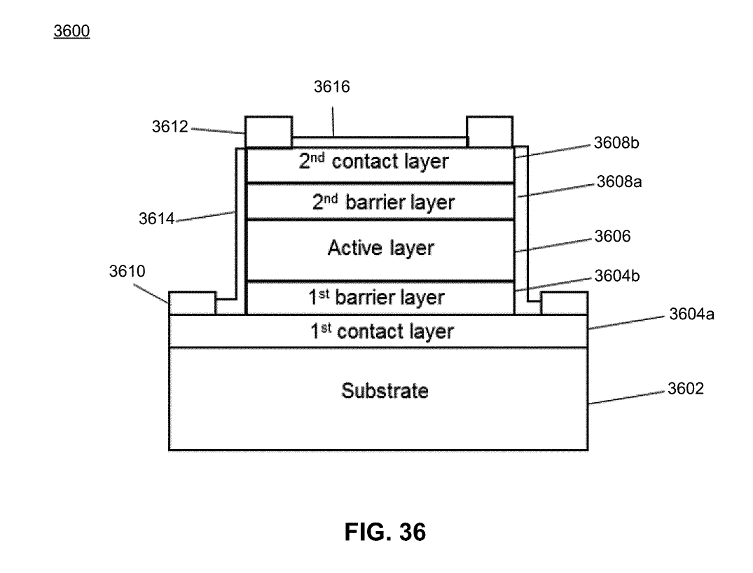

FIG. 36 shows a side view of an example of a photodetector 3600 according to the present invention. Device 3600 is similar to device 3500. Compared to device 3500, additional device layers include a first metal contact 3610, a second metal contact 3612, a passivation layer 3614, and an antireflection coating 3616. The semiconductor layers 3602, 3604a, 3604b, 3606, 3608a and 3608b correspond to layers 3502, 3504a, 3504b, 3506, 3508a and 3508b of device 3500. Multiple lithography and materials deposition steps may be used to form the metal contacts, passivation layer, and antireflection coating. The device structure has a mesa structure, produced by etching. This exposes the underlying layers. A passivation layer 3614 is provided that covers the side-walls of the device and exposed surfaces of layers so as to reduce effects of surface defects and dangling bonds that may otherwise affect device performance. The passivation layer can be formed using a dielectric material such as silicon nitride, silicon oxide, or titanium oxide. Anti-reflection layer 3616 overlies a first portion of second contact layer 3608a. The antireflection layer can be formed using a dielectric material such as silicon nitride, silicon oxide, and titanium oxide. A first metal contact 3610 overlies a portion of the first contact layer 3504a. A second metal contact overlies a portion of second contact layer 3608b. Metallization schemes for contacting to n-doped and p-doped materials are known to those ordinarily skilled in the art. Exemplary photodetector 3600 is illuminated from the top surface of the device—i.e. through the interface between anti-reflection coating 3616 and air. A photodetector may be illuminated via the bottom surface (i.e. the interface between the lower surface of the substrate and air). The bottom surface of the substrate may be coated with an anti-reflection coating. Incident optical radiation on a detector will generate an electronic signal at the detector.

### E. Examples of Photodetectors Including Dilute Nitride Materials in an Active Layer

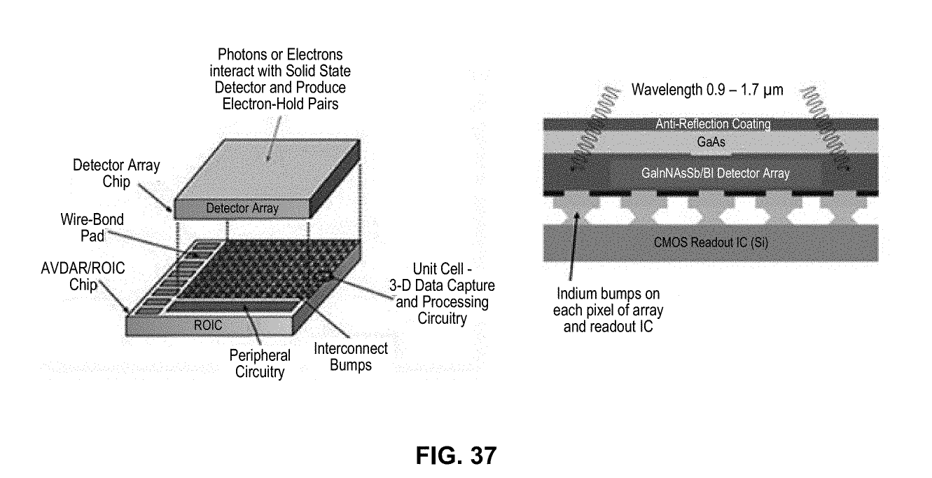

For an array of detectors, the collected signals may be amplified by a readout circuit (ROIC) composed of a simple transistor or a trans-impedance amplifier to form a Focal Plane Array (FPA). This is shown in FIG. 37.

### Example 1

X-Ray and Photoluminescence Characterization of GaInNAsSb Layers

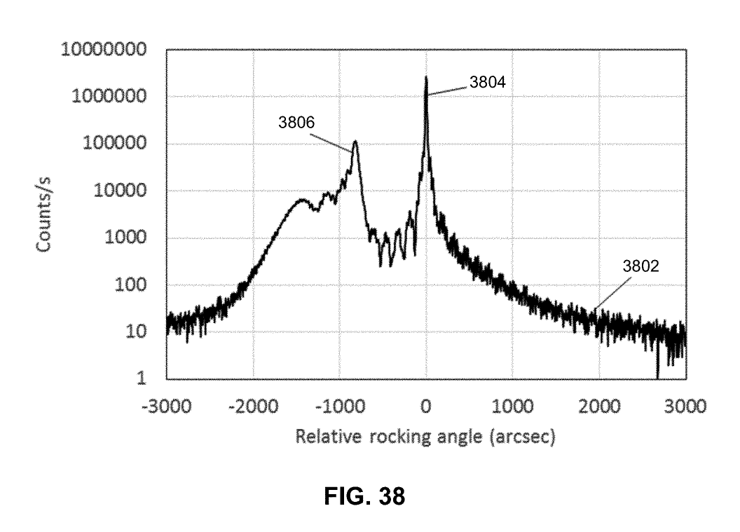

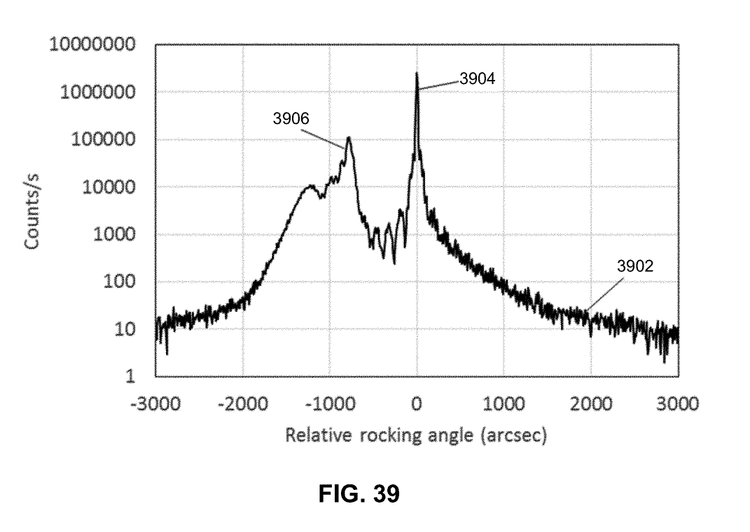

Dilute nitride GaInNAsSb materials, with band gaps between about 0.8 eV and 0.92 eV suitable for incorporation into photodetectors have been characterized by x-ray diffraction (XRD) and photoluminescence (PL) spectroscopy. The thickness of the dilute nitride absorber layer for these samples was approximately 0.5 μm. FIGS. 38 and 39 show XRD scans for GaInNAsSb layers, with band gaps of about 0.855 eV and 0.912 eV, respectively, epitaxially formed using MBE on GaAs substrates. The layers are pseudomorphic layers (non-relaxed). Scan 3802 for the 0.855 eV material has two peaks 3804 and 3806, indicating the presence of two different lattice parameters. Peak 3804 corresponds to the GaAs substrate and peak 3806 corresponds to the GaInNAsSb layer. Peak 3806 is shifted by about −820 arcsec from peak 3808, indicating the GaInNAsSb layer is compressively strained with respect to GaAs.

Scan 3902 for the 0.912 eV material has two peaks 3904 and 3906, indicating the presence of two different lattice parameters. Peak 3904 corresponds to the GaAs substrate and peak 3906 corresponds to the GaInNAsSb layer. Peak 3906 is shifted by about −780 arcsec from peak 3908, indicating the GaInNAsSb layer is compressively strained with respect to GaAs.

The narrowness of peaks 3804, 3806, 3904, and 3906 indicates that the GaInNAsSb layers have high crystallinity and low defect levels.

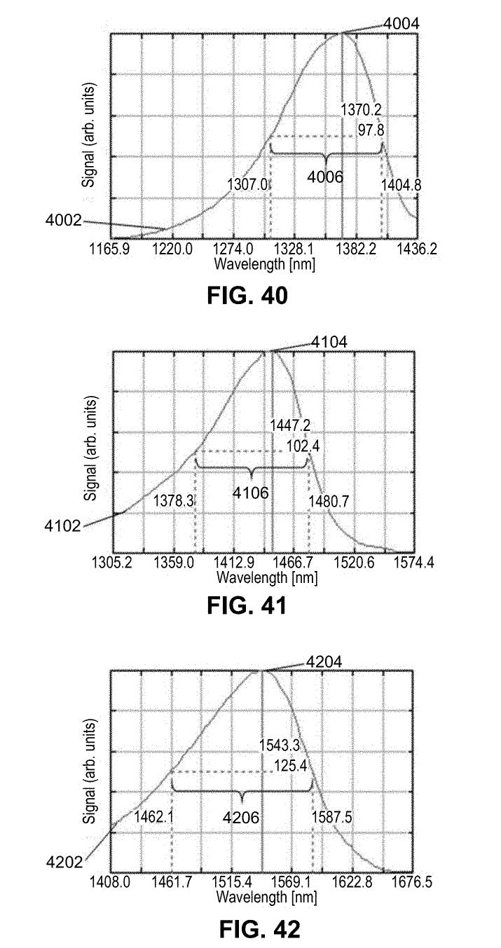

FIGS. 40, 41 and 42 show PL spectra for different samples with band gaps between about 0.8 eV and 0.92 eV, respectively. Scan 802 includes a peak 804 at a wavelength of 1370.2 nm, corresponding to an energy of about 0.905 eV. Scan 802 includes a full-width-half-maximum (FWHM) 806 of 97.8 nm. This narrow width indicates good material quality.

Scan 902 includes a peak 904 at a wavelength of 1447.2 nm, corresponding to an energy of about 0.857 eV. Scan 902 includes a full-width-half-maximum (FWHM) 906 of 102.4 nm. This narrow width indicates good material quality.

Scan 1002 includes a peak 1004 at a wavelength of 1543.3 nm, corresponding to an energy of about 0.803 eV. Scan 1002 includes a full-width-half-maximum (FWHM) 1006 of 125.4 nm. This narrow width also indicates good material quality.

### Example 2

GaInNAsSb-Based Photodetectors Grown on GaAs

Photodetectors incorporating a dilute nitride layer comprising GaInNAsSb and having band gaps within a range from 0.9 eV to 0.92 eV were fabricated. The structure of the photodetectors is shown in FIG. 36. Photoluminescence (PL) measurements for the dilute nitride layers exhibited a full-width half maximum within a range from 50 nm to 70 nm. The thickness of the dilute nitride layers was within a range from 0.5 μm to 1.5 μm. The photodetector structures included a semi-insulating (SI) GaAs substrate. The first contact layer was a p-doped GaAs layer with a thickness of 1 μm, and a doping level of 5×10¹⁸ cm⁻³. The first barrier layer was a p-doped GaAs layer with a thickness of 0.1 μm, and a doping level of 1×10¹⁸ cm⁻³. The active layer was an intrinsic (or unintentionally doped) GaInNAsSb layer. The second barrier layer was an n-doped GaAs layer with a thickness of 0.1 μm, and a doping level of 1×10¹⁸ cm⁻³. The second contact layer is an n-doped GaAs layer with a thickness of 50 nm and a doping level of 1×10¹⁹ cm⁻³. The strain of the dilute nitride layer was characterized using high-resolution X-ray diffraction (XRD), and exhibited a peak splitting between the substrate and dilute nitride layer in the within a range from −600 arcsec to −1000 arcsec, corresponding to a compressive strain of 0.2% to 0.35%. Devices with active layers with compressive strain up to 0.4% are also possible. Photodetectors with diameters within a range from 20 jim to 3 mm were also fabricated.

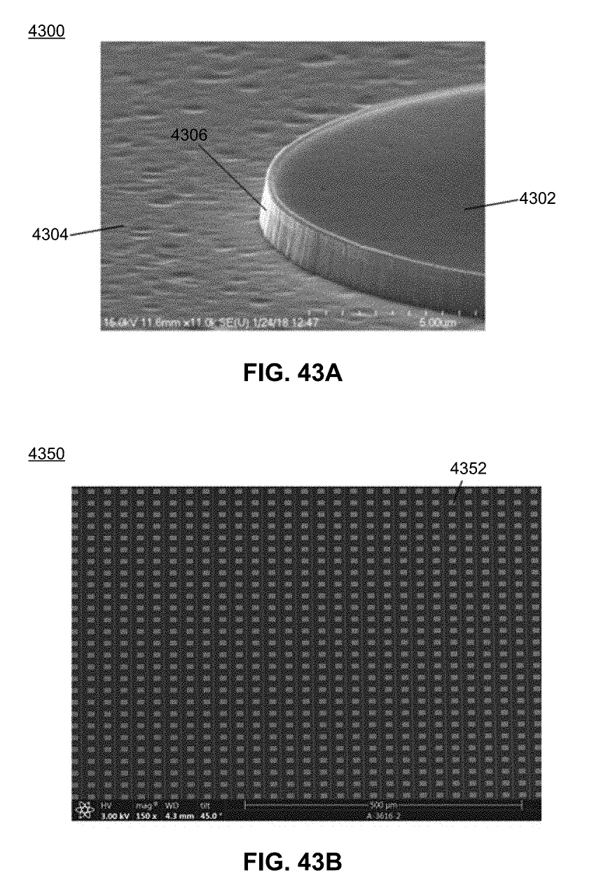

Detectors, and arrays of detectors, were fabricated by etching through the dilute nitride materials to form mesa structures, with device diameters up to about 1 mm. Methods to etch dilute nitride materials include wet etch processes such as those described in U.S. Pat. No. 9,263,611 and U.S. Pat. No. 9,627,561, both of which are incorporated herein in their entirety, and dry etching techniques such as an inductance-coupled plasma (ICP). The etch process can be configured to provide smooth sidewalls, with sidewall angles between about 80° and 90° (perpendicular to the substrate), or between about 70° and 90°. FIG. 43A shows a scanning electron microscopy image of a dilute nitride material etched using an ICP etch, forming a mesa 4300. Mesa 4300 has a top surface 4302, a bottom surface 4304, and a sidewall 4306 having a sidewall angle with respect to the surface. The sidewall angle is less than 90° but greater than 80°. Standard passivation and metallization steps known in the art were used to complete the devices. FIG. 43B shows a scanning electron microscopy image of part of an array of dilute nitride photodetectors 4350. Array 4350 is formed by a two-dimensional array of photodetector mesa structures 4352. Arrays of 320 by 256 detector elements or pixels have been fabricated. The sidewall angles allow closely spaced photodetectors. In some embodiments, the length and width of mesa 4300 may each be approximately 6 μm. In some embodiments, the minimum mesa pitch may be 30 μm. In other embodiments, the minimum mesa pitch may be 12 μm.

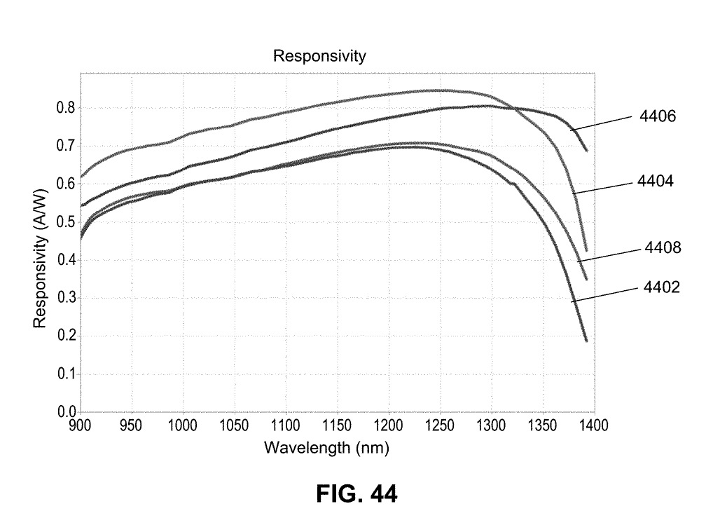

FIG. 44 shows responsivity curves for four (4) photodetectors fabricated according to the present invention. The GaInNAsSb layer was compressively strained, with an XRD peak splitting of 600 arcsec or 800 arcsec between the dilute nitride peak and the substrate peak. Responsivity curve 4402 is for a device with a 0.5 μm thick dilute nitride layer and an XRD peak splitting of 600 arc sec. Responsivity curve 4404 is for a device with a 1 μm thick dilute nitride layer and an XRD peak splitting of 600 arc sec. Responsivity curve 4406 is for a with a 1.5 μm thick dilute nitride layer and an XRD peak splitting of 600 arc sec. Responsivity curve 4408 is for a with a 0.5 μm thick dilute nitride layer and an XRD peak splitting of 800 arc sec.

Responsivities within a range from 0.6 A/W to 0.85 A/W (at a wavelength of 1300 nm) measured for these photodetectors. Responsivity was measured using a broad band halogen lamp, with light monochromatized with 10 nm wavelength steps, and calibrated using a NIST traceable InGaAs detector.

Photodetectors having a diameter of 1 mm exhibited dark currents as low as 3.6 nA at a bias voltage of 1V, measured at room temperature (20° C. to 25° C.).

To assess GaInNAsSb materials quality, GaInNAsSb layers were grown on undoped GaAs, with thicknesses within a range from 250 nm and 2 μm. The GaInNAsSb layers were capped with GaAs. Time-resolved photoluminescence (TRPL) measurements were performed to determine the minority carrier lifetime of the GaInNAsSb layer. TRPL is a contactless method to characterize recombination and carrier transport in photovoltaic materials. Minority carrier lifetime for a material can be affected by parameters including the background carrier concentration, as well as the number of other defects that can cause non-radiative effects and carrier trapping. Lower background carrier concentrations and/or the lower the number of defects results in a longer minority carrier lifetime, which is indicative of high quality semiconductor material. The TRPL kinetics were measured at an excitation wavelength of 970 nm, with an average CW power of 0.250 mW, and a pulse duration of 200 fs generated by a Ti:Sapphire:OPA laser. The pulse repetition rate was 250 kHz. The laser beam diameter at the sample was approximately 1 mm. Whereas typical dilute nitride materials have been reported with minority carrier lifetimes below 1 ns, materials according to the present invention have higher carrier lifetime values, with carrier lifetimes between approximately 1.1 and 2.5 ns. Certain GaInNAsSb layers exhibited a minority carrier lifetime greater than 2 ns.

While background carrier concentrations of less than about 10¹⁶ cm⁻³ and as low as about 10¹⁵ cm⁻³ have been reported, for example, in U.S. Patent Application 2009/0014061, these materials exhibit minority carrier lifetimes of less than 1 ns. This indicates that background carrier concentration alone does not determine the minority carrier lifetime but that the number or concentration of other defects within the material that can act as recombination centers while not contributing free carriers can also degrade the electrical and optical properties of the materials, resulting in reduced carrier lifetimes and inferior device performance. Minority carrier lifetimes of greater than 1 ns therefore indicate lower levels of these other defects and it is believed that this contributes to the significantly higher responsivities than previously thought achievable for dilute nitride based photodetectors

### F. Power Converters Including Dilute Nitride Materials in an Active Layer

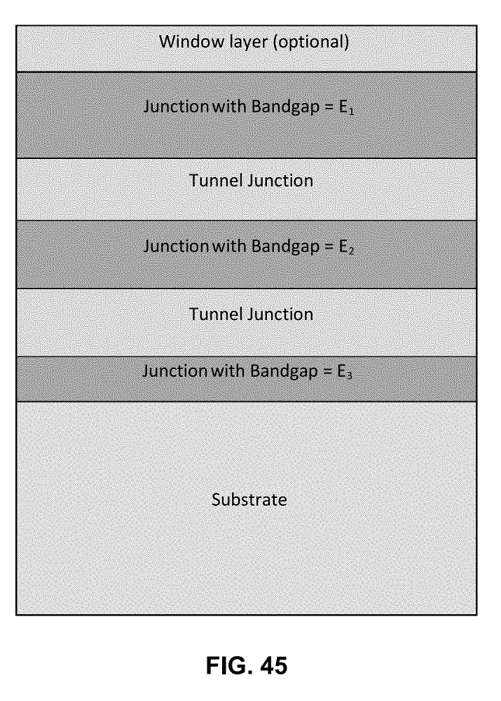

In certain embodiments provided by the present disclosure, two or more epitaxial layers of the same semiconductor material grown on a substrate, such as GaInNAs, GaInNAsSb, GaAs, Ge, GaSb, InP or other substrate known in the art, are stacked on top of one another with tunnel junctions in between each epitaxial layer. FIG. 45 shows an embodiment of a monolithic multijunction power converter in which E₁, E₂, and E₃ represent semiconductor materials having the same band gap. Each epitaxial layer has the same band gap, which is roughly matched to the energy of the monochromatic light source to minimize minority carrier and thermal losses. In certain embodiments, the light source reaches the uppermost epitaxial layer furthest from the substrate. In some embodiments, the epitaxial layer material may be a dilute-nitride material, such as GaInNAs or GaInNAsSb, or other dilute nitride known in the art. In some embodiments, the monochromatic light source is between 1 micron and up to 1.55 microns, and in certain embodiments, the light source is approximately 1.3 microns. While some current may be lost through light absorption by the tunnel junction(s), light that is not collected in the first epitaxial layer is collected in the second epitaxial layer, and so on. The overall efficiency of such a device may reach at least 50% power efficiency, such as from 50% to 60% or from 50% to 70%. In certain embodiments, the power conversion efficiency of a single junction power converter is at least 20% such as from 20% to 40%. In certain embodiments, the power conversion efficiency of a single junction power converter is at least 30% such as from 30% to 50%. In certain embodiments, three junction devices provided by the present disclosure exhibit a conversion efficiency from about 23% to about 25% over an input power from about 0.6 W to about 6 W when irradiated with 1.32 micron radiation.

In certain embodiments, three or more epitaxial layers of the same semiconductor material grown on a substrate such as GaInNAs, GaInNAsSb, GaAs, Ge, GaSb, InP or other substrate known in the art, are stacked on top of one another with tunnel junctions in between each epitaxial layer. Increasing the number of junctions in a power converter device can result in increased fill factor, increased open circuit voltage (Voc) and decreased short circuit current (Jsc). Each epitaxial layer has the same band gap, which is roughly matched to the energy of the monochromatic light source to minimize minority carrier and thermal losses. In certain embodiments, the light source reaches the bottom most epitaxial layer closet to the substrate first. The substrate has a band gap that is higher than the band gap of the epitaxial layers. Given that the substrate has a higher band gap than that of the epitaxial layers, the light source passes through the substrate and the light is absorbed by the epitaxial layers. An example of this employs GaInNAs epitaxial layers (band gap of 0.95 eV) and a GaAs substrate (band gap 1.42 eV). The light source in this example will not be absorbed by the GaAs substrate and will be absorbed by the GaInNAs active region. A heat sink can be coupled to the top of the uppermost epitaxial layer, and can serve to cool the device and prevent defects caused by overheating. In some embodiments, the epitaxial layer material may be a dilute-nitride material, such as GaInNAs or GaInNAsSb, or other dilute nitride known in the art. In some embodiments, the monochromatic light source has a wavelength between 1 micron and up to 1.55 microns, in certain embodiments, from 1 micron to 1.4 micron, and in certain embodiments the light source is approximately 1.3 microns. While some current may be lost through light absorption by the tunnel junction(s), light that is not collected in the first epitaxial layer can be collected in the second epitaxial layer, and so on. The overall efficiency of such a device may reach at least 50% power efficiency.

In certain embodiments, the light absorbing layer(s) comprise GaInNAsSb. In certain of the embodiments, a GaInNAsSb junction comprises Ga₁₋ₓInₓN_{y}As_{1-y-z}Sb_{z}, in which values for x, y, and z are 0≤x≤0.24, 0.01≤y≤0.07 and 0.001≤z≤0.20; in certain embodiments, 0.02≤x≤0.24, 0.01≤y≤0.07 and 0.001≤z≤0.03; in certain embodiments, 0.02≤x≤0.18, 0.01≤y≤0.04 and 0.001≤z≤0.03; in certain embodiments, 0.08≤x≤0.18, 0.025≤y≤0.04 and 0.001≤z≤0.03; and in certain embodiments, 0.06≤x≤0.20, 0.02≤y≤0.05 and 0.005 z>0.02.

In certain of the embodiments, a GaInNAsSb junction comprises Ga₁₋ₓInₓN_{y}As_{1-y-z}Sb_{z}, in which values for x, y, and z are 0≤x≤0.18, 0.001≤y≤0.05 and 0.001≤z≤0.15, and in certain embodiments, 0≤x≤0.18, 0.001≤y≤0.05 and 0.001≤z≤0.03; in certain embodiments, 0.02≤x≤0.18, 0.005≤y≤0.04 and 0.001≤z≤0.03; in certain embodiments, 0.04≤x≤0.18, 0.01≤y≤0.04 and 0.001≤z≤0.03; in certain embodiments, 0.06≤x≤0.18, 0.015≤y≤0.04 and 0.001≤z≤0.03; and in certain embodiments, 0.08≤x≤0.18, 0.025≤y≤0.04 and 0.001≤z≤0.03.

In certain embodiments, a GaInNAsSb junction is characterized by a band gap of 0.92 eV and comprises Ga₁₋ₓInₓN_{y}As_{1-y-z}Sb_{z}, in which values for x, y, and z are: x is 0.175, y is 0.04, and 0.012≤z≤0.019, and wherein the In/Sb ratio is greater than 9.

In certain embodiments, a GaInNAsSb junction is characterized by a band gap of 0.90 eV and comprises Ga₁₋ₓInₓN_{y}As_{1-y-z}Sb_{z}, in which values for x, y, and z are: x is 0.18, y is 0.045, and 0.012≤z≤0.019, and wherein the In/Sb ratio is greater than 9.

In certain embodiments, a GaInNAsSb junction comprises Ga₁₋ₓInₓN_{y}As_{1-y-z}Sb_{z}, in which values for x, y, and z are: 0.13≤x≤0.19, 0.03≤y≤0.048, and 0.007≤z≤0.02. As indicated, the minimum In/Sb ratio for this compositional range is 6.5. The compositional range covers band gaps between about 0.82 eV and 0.98 eV.

In certain embodiments, a GaInNAsSb junction comprises Ga₁₋ₓInₓN_{y}As_{1-y-z}Sb_{z}, in which values for x, y, and z are selected to have a band gap that matches or closely matches the energy of the radiation used to deliver power to the device. In certain embodiments, the GaInNAsSb junction is substantially lattice matched to a GaAs substrate. It is to be noted that the general understanding of “substantially lattice matched” is that the in-plane lattice constants of the materials in their fully relaxed states differ by less than 0.6% when the materials are present in thicknesses greater than 100 nm. Further, subcells that are substantially lattice matched to each other as used herein means that all materials in the subcells that are present in thicknesses greater than 100 nm have in-plane lattice constants in their fully relaxed states that differ by less than 0.6%.

In certain embodiments, each of the epitaxial layers in the power converter is lattice matched to a GaAs substrate.

In certain embodiments, the use of layering materials of different refractive indices can produce distributed Bragg reflectors (DBR) within the structure and is used to increase the efficiency of the power converter. One such example uses a dilute nitride material, which in certain embodiments is a GaInNAsSb material, as the absorbing material in the epitaxial stack of the structure. A cavity can be grown using a material such as GaAs/AlGaAs as a DBR below the dilute nitride layer and above the substrate, and another DBR grown above the dilute nitride layer, that can be made of semiconductors or a number of oxides.

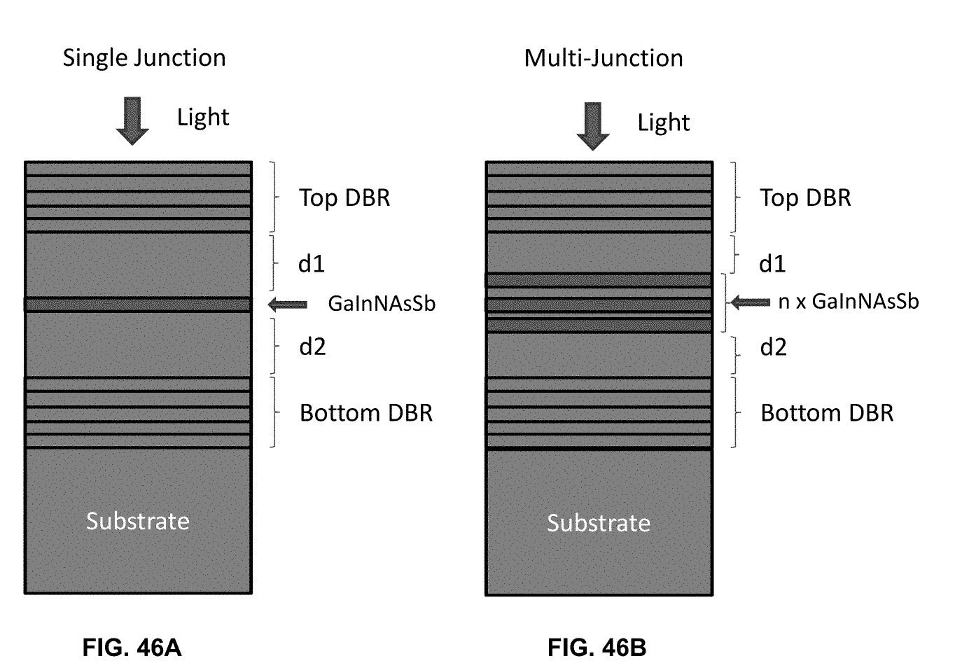

In certain embodiments, where the substrate has a higher band gap than the absorbing material, a back-side metal can be used as structured mirror, allowing unabsorbed light to be reflected from the back metal to be reabsorbed in the epitaxial layers above. Examples of resonant cavity power converters using the double pass configuration are shown in FIGS. 46A and 46B. FIG. 46A shows a single junction resonant cavity with a top DBR and a bottom DBR. A single GaInNAsSb junction is disposed between the two DBRs and separated from the DBRs by semiconductor layers d1 and d2. Semiconductor layers may be formed from a material that does not appreciably absorb the incident radiation and that can be lattice matched to GaAs and the absorbing layer, and in certain embodiments can be GaAs. The thickness of d1, d2 and a GaInNAsSb junction can be selected to provide a standing wave at the wavelength of the incident radiation. FIG. 46B shows a similar configuration as shown in FIG. 46A but includes multiple GaInNAsSb junctions with each of the junctions separated by a tunnel junction. The thickness of the GaInNAsSb junction can be from about 100 nm to about 1 micron. In certain embodiments, the substrate is a semi-insulating or n-doped GaAs substrate with a back-metal as the bottom-most layer of the structure.

For use with 1 micron to 1.55 micron radiation, the mirror layer can be, for example, gold or gold/nickel alloys.

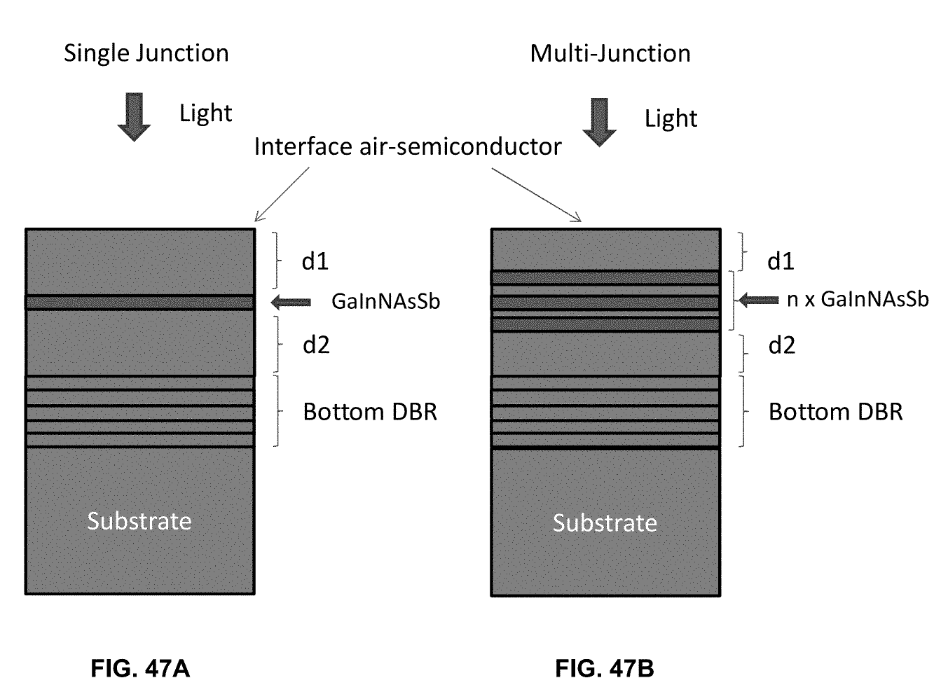

In certain embodiments, the power converter structure uses one DBR instead of two. Resonant power converters employing a single DBR are shown in FIGS. 47A and 47B. FIG. 47A shows a single GaInNAsSb junction disposed between two semiconductor layers d1 and d2. These layers overly a bottom DBR, which overlies a substrate. The upper surface of the device, such as the upper surface of layer d1 facing the incident radiation may be coated with an antireflection coating. The antireflection coating may be optimized for the wavelength of the incident radiation to reduce scattering. FIG. 47B shows a single DBR resonant cavity configuration having multiple GaInNAsSb junctions.

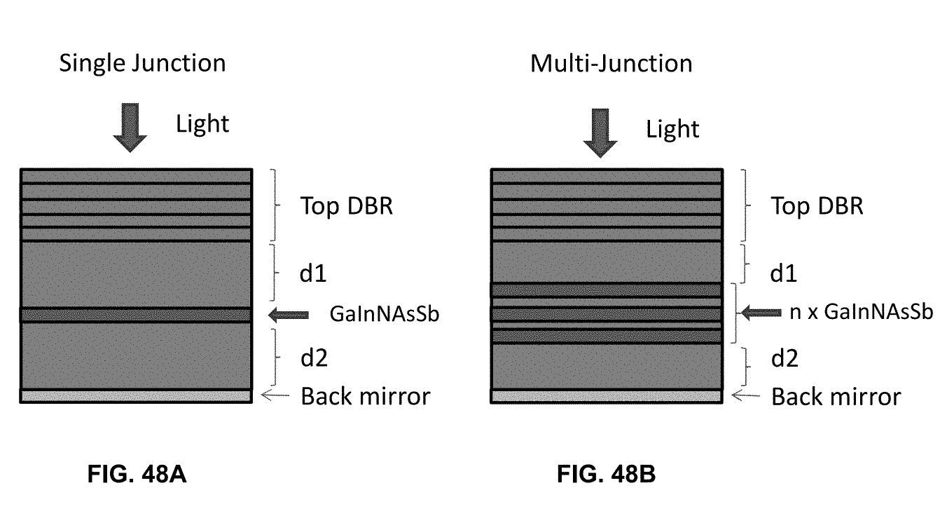

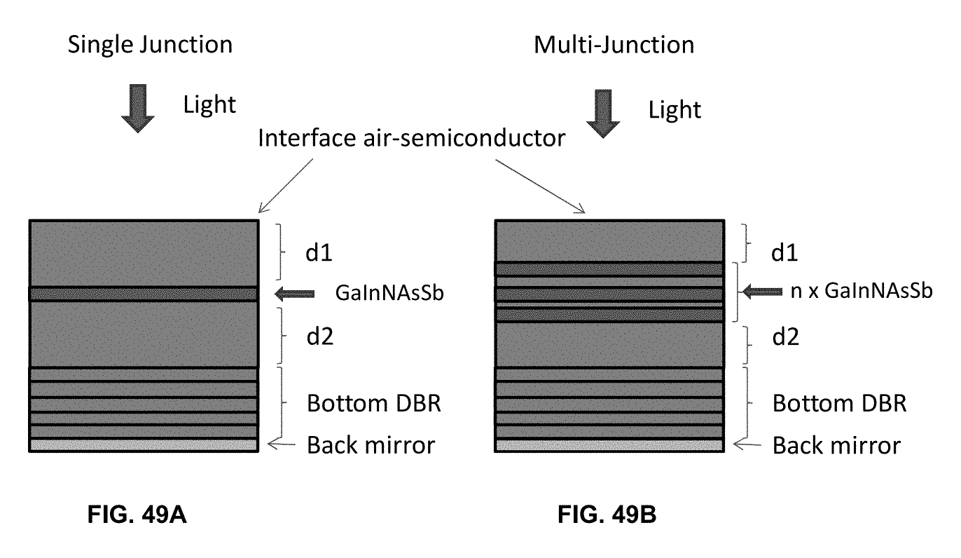

In certain embodiments, the power converter structure includes one DBR and a back mirror below the substrate. Such device configurations are shown in FIGS. 48A, 48B, 49A, and 49B. FIGS. 48A and 48B show power converters having a top DBR a resonant cavity including a single GaInNAsSb junction between two semiconductor layers d1 and d2, and a back mirror beneath semiconductor layer d2. In certain embodiments, the back mirror can also serve as an electrical contact. A multi junction power converter is shown in FIG. 48B in which multiple GaInNAsSb junctions are disposed between a top DBR and a back mirror.

In the power converters shown in FIGS. 49A and 49B both a DBR and a back mirror are used at the bottom of the device. In this configuration the thickness of the DBR can be reduced compared to a configuration with a bottom DBR without the back mirror. As with other devices, the upper surface of layer D1 may include an antireflection coating. In certain embodiments, the substrate is removed and a metal is used it its place as a back mirror. In such structures, the light passes through the top DBR, then through the epitaxial layers, then through the bottom DBR and finally hits the back mirror. In these embodiments, the epitaxial layer comprises GaInNAsSb as one or more absorbing layers.

In certain embodiments, the upper most layer of the structure comprises an interface air-semiconductor above the epitaxial layers, which may comprise of one or more layers of GaInNAsSb. Below the epitaxial layer is a bottom DBR which overlays a back mirror. In these embodiments, the light hits the upper most layer of the interface air-semiconductor and moves to the epitaxial layer, then the DBR and finally reflects back through the structure after being reflected by the back mirror.

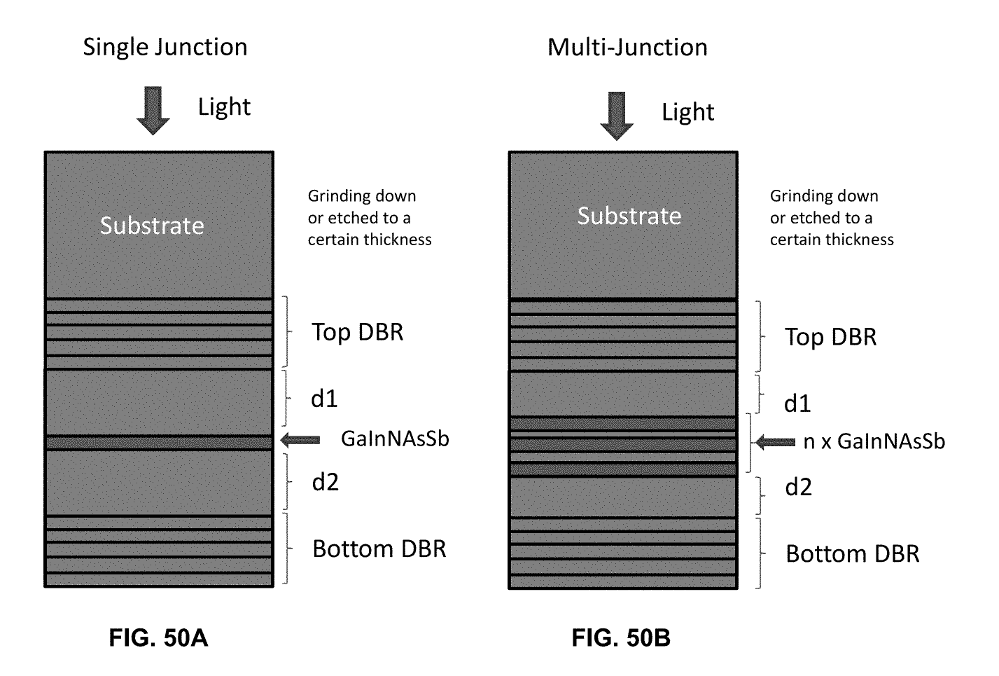

Resonant cavity configurations with two DBRs and a top substrate layer are shown in FIGS. 50A and 50B. The top substrate layer is substantially transparent to the incident radiation used to generate the power. In certain embodiments, the substrate can be GaAs such as n-type GaAs and can have a thickness from about 150 microns to about 250 microns, such as from 175 microns to 225 microns. The thickness of the substrate can be thinned, for example, by grinding or etching to minimize absorption and in such embodiments can be 50 microns or less. In certain embodiments, the bottom DBR can be bonded to a heatsink. Bonding the DBR directly to the heatsink can reduce the temperature of the power converter.

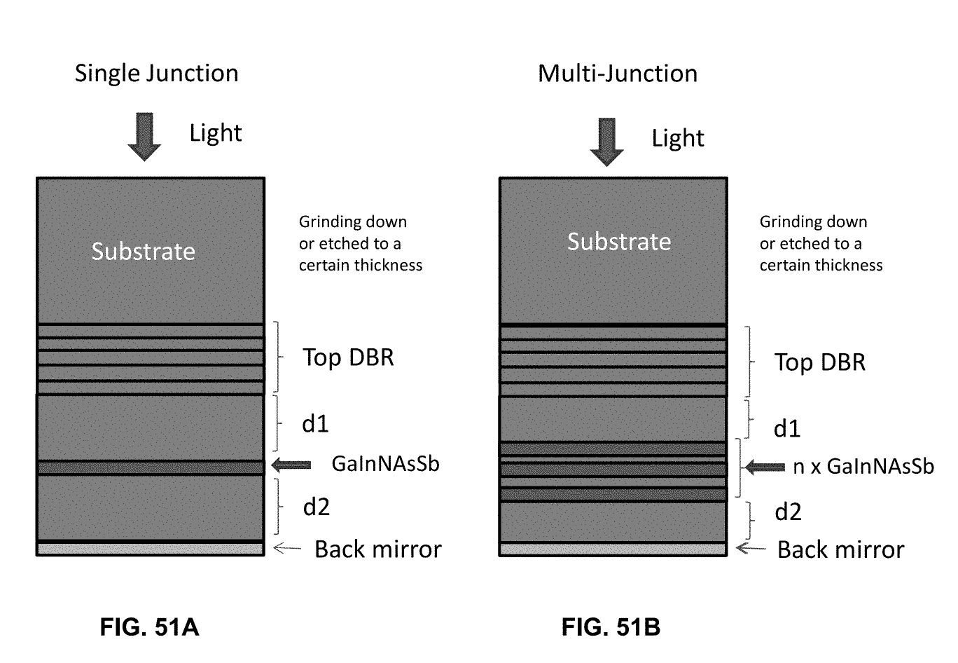

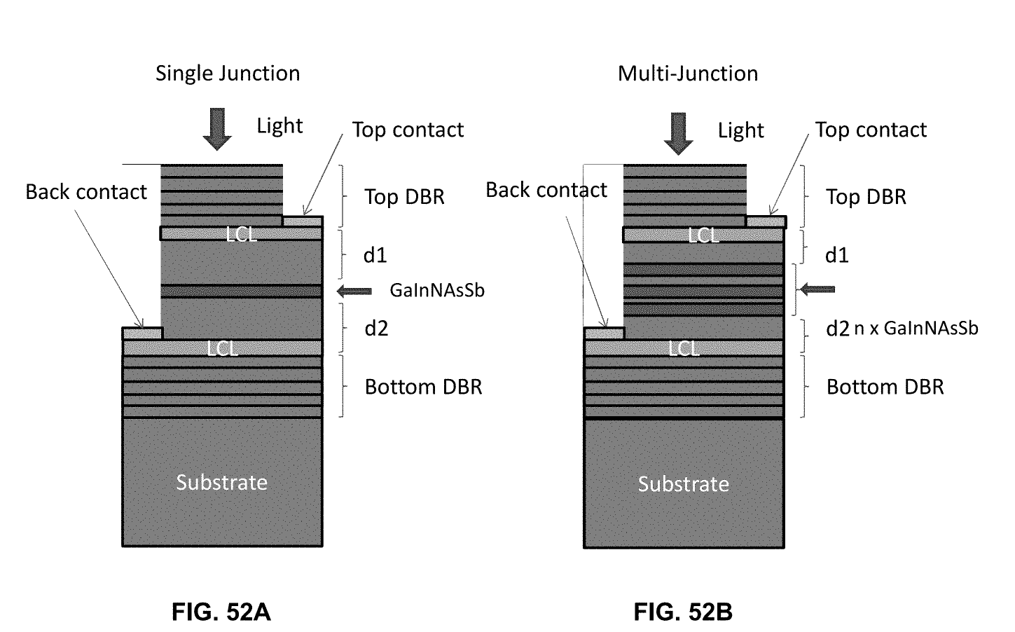

FIGS. 51A and 51B shown device configurations similar to those shown in FIGS. 52A and 52B but with the bottom DBR replaced with a back mirror.

In certain embodiments, the structure has intra-cavity contacts to avoid resistivity from the DBR structures. The contact is made in the cavity through lateral transport conducting layers (LCL) bypassing the DBR structures. Power converters having intra-cavity contacts are shown in FIGS. 8A and 8B. In these device structures the epitaxial layers are etched down to either an LCL overlying the bottom DBR or to an LCL overlying semiconductor layer d1. The LCLs improve carrier mobility to the electrical contacts (back contact and top contact) and can be formed, for example, from doped GaAs such as n-type GaAs. LCLs and similar etch back electrical contacts can be employed with other device structures provided by the present disclosure.

In certain embodiments, the structure can be grown inverted. In such cases, the substrate can be thinned down to a certain thickness or removed after growth using a variety of lift off techniques. The light passes through the substrate first before passing through the epitaxy layers. In such structures, the band gap of the substrate is greater than the band gap of the epitaxial layers.

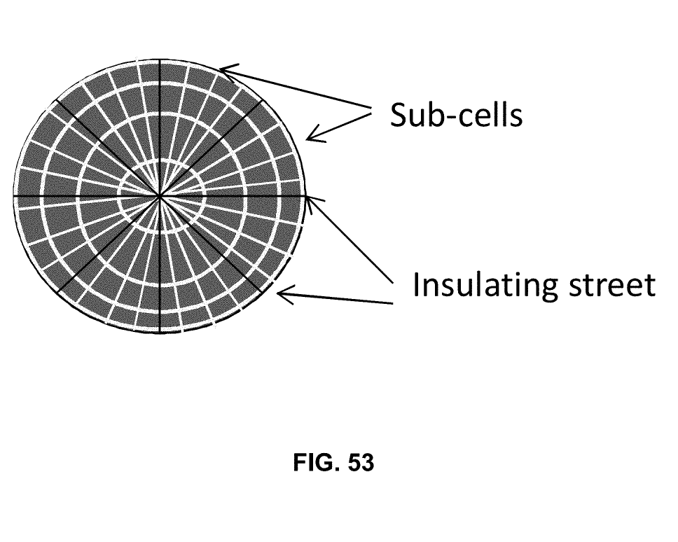

Multiple photovoltaic converters comprised of a number of subcells connected in series can be constructed to increase the output voltage. The subcells can be connected in parallel for increasing output current. An example is a Pi structure as shown in FIG. 53. Infrared absorbers are typically characterized by low voltage; however, in certain application it is desirable to increase the voltage of the power converter. This can be accomplished by connecting multiple power converters in series. One such configuration, of which a top-down view is shown in FIG. 53, is referred to as a Pi structure in which multiple power converter cells are disposed in concentric rings around a central axis, where each cell is separated by an insulator and the multiple cells or subsets of the multiple cells are connected in series. Such structures can be fabricated using single junctions and provide a high density of cells. The higher voltages provide improved DC-DC converter efficiencies and lower Ohmic losses. Although later currents can produce Ohmic losses this can be offset because the increased number of subcells results in lower currents.

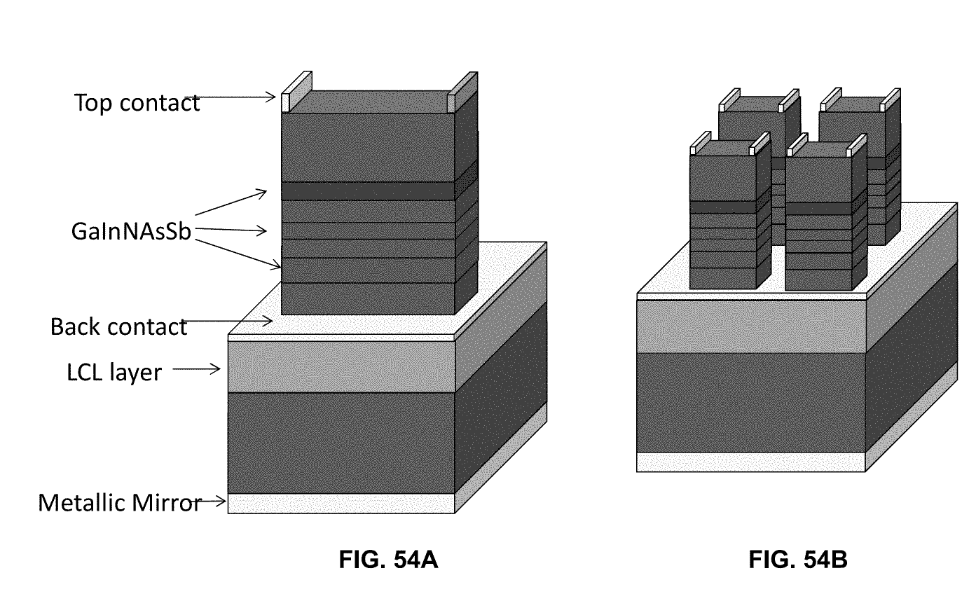

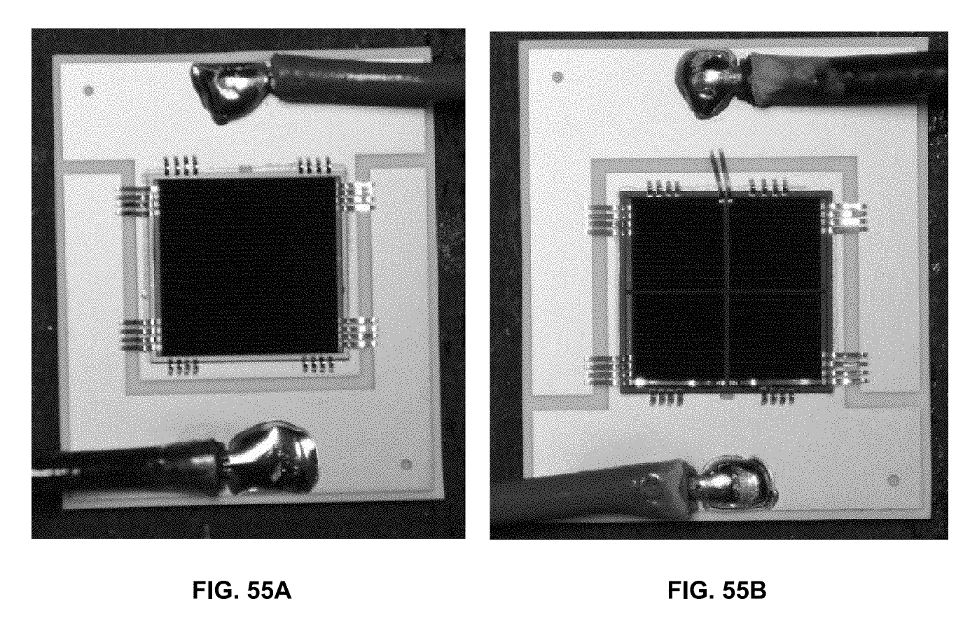

Other device structures are shown in FIGS. 54A and 54B. FIG. 54A shows single a triple junction double pass power converter. FIG. 54B shows a four quadrant triple junction double pass power converter. The dimensions of the devices are 300 microns by 300 microns. The four converters can be interconnected in series to increase the voltage and/or decrease the current. The series interconnection can also reduce the sensitivity to spatial orientation of the incident radiation. Furthermore, for large area power converters, separating the collection area into quadrants or other sub-areas can reduce the Ohmic losses by bringing the electrical contacts closer to the power generating surfaces. Photographs of the single and four quadrant devices are shown in FIGS. 55A and 55B.

The power converters shown in FIGS. 54A, 54B, 55A, and 55B were fabricated using GaInNAsSb junctions. All epitaxial layers were lattice matched to a GaAs substrate. A back mirror is disposed at the bottom of the GaAs substrate. The resonant cavity of the three junction structures was configured to support a standing wave at about 1.3 microns, such as at 1.32 microns or at 1.342 microns. The band gap of the GaInNAsSb junctions was about 0.92 eV for devices configured for power conversion at 1.32 microns. Certain of such devices exhibited a fill factor from about 65% to about 75%, a Voc of from about 1.47 V to about 1.5 V and a Jsc from about 0.6 A to about 1.4 A. The power conversion efficiency was from about 23% to 25% at an input power from about 0.6 W to about 6 W.

In certain embodiments, the two or more epitaxial layers of the same semiconductor material are of varying thicknesses. In particular, the epitaxial layers can decrease in thickness the further away from the light source. In certain embodiments, the thicknesses of each of the epitaxial layers are the same. In certain embodiments, the thicknesses of the epitaxial layers are varied, either increasing nor decreasing depending on the light source location.

In some embodiments, there is a window layer on top of the upper most epitaxial layer.

In certain embodiments, the thickness, or height, of the entire device may be between 1 micron and up to 10 microns. The area of the power converter can be, for example, between 100 microns×100 microns, and up to 1 cm×1 cm, or more. For example the total area is from 10⁻⁴ cm² to 1 cm². The thickness of each epitaxial layer may be between a few hundred nanometers up to a few microns.

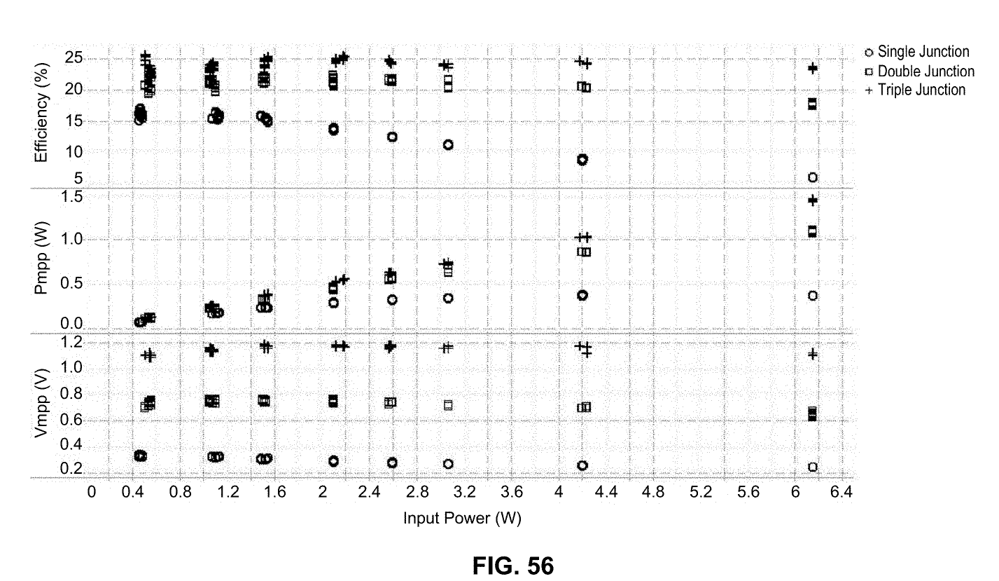

FIG. 56 shows the efficiency, power output and voltage at maximum power point (Mpp) as a function of laser input power for single (open circle), double (square), and triple (plus) GaInNAsSb junction power converters. The measurements were made using a semiconductor laser operating at a wavelength of 1.32 μm, a spot size of about 4 mm by 4 mm and at temperatures of about 25° C. to 28° C. Focusing on the power conversion efficiency, as the input power increases from 1 W to 6 W the power conversion efficiency of the single GaInNAsSb junction power converter decreases from about 16% to about 6%. In contrast, for the two-junction and 3-junction devices, the power conversion efficiency is relatively constant throughout a range of input powers from 1 W to 6 W. This result is unexpected based on a comparison with the drop-in efficiency with increasing power observed for a single GaInNAsSb power converter. Assuming multiple junctions operate independently, one would expect multiple GaInNAsSb junctions to exhibit the same dramatic decrease in power conversion efficiency with increasing input power as observed for the single GaInNAsSb junction power converter. Such a decrease in power conversion efficiency with increasing input power is in fact observed in multijunction GaAs power converters. Performance degradation can occur due to increased resistive losses at the higher currents associated with higher incident powers, which reduces the fill-factor and the efficiency.

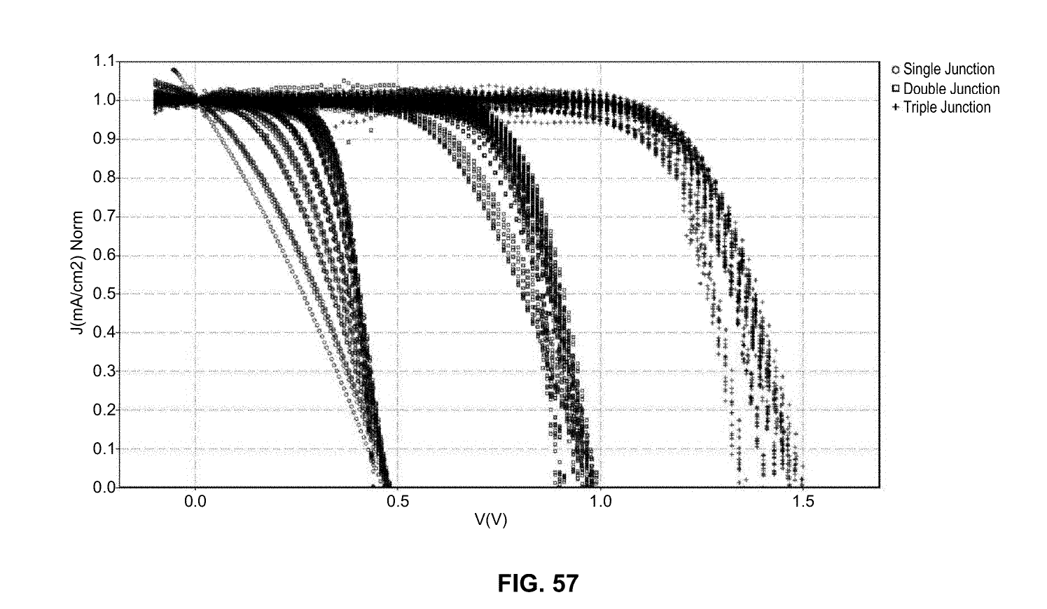

FIG. 57 shows the normalized current density (J) as a function of voltage for several laser input power levels for single (open circle), double (square), and triple (plus) GaInNAsSb junction power converters. For a single junction device (left-most set of curves), as the incident power increases (moving from right to left in that set of curves), the characteristic knee in the I-V curve “softens”, becoming almost linear, and the fill-factor decreases. However, for the two-junction and three-junction devices, this effect is far less pronounced, thus maintaining a high fill-factor, and a high device operating efficiency over the range of incident optical powers.

### G. Fabrication and Characteristics of Devices Having Dilute Nitride Materials

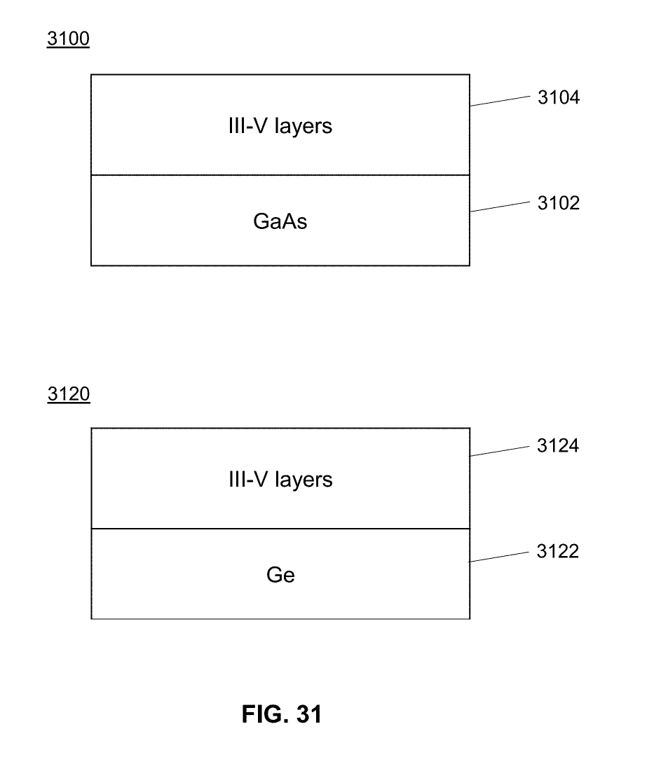

Semiconductor devices of the present invention, such as photodetectors and solar cells comprising III-V semiconductor layers can be grown on either a GaAs or a Ge substrate. The lattice constants of GaAs and Ge are 5.65 Å and 5.66 Å, respectively, and growth of III-V materials with broadly similar compositions without defects can be grown on either substrate. The close matching of the lattice constants of Ge and GaAs allows, for example, high-quality GaAs to be epitaxially grown on a Ge surface. FIG. 31 depicts semiconductor devices 3100 and 3120. Semiconductor device 3100 comprises III-V compound semiconductor layers 3104 epitaxially formed over a GaAs substrate 3102, and semiconductor device 3120 comprises semiconductor layers 3124 formed over a Ge substrate 3122. Semiconductor layers 3104 and 3124 are grown lattice matched or pseudomorphically strained to the substrate, ensuring the formation of high quality III-V layers.

The III-V material can also be grown on a substrate having a lattice constant closely matching that of GaAs or Ge, such as a buffered substrate. In some embodiments, “closely matching” (“or nearly matching”) means a difference between lattice constants of 3% or less. For example, a multijunction photovoltaic cell shown in FIG. 3B is shown where the III-V materials are formed overlying a layer comprising SiGe, such as SiGe(Sn), in which the SiGe(Sn) layer also functions as a subcell of the device.

As will be understood by one of ordinary skill in the art, the SiGe(Sn) can form a buffer layer (or lattice engineered layer) grown on a substrate such as Si that has a low number of defects and/or dislocations in the lattice engineered layer. The buffer layer can provide a lattice constant at the top of the buffer layer approximately equal to that of a GaAs or Ge substrate, enabling the formation of high quality III-V layers on the top of the buffer, with a low number of defects and/or dislocations in the III-V semiconductor layers and/or dilute nitride layers. A low number of defects can include comparable or fewer defects than would occur in an In_{0.53}Ga_{0.47}As layer grown on an InP substrate. Examples of buffered silicon substrates that can provide a lattice constant approximately equal to that of GaAs or Ge include SiGe buffered Si, SiGeSn buffered Si, and rare-earth (RE) buffered Si, such as a rare-earth oxide (REO) buffered Si.

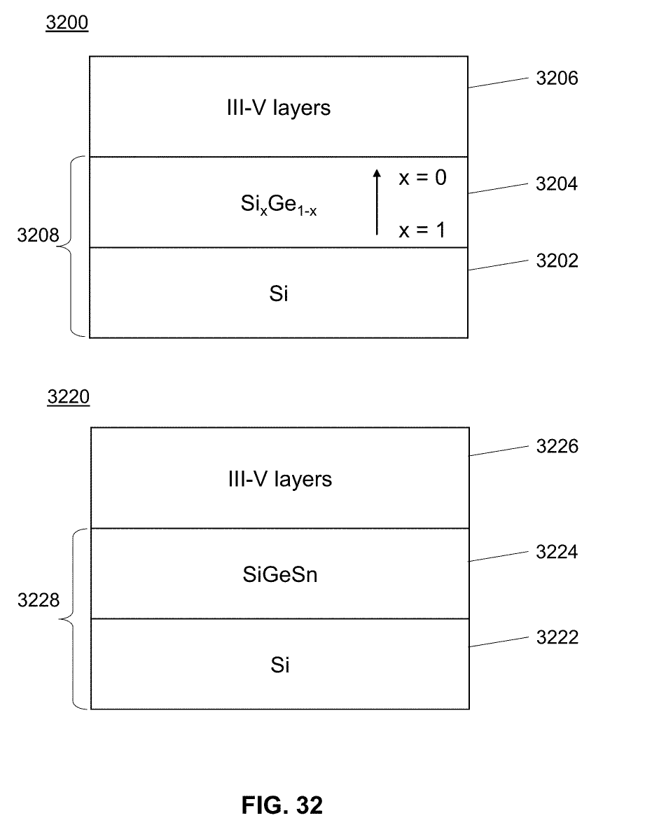

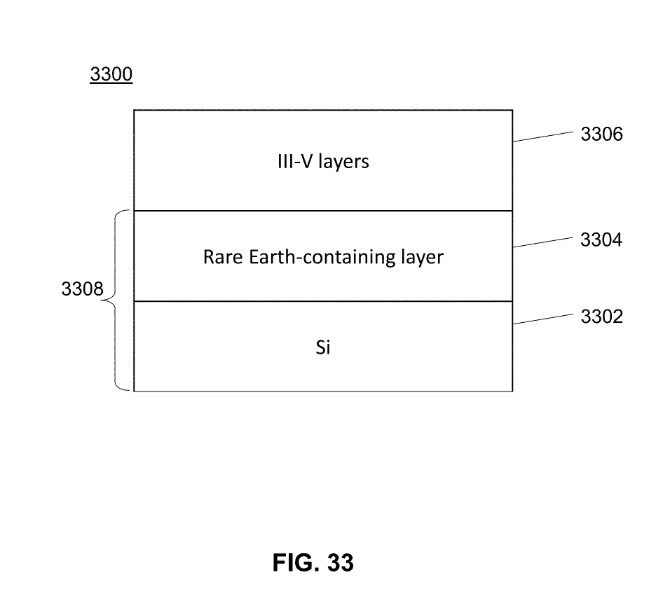

FIGS. 32 and 33 show examples of III-V materials, such as photovoltaic cells, photodetectors and power converters formed over buffered substrates with lattice parameters matching or nearly matching the lattice constant for GaAs or Ge.

FIG. 32 depicts semiconductor devices 3200 and 3220 comprising a lattice engineered buffer layer over a Silicon substrate. Device 3200 comprises a Silicon substrate 3202, a graded SiₓGe₁₋ₓ (0≤x≤1) buffer 3204 overlying the Si substrate and III-V compound semiconductor layers 3206 overlying the buffer 3204. The Si fraction x of the graded SiₓGe₁ₓ layer 3204 varies from 0 to 1 through its thickness. At the interface with the Si substrate 3202, x=1 and the graded SiₓGe₁₋ₓ layer 3204 substantially only contains Si. At the interface with the III-V layers 3206, x=0 and the graded SiₓGe₁₋ₓ layer 3204 substantially only contains Ge. Thus, the graded SiₓGe₁₋ₓ layer 3204 provides a transition in lattice parameter from that of the Si substrate (5.43 Å) to that of Ge (5.66 Å), which nearly matches to that of GaAs (5.65 Å). Thus, the graded SiₓGe₁₋ₓ layer 3204 allows growth of GaAs layers on Si substrates. Together, the graded SiₓGe₁₋ₓ layer 3204 and the silicon substrate 3202 comprise a substrate 3208 having a top surface with a lattice parameter nearly matching GaAs or Ge.

Device 3220 comprises a Silicon substrate 3222, a SiGeSn buffer 3224 overlying the Si substrate and III-V compound semiconductor layers 3206 overlying the buffer 3224. The SiGeSn buffer 3224 can be formed according to the description in U.S. Pat. No. 8,029,905 and can provide a lattice constant approximately equal to that of GaAs or Ge at the interface with the overlying III-V layers 3226, thus allowing the growth of GaAs layers on Si substrates. Together, the SiGeSn layer 3224 and the silicon substrate 3202 comprise a substrate 3228 having a top surface with a lattice parameter nearly matching GaAs or Ge.

FIG. 33 depicts a semiconductor device 3300 comprising a lattice engineered buffer layer over a Silicon substrate. Device 3300 comprises a Silicon substrate 3302, a rare-earth (RE) containing buffer 3304 epitaxially formed overlying the Si substrate and III-V compound semiconductor layers 3306 overlying the buffer 3304. The RE containing layer 3304 is a lattice engineered layer. Rare earth elements are a specific class of elements on the periodic table (Sc, Y, La, Ce, Pr, Nd, Pm, Sm, Eu, Gd, Tb, Dy, Ho, Er, Tm, Yb, Lu). The RE containing layer can contain one or more of the rare earth elements. Generically, the RE containing layer can be a rare earth oxide (REO), a rare earth silicide (RESi), or a pnictide (RE-V, where V represents a group V element from the periodic chart, namely N, P, As, Sb, or Bi) or any combination of REO, RESi, and/or pnictide. The composition of the RE containing layer can be selected to result in a lattice parameter matching or nearly matching GaAs at its interface with the p-i-n diode 1662. For example, the layer at the interface could be ErAsₓN₁₋ₓ, where x is approximately 0.9, which is lattice matched or nearly matched to GaAs. The rare earth containing layer can be of constant composition or graded throughout its thickness. When graded, the layer can be engineered so that the portion nearest the Si is chemically and mechanically compatible with silicon. For example, gadolinium oxide could be employed at or near the interface between the silicon and rare earth containing layer due to its lattice match with silicon. Thus, the RE containing layer 3304 provides a template for epitaxial growth of III-V layers 3306. Together, the RE containing layer 3304 and the silicon substrate 3302 comprise a substrate 3308 having a top surface with a lattice parameter matching or nearly matching GaAs or Ge. The substrates shown in FIGS. 31-33 can be used in any of the semiconductor devices shown in the above embodiments.

In one embodiment of the invention, the semiconductor layers composing the solar cell, photodetector or power converter excepting the substrate, are fabricated using molecular beam epitaxy (MBE) or chemical vapor deposition. In certain embodiments, more than one material deposition chamber is used for the deposition of the semiconductor layers comprising the solar cell, photodetector or power converter. The materials deposition chamber is the apparatus in which the semiconductor layers composing the semiconductor device such as the solar cell, photodetector or power converter are deposited. The conditions inside the chamber may range from 10⁻¹¹ Torr to 10³ Torr pressures. In certain embodiments the alloy constituents are deposited via physical and/or chemical processes. Each materials deposition chamber can have different configurations which allow it to deposit different semiconductor layers and can be independently controlled from other materials deposition chambers. The semiconductor layers may be fabricated using metalorganic chemical vapor deposition (MOCVD), MBE, or by other methods, including a combination of any of the foregoing.

The movement of the substrate and semiconductor layers from one materials deposition chamber to another is defined as the transfer. For example, a substrate is placed in a first materials deposition chamber, and then the buffer layer(s) and the bottom subcell(s) are deposited. Then the substrate and semiconductor layers are transferred to a second materials deposition chamber where the remaining subcells are deposited. The transfer may occur in vacuum, at atmospheric pressure in air or another gaseous environment, or in any environment in between. The transfer may further be between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

In one embodiment of the invention, a plurality of layers is deposited on a substrate in a first materials deposition chamber. The plurality of layers may include etch stop layers, release layers (i.e., layers designed to release the semiconductor layers from the substrate when a specific process sequence, such as chemical etching, is applied), contact layers such as lateral conduction layers, buffer layers, or other semiconductor layers. In one specific embodiment, the sequence of layers deposited is buffer layer(s), then release layer(s), and then lateral conduction or contact layer(s). Next the substrate is transferred to a second materials deposition chamber where one or more subcells are deposited on top of the existing semiconductor layers. The substrate may then be transferred to either the first materials deposition chamber or to a third materials deposition chamber for deposition of one or more subcells and then deposition of one or more contact layers. Tunnel junctions are also formed between the subcells.

In one embodiment of the invention, the III-AsNV subcells (or optical absorption layers) are deposited in a first materials deposition chamber, and the (Al)InGaP, (Al,In)GaAs and (Al)GaInPAs subcells (or other layers required by photodetectors or power converters) are deposited in a second materials deposition chamber, with tunnel junctions formed between the subcells (or absorbing regions). In a related embodiment of the invention, III-AsNV layers are deposited in a first materials deposition chamber, and other semiconductor layers that contain Al are deposited in a second materials deposition chamber. In another embodiment of the invention, a transfer occurs in the middle of the growth of one subcell, such that the said subcell has one or more layers deposited in one materials deposition chamber and one or more layers deposited in a second materials deposition chamber.

In one embodiment of the invention, some or all of the layers composing the III-AsNV optical absorption layers, such as subcells, and the tunnel junctions are deposited in one materials deposition chamber by molecular beam epitaxy, and the remaining layers of the solar cell are deposited by chemical vapor deposition in another materials deposition chamber. For example, with respect to solar cells, a substrate is placed in a first materials deposition chamber and layers that may include nucleation layers, buffer layers, emitter and window layers, contact layers and a tunnel junction are grown on the substrate, followed by one or more III-AsNV subcells. If there is more than one III-AsNV subcell, then a tunnel junction is grown between adjacent subcells. One or more tunnel junction layers may be grown, and then the substrate is transferred to a second materials deposition chamber where the remaining solar cell layers are grown by chemical vapor deposition. In certain embodiments, the chemical vapor deposition system is a MOCVD system. In a related embodiment of the invention, a substrate is placed in a first materials deposition chamber and layers that may include nucleation layers, buffer layers, emitter and window layers, contact layers and a tunnel junction are grown on the substrate by chemical vapor deposition. Subsequently, the top subcells, two or more, are grown on the existing semiconductor layers, with tunnel junctions grown between the subcells. Part of the topmost III-AsNV subcell, such as the window layer, may then be grown. The substrate is then transferred to a second materials deposition chamber where the remaining semiconductor layers of the topmost III-AsNV subcell may be deposited, followed by up to three more III-AsNV subcells, with tunnel junctions between them.

In certain embodiments of the invention, a solar cell, photodetector, power converter, or the like, is subjected to one or more thermal annealing treatments after growth. For example, a thermal annealing treatment includes the application of a temperature of 400° C. to 1000° C. for between 10 seconds and 10 hours. Thermal annealing may be performed in an atmosphere that includes air, nitrogen, arsenic, arsine, phosphorus, phosphine, hydrogen, forming gas, oxygen, helium and any combination of the preceding materials. In certain embodiments, a stack of subcells and associated tunnel junctions may be annealed prior to fabrication of additional subcells.

Thus, methods of manufacturing a photovoltaic cell are provided, comprising: forming one or more semiconductor layers on a substrate; forming four or more subcells overlying the one or more semiconductor layers; and wherein at least one of the subcells has a base layer formed of an alloy of one or more elements from group III on the periodic table, nitrogen, arsenic, and at least one element selected from the group consisting of Sb and Bi; wherein the photovoltaic cell comprises at least four subcells and each of the at least four subcells is substantially lattice matched to each of the other subcells. In certain embodiments, the substrate is a subcell having a base layer formed of a material selected from the group consisting of Ge, SiGe(Sn), and an alloy of one or more elements from group III on the periodic table, nitrogen, arsenic, and at least one element selected from the group consisting of Sb and Bi. In certain embodiments, the methods comprise forming tunnel junctions between the four or more subcells.

In certain embodiments, methods of manufacturing a photovoltaic cell comprise: forming a first subcell having a first base layer formed of a material selected from the group consisting of Ge, SiGe(Sn), and an alloy of one or more elements from group III on the periodic table, nitrogen, arsenic, and at least one element selected from the group consisting of Sb and Bi, wherein the first subcell is characterized by a band gap from 0.7 eV to 1.1 eV; forming a second subcell having a second base layer, wherein the second base layer is formed of an alloy of one or more elements from group III on the periodic table, nitrogen, arsenic, and at least one element selected from the group consisting of Sb and Bi, wherein the second subcell is characterized by a band gap from 0.9 eV to 1.3 eV; and forming at least two additional subcells overlying the second subcell; wherein the photovoltaic cell comprises at least four subcells and each of the at least four subcells is substantially lattice matched to each of the other subcells. In certain methods, each of the at least four subcells is substantially lattice matched to a material selected from the group consisting of Si, Ge, SiGe, GaAs, and InP. In certain methods, the first base layer formed of an alloy Ga₁₋ₓInₓN_{y}As_{1-y-z}Sb_{z}, in which values for x, y and z are 0.02≤x≤0.24, 0.015≤y≤0.07 and 0.001≤z≤0.03; and the second base layer formed of an alloy Ga₁₋ₓInₓN_{y}As_{1-yz}Sb_{z}, in which values for x, y and z are 0≤x≤0.18, 0.005≤y≤0.05 and 0.001≤z≤0.03. In certain methods, forming at least two additional subcells overlying the second subcell comprises: forming a third subcell having a third base layer is overlying the second subcell, wherein the third base layer is formed of a material selected from the group consisting GaInPAs and (Al,In)GaAs, and characterized by a band gap from 1.4 eV to 1.7 eV; and forming a fourth subcell having a fourth base layer overlying the third subcell, wherein the fourth base layer is formed of (Al)InGaP, and characterized by a band gap from 1.9 eV to 2.2 eV.

In certain embodiments, methods of manufacturing a photovoltaic cell comprise: forming at least two subcells on a substrate; forming a first subcell having a first base layer, wherein the first base layer is formed of an alloy of one or more elements from group III on the periodic table, nitrogen, arsenic, and at least one element selected from the group consisting of Sb and Bi, wherein the first subcell is characterized by a band gap from 0.9 eV to 1.3 eV; and forming a second subcell having a second base layer formed of a material selected from the group consisting of Ge, SiGe(Sn), and an alloy of one or more elements from group III on the periodic table, nitrogen, arsenic, and at least one element selected from the group consisting of Sb and Bi, wherein the second subcell is characterized by a band gap from 0.7 eV to 1.1 eV; wherein the photovoltaic cell comprises at least four subcells and each of the at least four subcells is substantially lattice matched to each of the other subcells.

In certain embodiments, methods of manufacturing a photovoltaic cell comprise: forming one or more subcells on a substrate in a first materials deposition chamber; transferring the substrate to a second materials deposition chamber; and forming one or more additional subcells overlying the one or more subcells; and wherein one or more of the subcells of the photovoltaic cell has a base layer formed of an alloy of one or more elements from group III on the periodic table, nitrogen, arsenic, and at least one element selected from the group consisting of Sb and Bi; and wherein each of the subcells is substantially lattice matched to each of the other subcells. In certain embodiments, methods of manufacturing a photovoltaic cell further comprise: forming one or more layers selected from the group consisting of a buffer layer, a contact layer, an etch stop layer, a release layer, and other semiconductor layer on the substrate in a chamber selected from the group consisting of a third materials deposition chamber and the second materials chamber; and transferring the substrate to the first materials deposition chamber.

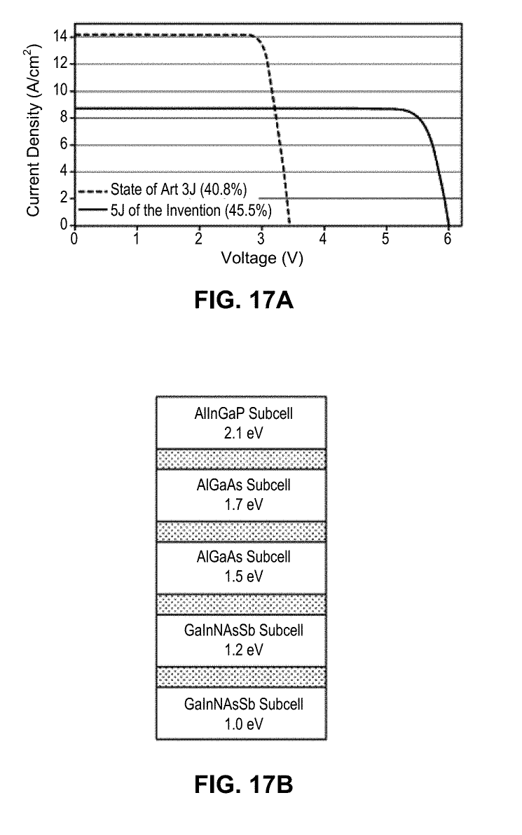

A more specific example of the embodiment illustrated by FIG. 7 is the five junction solar cell depicted in FIG. 17B. The bottom subcell is a GaInNAsSb subcell with a band gap of 1.0 eV and a total subcell thickness of 2-3 microns. J4 is a GaInNAsSb subcell with a band gap of 1.2 eV and a total subcell thickness of 2-3 microns. J3 is an AlGaAs subcell with a band gap of 1.5 eV and a total subcell thickness of 4-5 microns. J2 is an AlGaAs subcell with a band gap of 1.7 eV and a subcell thickness of 4-5 microns. J1 is an AlInGaP subcell with a band gap of 2.1 eV and a subcell thickness of 0.3-1.0 microns. The upper two tunnel junctions comprise GaAs:Si/AlGaAs:C, each with a total thickness of approximately 15 nm to 25 nm. The lower two tunnel junctions are GaAs:Si/GaAs:C, each with total thickness between 40 and 100 nm. All of the subcells are substantially lattice-matched to a GaAs substrate. The solar cell undergoes a thermal anneal after growth and before device processing, and an additional thermal anneal during device processing.

An I-V curve of the simulated current output as a function of voltage of the multijunction solar cell shown in FIG. 17B at 1000 suns under the AM1.5D spectrum at 25° C. is shown in FIG. 17A, along with the performance of the state-of-the-art high efficiency triple-junction solar cell described herein. The two solar cells have bottom GaInNAsSb subcells with the same band gap. The simulated efficiency of the five-junction solar cell according to certain embodiments is 45.5%, compared to 40.8% for the triple-junction solar cell. While the achievable current at this solar concentration is lower for the five-junction solar cell compared to the three-junction solar cell, the voltage is substantially higher. The higher efficiency is achieved because much less of the incident light energy is being lost as heat. More photons are absorbed by subcells with band gaps closer to their energies, allowing more of the energy to be converted into electricity and less into heat.

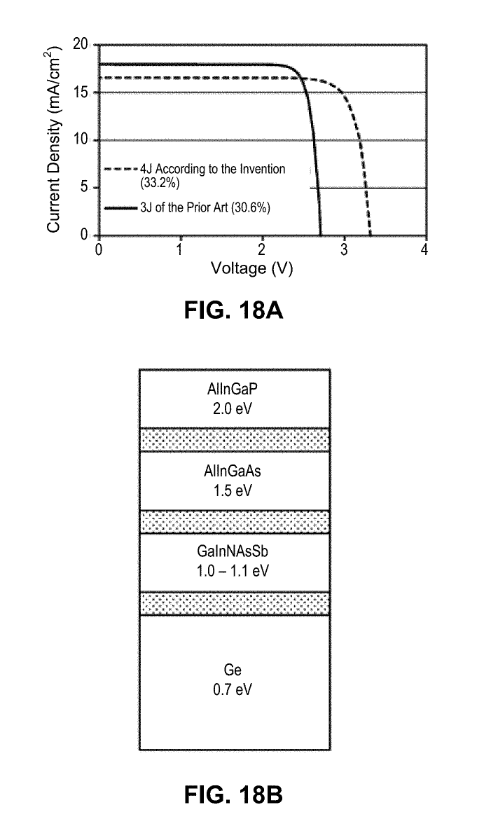

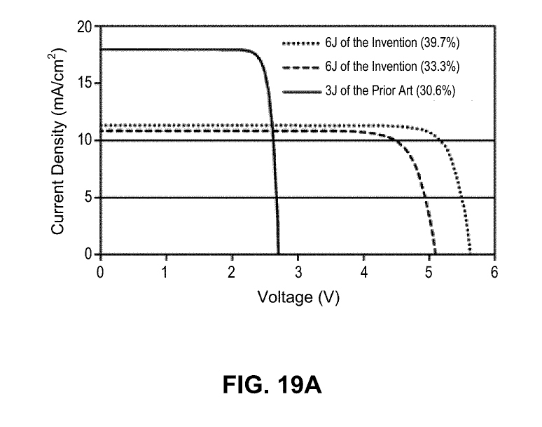

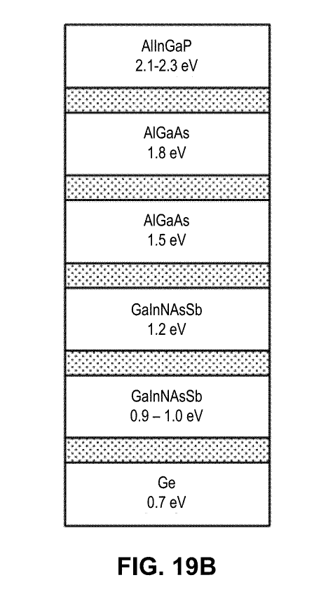

An I-V curve of the simulated current output as a function of voltage of the multijunction solar cell shown in FIG. 18B, a four junction solar cell disclosed by the invention, under the AM0 spectrum at 1 sun at 25° C. is shown in FIG. 18A, along with the simulated performance of the typical InGaP/InGaAs/Ge triple-junction solar cell found on the market today for use in space. The simulated efficiency of the four-junction solar cell disclosed by the invention is 33.2%, compared to 30.6% for the triple-junction solar cell. While the achievable current is lower for the four-junction solar cell compared to the three-junction solar cell, the voltage is substantially higher. I-V curves for the six-junction solar cell disclosed by the invention and shown in FIG. 19B under the AM0 spectrum at 25° C. are shown in FIG. 19A, along with the performance of the state-of-the-art triple-junction solar cell described above. Shown is both the data for a six-junction cell made today, as well as the data for a future cell with improved minority carrier properties. The simulated efficiencies of the current and future six-junction solar cells of the invention are 33.3% and 39.7%, respectively, compared to 30.6% for today's triple junction solar cell. While the achievable current is lower for the six-junction solar cells compared to the three-junction solar cell, the voltage is approximately double that of the triple junction solar cell. In both FIGS. 18A and 19A, similar to the terrestrial multijunction solar cell, the higher efficiency is achieved because much less of the incident light energy is being lost as heat. More photons are absorbed by subcells with band gaps closer to their energies, allowing more of the energy to be converted into electricity and less into heat.

In certain embodiments, methods of manufacturing optoelectronic devices, including photodetectors described above, comprise: depositing a plurality of layers on a substrate in a materials deposition chamber. The plurality of layers may include active layers, doped layers, contact layers, etch stop layers, release layers (i.e., layers designed to release the semiconductor layers from the substrate when a specific process sequence, such as chemical etching, is applied), buffer layers, or other semiconductor layers.

The plurality of layers can be deposited by molecular beam epitaxy (MBE) or by metal-organic chemical vapor deposition (MOCVD). Combinations of deposition methods may also be used.

Various values for band gaps have been recited in the description and in the claims. It should be understood that these values are not exact. However, the values for band gaps are approximated to one significant figure to the right of the decimal point, except where otherwise indicated. Thus, the value 0.9 covers the range 0.850 to 0.949.

Embodiments of the present invention include a semiconductor with a substrate, a first doped III-V layer over the substrate, an absorber layer over the first doped III-V layer, and a second doped III-V layer over the absorber layer. The substrate can have a lattice parameter matching or nearly matching GaAs. The absorber layer can include: a dilute nitride with InₓGa₁₋ₓN_{y}As_{1-y-z}Sb_{z} (0.1232≤x≤0.1568; 0.0318≤y≤0.0352; 0.0067≤z≤0.0126); an In/Sb ratio of at least approximately 10; a band gap between approximately 0.935 eV and 0.963 eV; and a carrier concentration between approximately 8×10¹⁵ cm⁻³ and approximately 1×10¹⁷ cm⁻³ at room temperature. In some embodiments, the dilute nitride can include InₓGa₁₋ₓN_{y}As_{1-y-z}Sb_{z} (0.1232≤x≤0.1568; 0.0318≤y≤0.0352; 0.0067≤z≤0.0080). In some embodiments, the carrier concentration (e.g., background carrier concentration) of the absorber layer is approximately 2×10¹⁵ cm⁻³. In some embodiments, the carrier concentration (e.g., background carrier concentration) of the absorber layer is approximately 7.5×10¹⁴ cm⁻³In some embodiments, the thickness of the absorber layer is approximately 2 micrometers. In some embodiments, the thickness of the absorber layer is between approximately 3 micrometers and approximately 5 micrometers. In some embodiments, the substrate includes GaAs. In some embodiments, the absorber layer is p-type.

Embodiments of the present invention can also include a method of forming a semiconductor. The method can include: forming a first doped III-V layer over a substrate with a lattice parameter matching or nearly matching GaAs; forming an absorber layer over the first doped III-V layer; and forming a second doped III-V layer over the absorber layer. The absorber layer can include: a dilute nitride with InₓGa₁₋ₓN_{y}As_{1-y-z}Sb_{z} (0.1232≤x≤0.1568; 0.0318≤y≤0.0352; 0.0067≤z≤0.0126); an In/Sb ratio of at least approximately 10; a band gap between approximately 0.935 eV and 0.963 eV; and a carrier concentration between approximately 8×10¹⁵ cm⁻³ and approximately 1×10¹⁷ cm⁻³ at room temperature. In some embodiments, the dilute nitride can include InₓGa₁₋ₓN_{y}As_{1-y-z}Sb_{z} (0.1232≤x≤0.1568; 0.0318≤y≤0.0352; 0.0067≤z≤0.0080). In some embodiments, the carrier concentration (e.g., background carrier concentration) of the absorber layer is approximately 2×10¹⁵ cm⁻³. In some embodiments, the carrier concentration (e.g., background carrier concentration) of the absorber layer is approximately 7.5×10¹⁴ cm⁻³. In some embodiments, the thickness of the absorber layer is approximately 2 micrometers. In some embodiments, the thickness of the absorber layer is between approximately 3 micrometers and approximately 5 micrometers. In some embodiments, the substrate includes GaAs. In some embodiments, the absorber layer is p-type.

Embodiments of the present invention include a semiconductor with a substrate, a first doped III-V layer over the substrate, an absorber layer over the first doped III-V layer, and a second doped III-V layer over the absorber layer. The absorber layer can include: a dilute nitride with InₓGa₁₋ₓN_{y}As_{1-y-z}Sb_{z} (0≤x≤1; 0≤y≤0.1; 0≤z≤0.1667); an In/Sb ratio of at least approximately 6; a band gap between approximately 0.7 eV and 0.95 eV; and a carrier concentration less than approximately 1×10¹⁶ cm⁻³ at room temperature. In some embodiments, the dilute nitride includes InₓGa₁₋ₓN_{y}As_{1-y-z}Sb_{z} (0≤x≤0.55; 0<y≤0.1; 0<z≤0.1). In some embodiments, the carrier concentration of the absorber layer is less than approximately 5×10¹⁵ cm⁻³. In some embodiments, the carrier concentration of the absorber layer is less than approximately 1×10¹⁵ cm⁻³. In some embodiments, the thickness of the absorber layer is between approximately 2 micrometers and approximately 10 micrometers. In some embodiments, the thickness of the absorber layer is between approximately 3 micrometers and approximately 5 micrometers. In some embodiments, the absorber layer is p-type.

Embodiments of the present invention can also include a method of forming a semiconductor. The method can include: forming a first doped III-V layer over a substrate with a lattice parameter matching or nearly matching GaAs; forming an absorber layer over the first doped III-V layer; and forming a second doped III-V layer over the absorber layer. The absorber layer can include: a dilute nitride with InₓGa₁₋ₓN_{y}As_{1-y-z}Sb_{z} (0≤x≤1; 0≤y≤0.1; 0<z≤0.1667); an In/Sb ratio of at least approximately 6; a band gap between approximately 0.7 eV and 0.95 eV; and a carrier concentration less than approximately 1×10¹⁶ cm⁻³ at room temperature. In some embodiments, the dilute nitride includes InₓGa₁₋ₓN_{y}As_{1-y-z}Sb_{z} (0≤x≤0.55; 0<y≤0.1; 0<z≤0.1). In some embodiments, the carrier concentration of the absorber layer is less than approximately 5×10¹⁵ cm⁻³. In some embodiments, the carrier concentration of the absorber layer is less than approximately 1×10¹⁵ cm⁻³. In some embodiments, the thickness of the absorber layer is between approximately 2 micrometers and approximately 10 micrometers. In some embodiments, the thickness of the absorber layer is between approximately 3 micrometers and approximately 5 micrometers. In some embodiments, the absorber layer is p-type.

The present disclosure has been explained with reference to specific embodiments. Other embodiments will be evident to those of ordinary skill in the art. It is therefore not intended for the invention to be limited, except as indicated by the appended claims.

What is claimed is:

1. A semiconductor, comprising:
a substrate with a lattice parameter matching or nearly matching GaAs;
a first doped III-V layer over the substrate;
an absorber layer over the first doped III-V layer, the absorber layer having:
a dilute nitride comprising InₓGa₁₋ₓN_{y}As_{1-y-z}Sb_{z} (0.1232≤x≤0.1568; 0.0318≤y≤0.0352; 0.0067≤z≤0.0126),
an In/Sb ratio of at least approximately 10,
a band gap between approximately 0.935 eV and 0.963 eV, and
a carrier concentration between approximately 8×10¹⁵ cm⁻³ and approximately 1×10¹⁷ cm⁻³ at room temperature; and
a second doped III-V layer over the absorber layer.

2. The semiconductor of claim 1, wherein the dilute nitride comprises InₓGa₁₋ₓN_{y}As_{1-y-z}Sb_{z}(0.1232≤x≤0.1568; 0.0318≤y≤0.0352; 0.0067≤z≤0.0080).

3. The semiconductor of claim 1, wherein the carrier concentration of the absorber layer is approximately 2×10¹⁵ cm⁻³.

4. The semiconductor of claim 1, wherein the carrier concentration of the absorber layer is approximately 7.5×10¹⁴ cm⁻³.

5. The semiconductor of claim 1, wherein a thickness of the absorber layer is approximately 2 micrometers.

6. The semiconductor of claim 1, wherein a thickness of the absorber layer is between approximately 3 micrometers and approximately 5 micrometers.

7. The semiconductor of claim 1, wherein the substrate comprises GaAs.

8. The semiconductor of claim 1, wherein the absorber layer is p-type.

9. A method of forming a semiconductor, comprising:
forming a first doped III-V layer over a substrate with a lattice parameter matching or nearly matching GaAs;
forming an absorber layer over the first doped III-V layer, the absorber layer having:
a dilute nitride comprising InₓGa₁₋ₓN_{y}As_{1-y-z}Sb_{z} (0.1232≤x≤0.1568; 0.0318≤y≤0.0352; 0.0067≤z≤0.0126),
an In/Sb ratio of at least approximately 10,
a band gap between approximately 0.935 eV and 0.963 eV, and
a carrier concentration between approximately 8×10¹⁵ cm⁻³ and approximately 1×10¹⁷ cm⁻³; and
forming a second doped III-V layer over the absorber layer.

10. The method of claim 9, wherein the dilute nitride comprises InₓGa₁₋ₓN_{y}As_{1-y-z}Sb_{z}(0.1232≤x≤0.1568; 0.0318≤y≤0.0352; 0.0067≤z≤0.0080).

11. The method of claim 9, wherein the carrier concentration of the absorber layer is approximately 2×10¹⁵ cm⁻³.

12. The method of claim 9, wherein the carrier concentration of the absorber layer is approximately 7.5×10¹⁴ cm⁻³.

13. The method of claim 9, wherein a thickness of the absorber layer is approximately 2 micrometers.

14. The method of claim 9, wherein a thickness of the absorber layer is between approximately 3 micrometers and approximately 5 micrometers.

15. The method of claim 9, wherein the substrate comprises GaAs.

16. The method of claim 9, wherein the absorber layer is p-type.

17. A semiconductor, comprising:
a substrate with a lattice parameter matching or nearly matching GaAs;
a first doped III-V layer over the substrate;
an absorber layer over the first doped III-V layer, the absorber layer having:
a dilute nitride comprising InₓGa₁₋ₓN_{y}As_{1-y-z}Sb_{z} (0≤x≤1; 0≤y≤0.1; 0<z≤0.1667),
an In/Sb ratio of at least approximately 6,
a band gap between approximately 0.7 eV and 0.95 eV, and
a carrier concentration less than approximately 1×10¹⁶ cm⁻³ at room temperature; and
a second doped III-V layer over the absorber layer.

18. The semiconductor of claim 17, wherein the dilute nitride comprises InₓGa₁₋ₓN_{y}As_{1-y-z}Sb_{z} (0≤x≤0.55; 0<y≤0.1; 0<z≤0.1).

19. The semiconductor of claim 17, wherein the carrier concentration of the absorber layer is less than approximately 5×10¹⁵ cm⁻³.

20. The semiconductor of claim 17, wherein the carrier concentration of the absorber layer is less than approximately 1×10¹⁵ cm⁻³.

21. The semiconductor of claim 17, wherein a thickness of the absorber layer is between approximately 2 micrometers and approximately 10 micrometers.

22. The semiconductor of claim 17, wherein a thickness of the absorber layer is between approximately 3 micrometers and approximately 5 micrometers.

23. The semiconductor of claim 17, wherein the absorber layer is p-type.

24. A method of forming a semiconductor, comprising:
forming a first doped III-V layer over a substrate with a lattice parameter matching or nearly matching GaAs;
forming an absorber layer over the first doped III-V layer, the absorber layer having:
a dilute nitride comprising InₓGa₁₋ₓN_{y}As_{1-y-z}Sb_{z} (0≤x≤1; 0≤y≤0.1; 0≤z≤0.1667),
an In/Sb ratio of at least approximately 6,
a band gap between approximately 0.7 eV and 0.95 eV, and
a carrier concentration less than approximately 1×10¹⁶ cm⁻³; and
forming a second doped III-V layer over the absorber layer.

25. The method of claim 24, wherein the dilute nitride comprises InₓGa₁₋ₓN_{y}As_{1-y-z}Sb_{z} (0≤x≤0.55; 0<y≤0.1; 0<z≤0.1).

26. The method of claim 24, wherein the carrier concentration of the absorber layer is less than approximately 5×10¹⁵ cm⁻³.

27. The method of claim 24, wherein the carrier concentration of the absorber layer is less than approximately 1×10¹⁵ cm⁻³.

28. The method of claim 24, wherein a thickness of the absorber layer is between approximately 2 micrometers and approximately 10 micrometers.

29. The method of claim 24, wherein a thickness of the absorber layer is between approximately 3 micrometers and approximately 5 micrometers.

30. The method of claim 24, wherein the absorber layer is p-type.
